(19) United States
(12) Patent Application Publication
(10) Pub. No.: US 2024/0255855 A1
(43) Pub. Date: Aug. 1, 2024

(54) PATTERN EXPOSURE APPARATUS, EXPOSURE METHOD, AND DEVICE MANUFACTURING METHOD

(71) Applicant: NIKON CORPORATION, Tokyo (JP)

(72) Inventors: Masaki KATO, Yokohama-shi (JP); Keisuke HASEGAWA, Ageo-shi (JP); Toshiharu NAKASHIMA, Fukaya-shi (JP); Yasushi MIZUNO, Saitama-shi (JP)

(73) Assignee: NIKON CORPORATION, Tokyo (JP)

(21) Appl. No.: 18/400,519

(22) Filed: Dec. 29, 2023

Related U.S. Application Data
(63) Continuation of application No. PCT/JP22/26500, filed on Jul. 1, 2022.

(30) Foreign Application Priority Data
Jul. 5, 2021 (JP) 2021-111514

(51) Int. Cl. G03F 7/00

(52) U.S. Cl. CPC G03F 7/70116; G03F 7/70075; G03F 7/70141; G03F 7/70258; G03F 7/70425; G03F 7/70653; G03F 7/70725

(57) ABSTRACT

A pattern-exposure-apparatus includes illumination-unit that irradiates illumination-light to spatial-light-modulating-element including a plurality of micro-mirrors that are driven to switch between ON-state and OFF-state based on drawing-data, and projection-unit that allows incidence of reflected light from the micro-mirrors of the spatial-light-modulating-element in the ON-state as image-forming-light-flux and that projects image of pattern corresponding to the drawing-data to a substrate. The pattern-exposure-apparatus includes a controller that stores information, which is related to an angular-variation of the image-forming-light-flux generated according to a distribution density of the micro-mirrors of spatial-light-modulating-element which are in the ON-state, together with the drawing-data as recipe-information, and an adjustment-mechanism that adjusts (i) a position or an angle of at least one optical-member in the illumination-unit or the projection-unit or (ii) an angle of the spatial-light-modulating-element, according to the information related to the angular-variation when a pattern is exposed on the substrate by driving the spatial-light-modulating-element based on the recipe-information.

### CROSS-REFERENCE TO RELATED APPLICATION

Priority is claimed on Japanese Patent Application No. 2021-111514, filed on Jul. 5, 2021. The present application is a continuation application of International Application PCT/JP2022/026500, filed on Jul. 1, 2022. The contents of the above applications are incorporated herein.

### BACKGROUND

### Technical Field

The present invention relates to a pattern exposure apparatus configured to expose a pattern for an electronic device, an exposure method, and a device manufacturing method.

In the related art, in a lithography process of manufacturing liquid crystal or organic EL display panels, an electronic device (micro device) such as a semiconductor device (an integrated circuit or the like), or the like, a step-and-repeat type projection exposure apparatus (so-called stepper), a step-and-scan type projection exposure apparatus (so-called scanning stepper (also referred to as a scanner)), or the like is used. Such an exposure apparatus projects and exposes a mask pattern for an electronic device to a photosensitive layer applied on a surface of an exposed substrate (hereinafter, also simply referred to as a substrate) such as a glass substrate, a semiconductor wafer, a printed circuit board, a resin film, or the like.

Due to the time and expenses required to create a mask substrate that forms the mask pattern fixedly, an exposure apparatus using a spatial light modulating element (a variable mask pattern generator) such as a digital mirror device (DMD) or the like in which a plurality of micromirrors that are slightly displaced are regularly arranged, instead of the mask substrate, is known (for example, see Japanese Unexamined Patent Application, First Publication No. 2019-23748). In the exposure apparatus disclosed in Japanese Unexamined Patent Application, First Publication No. 2019-23748, for example, illumination light obtained by mixing light from a laser diode (LD) with a wavelength of 375 nm and light from an LD with a wavelength of 405 nm using a multi-mode fiber bundle is radiated to a digital mirror device (DMD), and reflected light from each of a plurality of micromirrors, inclinations of which are controlled, is projected to expose a substrate via an imaging optical system and a microlens array.

In a digital type, for example, an inclined angle of each of the micromirrors of the DMD is set to 0° when off (when reflected light does not enter an imaging optical system), and 12° when on (reflected light enters the imaging optical system). Since the plurality of micro mirrors are disposed at a constant pitch (for example, 10 μm or less) in a matrix, the function of an optical diffraction grating is also provided. In particular, when a fine pattern for an electronic device is projected and exposed, an image forming state of a pattern may be deteriorated by a wavelength of illumination light to the DMD and an action of the diffraction grating of the DMD (a state of a generating direction or an intensity distribution of diffraction light).

### SUMMARY

According to a first aspect of the present invention, there is provided a pattern exposure apparatus including an illumination unit configured to irradiate illumination light to a spatial light modulating element including a plurality of micro mirrors that are driven to switch between an ON state and an OFF state based on drawing data, and a projection unit configured to allow incidence of reflected light from the micro mirrors of the spatial light modulating element which are in the ON state as an image forming light flux and configured to project an image of a pattern corresponding to the drawing data to a substrate, the pattern exposure apparatus including a control unit configured to store information, which is related to an angular variation of the image forming light flux generated according to a distribution density of the micro mirrors of the spatial light modulating element in the ON state, together with the drawing data as recipe information; and an adjustment mechanism configured to adjust (i) a position or an angle of at least one optical member in the illumination unit or the projection unit or (ii) an angle of the spatial light modulating element, according to the information related to the angular variation when a pattern is exposed on the substrate by driving the spatial light modulating element based on the recipe information.

According to a second aspect of the present invention, there is provided a pattern exposure apparatus including a spatial light modulating element including a plurality of micro mirrors selectively driven based on drawing data, an illumination unit configured to irradiate illumination light to the spatial light modulating element at a predetermined incidence angle, and a projection unit configured to allow incidence of reflected light from the selected micro mirrors of the spatial light modulating element in the ON state as an image forming light flux and configured to project the reflected light to a substrate, and the pattern exposure apparatus is configured to project and expose a pattern corresponding to the drawing data to the substrate, the pattern exposure apparatus including a telecentric error specifying part configured to previously specify a telecentric error, which occurs in the image forming light flux projected to the substrate from the projection unit upon projection exposure of the pattern, according to a distribution state of the micro mirrors of the spatial light modulating element which are in the ON state; and an adjustment mechanism configured to adjust a position or an angle of an optical member of a part of the illumination unit or the projection unit such that the telecentric error is corrected.

According to a third aspect of the present invention, there is provided a pattern exposure apparatus including an illumination unit configured to irradiate illumination light to a spatial light modulating element including a plurality of micro mirrors that are switched between an ON state and an OFF state based on drawing data for pattern exposure, and a projection unit configured to allow incidence of the reflected light from the micro mirrors of the spatial light modulating element which are in the ON state as an image forming light flux and configured to project a pattern image corresponding to the drawing data to a substrate, the pattern exposure apparatus including a measurement unit configured to measure a degree of asymmetry of the pattern image caused by a telecentric error of the image forming light flux occurring according to a distribution density of the micro mirrors of the spatial light modulating element which are in the ON state; and an adjustment mechanism configured to adjust (i) a position or an angle of at least one optical member in the illumination unit or the projection unit or (ii) an angle of the spatial light modulating element such that the measured asymmetry is reduced when the spatial light modulating element is driven based on the drawing data and the pattern image is exposed on the substrate.

According to a fourth aspect of the present invention, there is provided a device manufacturing method of forming a device pattern on a substrate by irradiating illumination light from an illumination unit to a spatial light modulating element including a plurality of micro mirrors that are switched between an ON state and an OFF state based on drawing data and by projecting an image of the device pattern corresponding to the drawing data to the substrate using a projection unit configured to allow incidence of reflected light from the micro mirrors of the spatial light modulating element which are in the ON state as an image forming light flux, the device manufacturing method including a step of specifying a telecentric error of the image forming light flux generated according to a distribution state of the micro mirrors of the spatial light modulating element which are in the ON state or a light quantity variation error of the image forming light flux caused by a driving error of the micro mirrors which are in the ON state; and a step of adjusting an installation state of at least one optical member in the illumination unit or the projection unit or the spatial light modulating element such that the specified telecentric error or the specified light quantity variation error is reduced when an image of the device pattern is exposed on the substrate by driving the spatial light modulating element based on the drawing data t.

According to a fifth aspect of the present invention, there is provided a device manufacturing method of forming an electronic device on a substrate by irradiating illumination light from an illumination unit to a spatial light modulating element including a plurality of micro mirrors that are switched between an ON state and an OFF state based on drawing data and projecting a pattern image of an electronic device corresponding to the drawing data to the substrate using a projection unit configured to allow incidence of reflected light from the micro mirrors of the spatial light modulating element which are in the ON state as an image forming light flux, the device manufacturing method including a step of specifying at least one error of (i) a telecentric error of the image forming light flux generated by a diffraction effect caused by a distribution state of the micro mirrors of the spatial light modulating element which are in the ON state, (ii) an asymmetry error of the pattern image occurring due to the telecentric error, (iii) a light quantity variation error of the image forming light flux caused due to a driving error of the micro mirrors which are in the ON state, and (iv) a telecentric error of the image forming light flux caused due to the driving error, and a step of adjusting an installation state of at least one optical member in the illumination unit or the projection unit or an installation state of the spatial light modulating element such that the at least one specified error is reduced when the spatial light modulating element is driven and the pattern image is exposed on the substrate.

According to a sixth aspect of the present invention, there is provided an exposure method including an illumination unit configured to irradiate illumination light to a spatial light modulating element including a plurality of micro mirrors that are driven to switch between an ON state and an OFF state based on drawing data, and a projection unit configured to allow incidence of reflected light from the micro mirrors of the spatial light modulating element which are in the ON state as an image forming light flux and configured to project the light to a substrate, wherein an angular variation of the image forming light flux, which is generated based on a distribution of the micro mirrors of the spatial light modulating element which are in the ON state, is adjusted, and a light quantity variation of the image forming light flux caused by the adjustment is adjusted, and the adjustment of the angular variation is performed by adjustment of a position or an angle of an optical member in the illumination unit or the projection unit, or an angle of the spatial light modulating element.

### BRIEF DESCRIPTION OF THE DRAWINGS

FIG. 1 is a perspective view showing a schematic external configuration of a pattern exposure apparatus EX according to an embodiment.

FIG. 2 is a view showing a disposition example of a projection region IAn of a DMD 10 projected onto a substrate P by a projection unit PLU of each of a plurality of exposure modules MU.

FIG. 3 is a view for describing a state of continuous exposure by each of four specified projection regions IA8, IA9, IA10 and IA27 in FIG. 2.

FIG. 4 is an optical arrangement view showing a specific configuration of two exposure modules MU18 and MU19 arranged in an X direction (scanning exposure direction) in an XZ plane.

FIG. 5 is a view schematically showing a state in which the DMD 10 and the illumination unit PLU are inclined by an angle θk in the XY plane.

FIG. 6 is a view for describing an image forming state of micro mirrors of the DMD 10 by the projection units PLU in detail.

FIG. 7 is a schematic view showing an MFE lens 108A as an optical integrator 108 from an emission surface side.

FIG. 8 is a view schematically showing an example of an arrangement relation between a point light source SPF and an emission end of an optical fiber bundle FBn formed on an emission surface side of a lens element EL of the MFE lens 108A of FIG. 7.

FIG. 9 is a view schematically showing an aspect of a light source image formed on a pupil Ep in a second lens system 118 of the projection unit PL shown in FIG. 6.

FIG. 10 is a view schematically showing a behavior of illumination light (image forming light flux) Sa of an optical path from the pupil Ep of the second lens group 118 to the substrate P shown in FIG. 6.

FIG. 11 is an enlarged perspective view of a state of some micro mirrors Ms of the DMD 10 when a power supply to a driving circuit of the DMD 10 is off.

FIG. 12 is an enlarged perspective view of a part of a mirror surface of the DMD 10 when the micro mirrors Ms of the DMD 10 are in an ON state and an OFF state.

FIG. 13 is a view showing a part of the mirror surface of the DMD 10 in an X′Y′ plane when only a row of micro mirrors Ms arranged in a Y′ direction is in an ON state.

FIG. 14 is a view of a portion of the mirror surface of the DMD 10 of FIG. 13 along an arrow XIV-XIV in an X′Z plane.

FIG. 15 is a view schematically showing an image forming state due to the projection units PLU of the reflected light (image forming light flux) Sa from the isolated micro mirrors Msa in the X′Z plane as shown in FIG. 13.

FIG. 16 is a graph schematically showing a point image intensity distribution lea of a diffraction image in the pupil Ep by regular reflected light Sa from the isolated micro mirrors Msa.

FIG. 17 is a view showing a part of the mirror surface of the DMD 10 in an X′Y′ plane when the plurality of micro mirrors Ms adjacent to each other in the X′ direction are in an ON state simultaneously.

FIG. 18 is a view of a portion of the mirror surface of the DMD 10 of FIG. 16 along the arrow XVIII-XVIII in the X′Z plane.

FIG. 19 is a graph showing an example of a distribution of an angle θj of diffraction light Idj generated from the DMD 10 in the state of FIG. 17 and FIG. 18.

FIG. 20 is a view schematically showing an intensity distribution of an image forming light flux on the pupil Ep in a generation state of such diffraction light in FIG. 19.

FIG. 21 is a view of a state of a part of the mirror surface of the DMD 10 upon projection of a line and space pattern in an X′Y′ plane.

FIG. 22 is a view showing a part of the mirror surface of the DMD 10 of FIG. 21 along the arrow XXII-XXII in the X′Z plane, showing a variant of a distribution unit of the embodiment.

FIG. 23 is a graph showing an example of a distribution of the angle θj of the diffraction light Idj generated from the DMD 10 in the state of FIG. 21 and FIG. 22.

FIG. 24 is a graph showing a result obtained by simulating a contrast of a spatial image of a line and space pattern with a line width of 1 μm on an image surface.

FIG. 25 is a graph that calculates a relation between a wavelength λ and a telecentric error Δθt on the basis of Equation (2).

FIG. 26 is a view showing a specific configuration of an optical path from the optical fiber bundle FBn of the illumination unit ILU to the MFE 108A shown in FIG. 4 or FIG. 6.

FIG. 27 is a view showing a specific configuration of an optical path from the MFE 108A of the illumination unit ILU to the DMD 10 shown in FIG. 4 or FIG. 6.

FIG. 28 is a view in which a state of the point light source SPF formed on an emission surface side of the MFE 108A when the illumination light ILm entering the MFE 108A is inclined in the X′Z plane is exaggerated.

FIG. 29 is a view showing a configuration of an example of a beam supply unit provided in the exposure apparatus EX shown in FIG. 1 and configured to supply illumination light ILm to each of the modules MUn (n=1 to 27).

FIG. 30 is a view schematically showing a wavelength distribution of a beam LBb after beams LB1 to LB7 from seven laser light sources FL1 to FL8 are synthesized by a beam synthesizing unit 200.

FIG. 31 is a view showing an aspect of a portion of the mirror surface of the DMD 10 upon exposure of line and space pattern inclined by 45° on the substrate P.

FIG. 32 is a block diagram showing a schematic example of a part of an exposure control device provided in the exposure apparatus EX of the embodiment related to, in particular, adjustment control of a telecentric error.

FIG. 33 is a view showing an example of arrangement of a display region DPA for a display panel exposed on the substrate P by the exposure apparatus EX and peripheral regions PPAx and PPAy.

FIG. 34 is a view showing an example of an arrangement state of pixels PIX in the display region DPA appeared in the projection region IAn (n=1 to 27).

FIG. 35 is a view showing a schematic configuration of an optical measurement part provided on a reference portion CU for calibration provided on an end portion of a substrate holder 4B of the exposure apparatus EX shown in FIG. 1.

FIG. 36 is a view showing a schematic configuration of one of drawing modules provided in a pattern exposure apparatus according to a second embodiment.

FIG. 37 is a view in which a state of micro mirrors Ms when an isolation pattern with a minimum line width is projected by a DMD 10′ of FIG. 36 is exaggerated.

FIG. 38 is a graph schematically showing a point image intensity distribution lea of a diffraction image on a pupil Ep of reflected light Sa from isolated micro mirrors Msa in an ON state as shown in FIG. 37.

FIG. 39 is a view in which a state of the micro mirrors Ms when a large land-like pattern is projected by the DMD 10′ of FIG. 36 is exaggerated.

FIG. 40 is a view schematically showing an example of a generating direction of a center ray of 0-order diffraction light and ±1-order diffraction light contained in reflected light Sa′ in a state of FIG. 39.

### DESCRIPTION OF THE EMBODIMENTS

A pattern exposure apparatus (pattern forming apparatus) according to an aspect of the present invention will be described below in detail with reference to the accompanying drawings while exemplifying suitable embodiments. Further, aspects of the present invention are not limited to these embodiments, and also include those with various changes or improvements. That is, the components described below include those that would likely be assumed by a person skilled in the art and those that are substantially the same, and the components described below can be combined as appropriate. In addition, various omissions, substitutions, or changes of the components may be made without departing from the scope of the present invention. Further, throughout the drawings and detailed descriptions that follow, the same reference signs are used for members or components that accomplish the same or similar functions.

### (Entire Configuration of Pattern Exposure Apparatus)

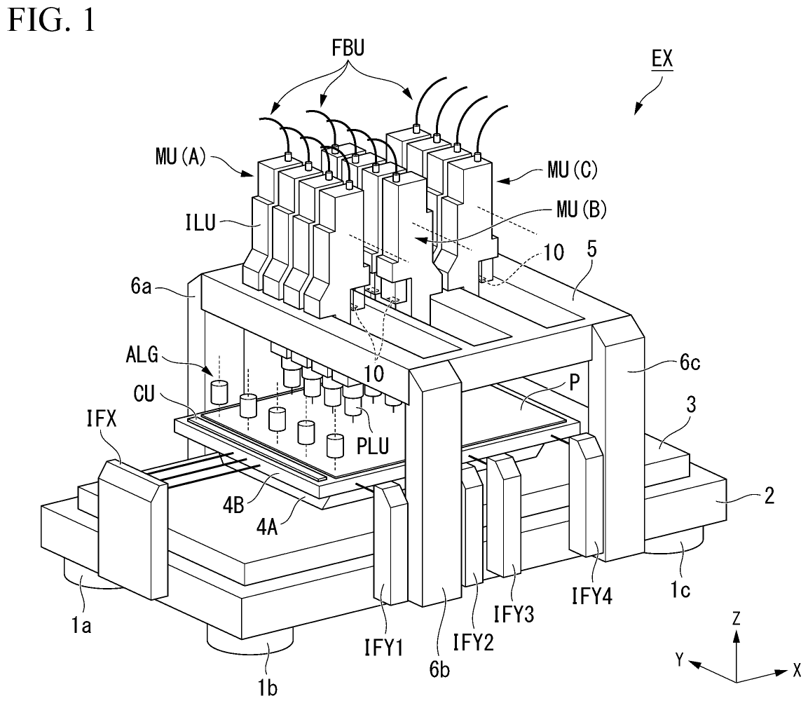

FIG. 1 is a perspective view showing a schematic external configuration of a pattern exposure apparatus (hereinafter, also simply referred to as an exposure apparatus) EX of the embodiment. The exposure apparatus EX is an apparatus configured to project exposure light with an intensity distribution dynamically modulated in a space to form an image on an exposed substrate using a spatial light modulating element (digital mirror device: DMD). In a specified embodiment, the exposure apparatus EX is a step-and-scan type projection exposure apparatus (scanner) in which a rectangular (square) glass substrate used in a display device (flat panel display) or the like is provided as an exposure object. The glass substrate is a substrate P for a flat panel display, in which a length of at least one side or a diagonal length is 500 mm or more and a thickness is 1 mm or less. The exposure apparatus EX exposes a projection image of a pattern created by the DMD to a photosensitive layer (photoresist) formed with a constant thickness on a surface of the substrate P. The substrate P conveyed from the exposure apparatus EX after exposure is sent to a predetermined process (a film forming process, an etching process, a plating process, or the like) after a development process.

The exposure apparatus EX includes a stage apparatus constituted by a pedestal 2 placed on active vibration proof units 1a, 1b, 1c and id (1d is not shown), a surface plate 3 placed on the pedestal 2, an XY stage 4A that is two-dimensionally movable on the surface plate 3, a substrate holder 4B configured to suck and hold the substrate P on a planar surface on the XY stage 4A, and a laser length measurement interferometers (hereinafter, also simply referred to as an interferometer) IFX and IFY1 to IFY4 configured to measure a two-dimensional moving position of the substrate holder 4B (the substrate P). Such a stage apparatus is disclosed in, for example, US Patent Publication No. 2010/0018950, and US Patent Publication No. 2012/0057140.

In FIG. 1, an XY plane of an orthogonal coordinate system XYZ is set to be parallel to a flat surface of the surface plate 3 of the stage apparatus, and the XY stage 4A is set to be able to move in translation within the XY plane. In addition, in the embodiment, a direction parallel to the X axis of the coordinate system XYZ is set as a scanning movement direction of the substrate P (the XY stage 4A) upon scanning exposure. A moving position of the substrate P in the X axis direction is sequentially measured by the interferometer IFX, and a moving position in a Y axis direction is sequentially measured by at least one or more (preferably two) of the four interferometers IFY1 to IFY4. The substrate holder 4B is configured to be finely movable with respect to the XY stage 4A in a Z axis direction perpendicular to the XY plane and finely tiltable with respect to the XY plane in an arbitrary direction, and focus adjustment and leveling (degree of parallelization) adjustment between a surface of the substrate P and an image forming surface of the projected pattern are actively performed. Further, the substrate holder 4B is configured to be micro-rotatable (Oz rotation) around an axis parallel to the Z axis in order to actively adjust an inclination of the substrate P in the XY plane.

The exposure apparatus EX further includes an optical surface plate 5 configured to hold a plurality of exposure (drawing) modules MU(A), MU(B) and MU(C), and main columns 6a, 6b, 6c and 6d (6d is not shown) configured to support the optical surface plate 5 from the pedestal 2. Each of the plurality of exposure modules MU(A), MU(B) and MU(C) has an illumination unit ILU attached on a side of the optical surface plate 5 in a +Z direction and configured to allow incidence of illumination light from an optical fiber unit FBU, and a projection unit PLU attached to a side of the optical surface plate 5 in a −Z direction and having an optical axis parallel to the Z axis. Further, each of the exposure modules MU(A), MU(B) and MU(C) includes a digital mirror device (DMD) 10 configured to reflect illumination light from the illumination unit ILU in the −Z direction and cause the illumination light to enter the projection unit PLU serving as an optical modulation unit. A detailed configuration of an exposure module constituted by the illumination unit ILU, the DMD 10, and the projection unit PLU will be described below.

A plurality of alignment systems (microscopes) ALG configured to detect alignment marks formed at a plurality of predetermined positions on the substrate P are attached to a side of the optical surface plate 5 of the exposure apparatus EX in the −Z direction. In order to perform confirmation (calibration) of a relative positional relation in an XY plane of a detection field of vision of each of the alignment systems ALG, confirmation (calibration) of a base line error between each projection position of a pattern image projected from the projection unit PLU of each of the exposure modules MU(A), MU(B) and MU(C) and a position of a detection field of vision of each of the alignment systems ALG, or confirmation of a position or image quality of the pattern image projected from the projection unit PLU, a calibration reference portion CU is provided on an end portion on the substrate holder 4B in the −X direction. Further, while a part in FIG. 1 is not shown, in the embodiment, in each of the exposure modules MU(A), MU(B) and MU(C), nine modules are arranged at a constant interval in the Y direction as an example, but the number of modules may be smaller than nine or may be greater than nine.

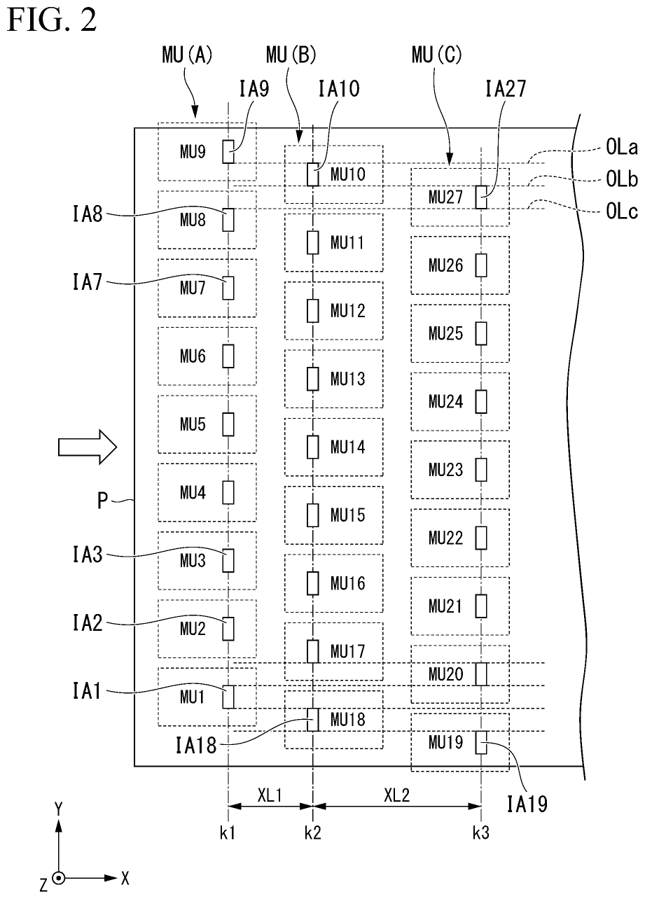

FIG. 2 is a view showing a disposition example of projection regions IAn of the digital mirror device (DMD) 10 projected onto the substrate P by the projection unit PLU of each of the exposure modules MU(A), MU(B) and MU(C), and the same orthogonal coordinate system XYZ as in FIG. 1 is set. In the embodiment, each of the exposure module MU(A) of a first row, the exposure module MU(B) of a second row, and the exposure module MU(C) of a third row, which are separated from each other in the X direction, is constituted by nine modules arranged in the Y direction. The exposure module MU(A) is constituted by nine modules MU1 to MU9 disposed in the +Y direction, the exposure module MU(B) is constituted by nine modules MU10 to MU18 disposed in the −Y direction, and the exposure module MU(C) is constituted by nine modules MU19 to MU27 disposed in the +Y direction. All the modules MU1 to MU27 have the same configurations, and when the exposure module MU(A) and the exposure module MU(B) are set to face each other in the X direction, the exposure module MU(B) and the exposure module MU(C) have a back-to-back relation in the X direction.

In FIG. 2, a shape of each of projection regions IA1, IA2, IA3, . . . , IA27 (n is 1 to 27, expressed as IAn) according to each of the modules MU1 to MU27 has a rectangular shape in the Y direction with an aspect ratio of about 1:2 as an example. In the embodiment, according to scanning movement of the substrate P in the +X direction, continuous exposure is performed by an end portion of each of the projection regions IA1 to IA9 of the first row in the −Y direction and an end portion of each of the projection regions IA10 to IA18 of the second row in the +Y direction. Then, a region on the substrate P not exposed by each of the projection regions IA1 to IA18 of the first row and the second row is continuously exposed by each of the projection regions IA19 to IA27 of the third row. A center point of each of the projection regions IA1 to IA9 of the first row is located on a line k1 parallel to the Y axis, a center point of each of the projection regions IA10 to IA18 of the second row is located on a line k2 parallel to the Y axis, and a center point of each of the projection regions IA19 to IA27 of the third row is located on a line k3 parallel to the Y axis. An interval between the line k1 and the line k2 in the X direction is set to a distance XL1, and an interval between the line k2 and the line k3 in the X direction is set to a distance XL2.

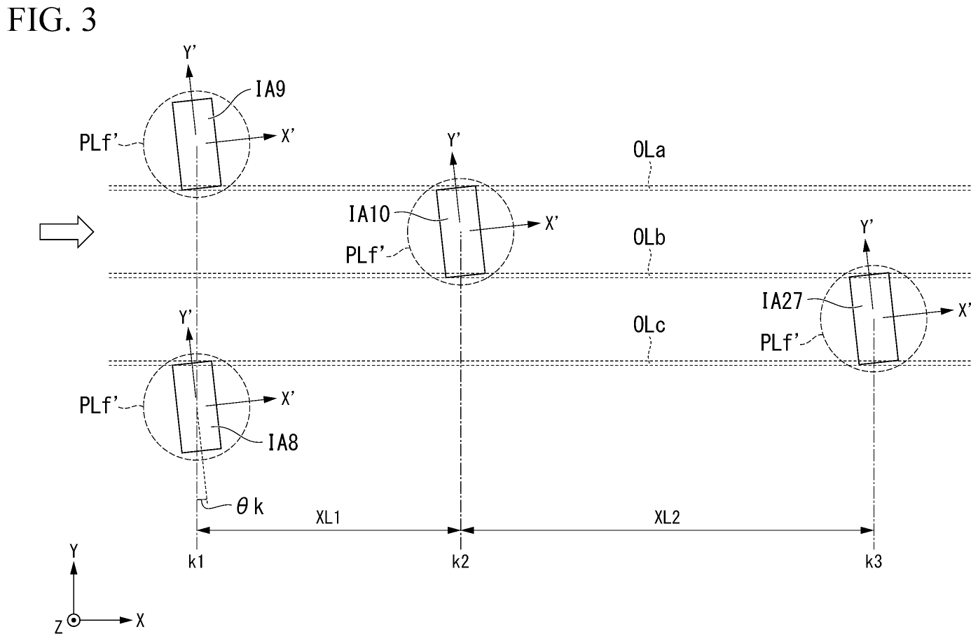

Here, a state of the continuous exposure will be described with reference to FIG. 3 when a joint portion between the end portion of the projection region IA9 in the −Y direction and the end portion of the projection region IA10 in the +Y direction is referred to as OLa, a joint portion between the end portion of the projection region IA10 in the −Y direction and the end portion of the projection region IA27 in the +Y direction is referred to as OLb, and a joint portion between the end portion of the projection region IA8 in the +Y direction and the end portion of the projection region IA27 in the −Y direction is referred to as OLc. In FIG. 3, the same orthogonal coordinate system XYZ as in FIG. 1 and FIG. 2 is set, and a coordinate system X′Y′ in the projection regions IA8, IA9, IA10 and IA27 (and, all the other projection regions IAn) are set to be inclined with respect to an X axis and a Y axis (the lines k1 to k3) of the orthogonal coordinate system XYZ by an angle θk. That is, the entire DMD 10 is inclined in the XY plane by the angle θk such that two-dimensional arrangement of the plurality of micro mirrors of the DMD 10 becomes the coordinate system X′Y′.

A circular region containing each of the projection regions IA8, IA9, IA10 and IA27 (and all the other projection regions IAn are also the same) in FIG. 3 represents a circular image field PLf′ of the projection unit PLU. In the joint portion OLa, a projection image of the micro mirror aligned obliquely (the angle θk) to the end portion of the projection region IA9 in the −Y′ direction and a projection image of the micro mirror aligned obliquely (the angle θk) to the end portion of the projection region IA10 in the +Y′ direction are set to overlap each other. In addition, in the joint portion OLb, a projection image of the micro mirror aligned obliquely (the angle θδk) to the end portion of the projection region IA10 in the −Y′ direction and a projection image of the micro mirror aligned obliquely (the angle θk) to the end portion of the projection region IA27 in the +Y′ direction are set to overlap each other. Similarly, in the joint portion OLc, a projection image of the micro mirror aligned obliquely (the angle θk) to the end portion of the projection region IA8 in the +Y′ direction and a projection image of the micro mirror aligned obliquely (the angle θk) to the end portion of the projection region IA27 in the −Y′ direction are set to overlap each other.

### (Configuration of Illumination Unit)

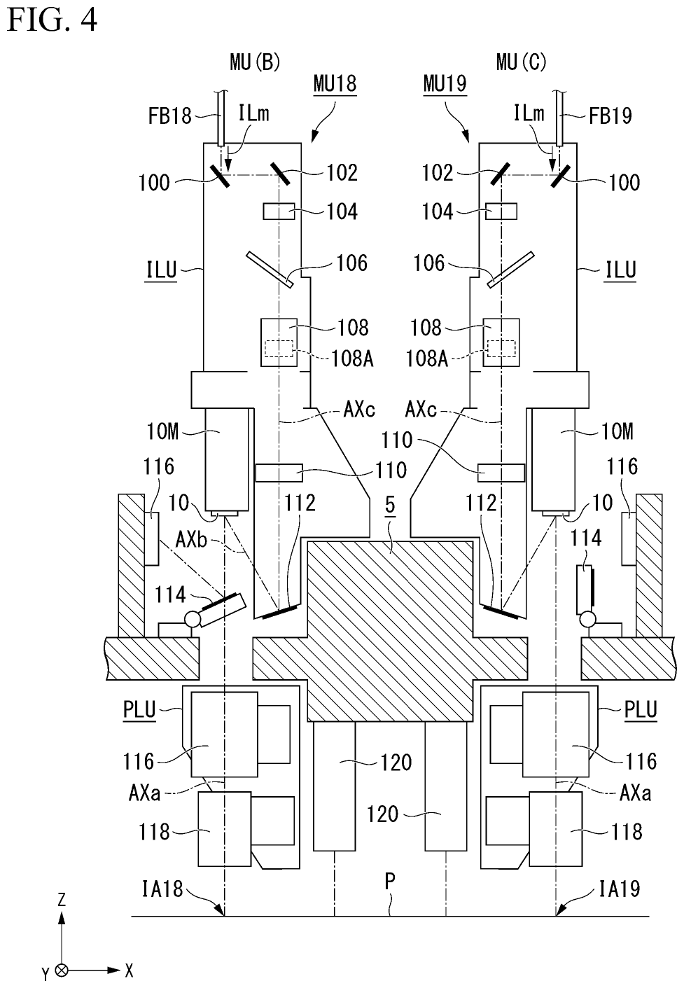

FIG. 4 is an optical arrangement view showing a specific configuration of the module MU18 in the exposure module MU(B) and the module MU19 in the exposure module MU(C) shown in FIG. 1 and FIG. 2 in the XZ plane. The orthogonal coordinate system XYZ of FIG. 4 is set to the same as the orthogonal coordinate system XYZ of FIG. 1 to FIG. 3. In addition, as will be apparent from the disposition of the modules in the XY plane shown in FIG. 2, the module MU18 is deviated from the module MU19 by a constant interval in the +Y direction, and they are installed to have a back-to-back relation. Since each of the optical members in the module MU18 and each of the optical members in the module MU19 are formed of the same material and have the same configuration, the optical configuration of the module MU18 will be mainly described in detail herein. Further, the optical fiber unit FBU shown in FIG. 1 is constituted by 27 optical fiber bundles FB1 to FB27 to correspond to the 27 modules MU1 to MU27 shown in FIG. 2, respectively.

The illumination unit ILU of the module MU18 is constituted by a mirror 100 configured to reflect illumination light ILm that advances from an emission end of the optical fiber bundle FB18 in the −Z direction, a mirror 102 configured to reflect the illumination light ILm from the mirror 100 in the −Z direction, an input lens system 104 serving as a collimator lens, an optical integrator 108 including an illuminance adjustment filter 106, a micro fly's eye (MFE) lens, a field lens, or the like, a condenser lens system 110, and an inclined mirror 112 configured to reflect the illumination light ILm from the condenser lens system 110 toward the DMD 10. The mirror 102, the input lens system 104, the optical integrator 108, the condenser lens system 110, and the inclined mirror 112 are disposed along an optical axis AXc parallel to the Z axis.

The optical fiber bundle FB18 is configured by a single optical fiber wire or a bundle of a plurality of optical fiber wires. The illumination light ILm radiated from an emission end of the optical fiber bundle FB18 (each of the optical fiber wires) is set to a numerical aperture (NA, also referred to as a flare angle) that allows incidence of the light without being cut off by the input lens system 104 in the subsequent stage. A position of a front focal point of the input lens system 104 is set to the same as the position of the emission end of the optical fiber bundle FB18 by design. Further, the position of the rear focal point of the input lens system 104 is set such that illumination light ILm from a single or a plurality of point light sources formed on the emission end of the optical fiber bundle FB18 overlaps an incident surface side of an MFE lens 108A of the optical integrator 108. Accordingly, an incident surface of the MFE lens 108A is Koehler-illuminated by the illumination light ILm from the emission end of the optical fiber bundle FB18. Further, in an initial state, a geometrical center point of the emission end of the optical fiber bundle FB18 in the XY plane is located on the optical axis AXc, and a principal ray (central ray) of the illumination light ILm from the point light source of the emission end of the optical fiber wire is parallel to (or coaxial with) the optical axis AXc.

The illumination light ILm from the input lens system 104 enters the condenser lens system 110 through the optical integrator 108 (the MFE lens 108A, the field lens, or the like) after reduction in illuminance with an arbitrary value of a range of 0% to 90% by the illuminance adjustment filter 106. The MFE lens 108A is constituted by a plurality of rectangular micro lens with angles of tens m in a two-dimensional array, and the entire shape in the XY plane is set to be almost similar to the entire shape of the mirror surface of the DMD 10 (an aspect ratio is about 1:2). In addition, a position of the front focal point of the condenser lens system 110 is set to substantially the same as the position of the emission surface of the MFE lens 108A. For this reason, the illumination light from each of the point light sources formed on each emission side of the plurality of micro lenses of the MFE lens 108A is converted to a substantially parallel light flux by the condenser lens system 110, reflected by the inclined mirror 112, and then, overlaps on the DMD 10 to be distributed with a uniform illuminance distribution. Since a surface light source in which a plurality of point light sources (condensing points) are two-dimensionally densely arranged is generated on the emission surface of the MFE lens 108A, the surface light source functions as a surface light source member.

In the module MU18 shown in FIG. 4, the optical axis AXc parallel to the Z axis through the condenser lens system 110 is bent by the inclined mirror 112 and reaches the DMD 10, but an optical axis between the inclined mirror 112 and the DMD 10 becomes an optical axis AXb. In the embodiment, a neutral plane including a center point of each of the plurality of micro mirrors of the DMD 10 is set to be parallel to the XY plane. Accordingly, an angle formed between a normal line (parallel to the Z axis) of the neutral plane and the optical axis AXb becomes an incidence angle θα of the illumination light ILm with respect to the DMD 10. The DMD 10 is attached to a lower side of a mount portion 10M fixed to a support column of the illumination unit ILU. For example, a micro-motion stage in which a parallel link mechanism and a stretchable piezo element are assembled as disclosed in PCT International Publication No. 2006/120927 is provided in the mount portion 10M in order to finely adjust a position or a posture of the DMD 10.

The illumination light ILm radiated to the micro mirror in an ON state among the micro mirrors of the DMD 10 is reflected toward the projection unit PLU in the X direction in the XZ plane. Meanwhile, the illumination light ILm radiated to the micro mirror in an OFF state among the micro mirrors of the DMD 10 is reflected not to be directed toward the projection unit PLU in the Y direction in the YZ plane. While described below in detail, the DMD 10 in the embodiment is a roll and pitch driving type in which the ON state and the OFF state are switched by inclination in a roll direction and inclination in a pitch direction of the micro mirror.

A movable shutter 114 configured to shield the reflected light from the DMD 10 in a non-exposure period is detachably provided in an optical path between the projection units PLU from the DMD 10. The movable shutter 114 is pivoted to an angle position where it retreats from the optical path in an exposure period as shown on the side of the module MU19 and pivoted to an angle position where it is obliquely inserted into the optical path in the non-exposure period as shown in the side of the module MU18. A reflecting surface is formed in the movable shutter 114 on the side of the DMD 10, and light from the DMD 10 reflected thereon is radiated to a light absorption body 116. The light absorption body 116 absorbs light energy in an ultraviolet wavelength region (a wavelength of 400 nm or less) without re-reflection and converts the light energy into thermal energy. For this reason, a heat radiation mechanism (a heat radiation fin or a cooling mechanism) is also provided in the light absorption body 116. Further, while not shown in FIG. 4, the reflected light from the micro mirror of the DMD 10 in the OFF state during the exposure period is absorbed by the same light absorption body (not shown in FIG. 4) installed with respect to the optical path between the DMD 10 and the projection unit PLU in the Y direction (a direction perpendicular to the drawing of FIG. 4).

### (Configuration of Projection Unit)

The projection unit PLU attached to a lower side of the optical surface plate 5 is constituted as a bilateral telecentric image forming projection lens system constituted by a first lens group 116 and a second lens group 118 disposed along an optical axis AXa parallel to the Z axis. Each of the first lens group 116 and the second lens group 118 is configured to be translated with respect to a support column fixed to a lower side of the optical surface plate 5 by a micro-motion actuator in a direction along the Z axis (the optical axis AXa). A projection magnification Mp of an image forming projection lens system by the first lens group 116 and the second lens group 118 is determined by a relation between an arrangement pitch Pd of the micro mirrors on the DMD 10 and a minimum line width (minimum pixel dimension) Pg of a pattern projected into the projection region IAn (n=1 to 27) on the substrate P.

As an example, when the required minimum line width (minimum pixel dimension) Pg is 1 μm and the arrangement pitch Pd of the micro mirrors is 5.4 μm, the projection magnification Mp is set to about ⅙ in consideration of an inclination angle θk in the XY plane of the projection region IAn (the DMD 10) described in FIG. 3 above. The image forming projection lens system by the lens groups 116 and 118 stands up and inverts a reduced image of the entire mirror surface of the DMD 10 to form an image in the projection region IA18 (IAn) on the substrate P.

The first lens group 116 of the projection unit PLU is finely movable in the optical axis AXa direction by an actuator in order to perform fine adjustment (about several tens ppm) of the projection magnification Mp, and the second lens group 118 is finely movable in the optical axis AXa direction by an actuator in order to perform high speed adjustment of the focus. Further, in order to measure a position change of a surface of the substrate P in the Z axis direction with accuracy of submicron or less, a plurality of oblique incident light type focus sensors 120 are provided below the optical surface plate 5. The plurality of focus sensors 120 measure a position change of the entire substrate P in the Z axis direction, a position change of a partial region on the substrate P in the Z axis direction corresponding to each of the projection regions IAn (n=1 to 27), a partial inclination change of the substrate P, or the like.

In the illumination unit ILU and the projection unit PLU as described above, since the projection region IAn needs to be inclined by the angle θk in the XY plane as shown in FIG. 3 above, the DMD 10 and the illumination unit PLU (at least an optical path portion of the mirror 102 to a mirror 112 along the optical axis AXc) in FIG. 4 are disposed to be inclined by the angle θk in the XY plane as a whole.

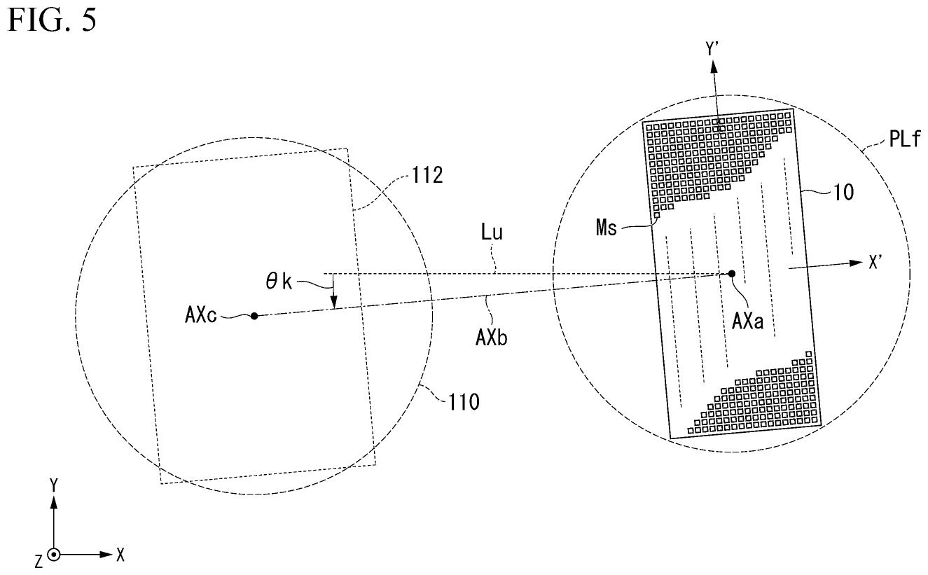

FIG. 5 is a view schematically showing a state in the XY plane in which the DMD 10 and the illumination unit PLU are inclined by the angle θk in the XY plane. In FIG. 5, the orthogonal coordinate system XYZ is the same as the coordinate system XYZ of each of FIG. 1 to FIG. 4 above, and an arrangement coordinate system X′Y′ of the micro mirrors Ms of the DMD 10 is the same as the coordinate system X′Y′ shown in FIG. 3. A circle that contains the DMD 10 is the image field PLf on an object surface side of the projection unit PLU, and the optical axis AXa is located on a center thereof. Meanwhile, the optical axis AXb where the optical axis AXc passing through the condenser lens system 110 of the illumination unit ILU is folded by the inclined mirror 112 is disposed to be inclined by the angle θk from a line Lu parallel to the X axis in the XY plane.

### (Image Forming Optical Path by DMD)

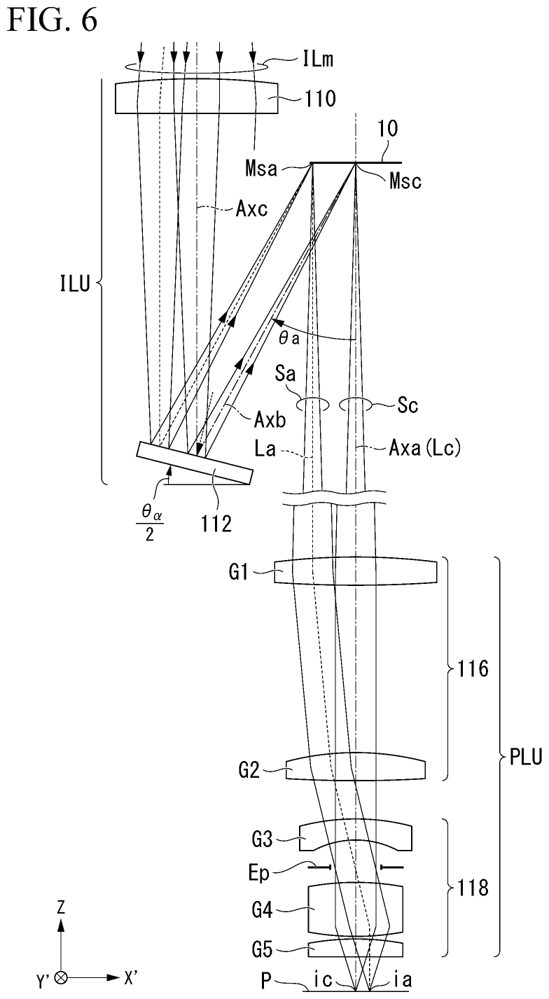

Next, an image forming state of the micro mirrors Ms of the DMD 10 by the projection unit PLU (image forming projection lens system) will be described in detail with reference to FIG. 6. The orthogonal coordinate system X′Y′Z of FIG. 6 is the same as the coordinate system X′Y′Z shown in FIG. 3 and FIG. 5 above, and FIG. 6 shows an optical path from the condenser lens system 110 of the illumination unit ILU to the substrate P. The illumination light ILm from the condenser lens system 110 advances along the optical axis AXc, is totally reflected by the inclined mirror 112, and reaches the mirror surface of the DMD 10 along the optical axis AXb. Here, the micro mirror Ms located at a center of the DMD 10 is referred to as Msc, the micro mirrors Ms located therearound are referred to as Msa, and the micro mirrors Msc and Msa are in an ON state.

When an inclination angle of the micro mirror Ms in an ON state is, for example, 17.5° as a standard value with respect to the X′Y′ plane (XY plane), in order to make each principal ray of reflected lights Sc and Sa from the micro mirrors Msc and Msa parallel to the optical axis AXa of the projection unit PLU, an incidence angle (an angle from the optical axis AXa of the optical axis AXb) θα of the illumination light ILm radiated to the DMD 10 is set to 35.0°. Accordingly, in this case, the reflecting surface of the inclined mirror 112 is also disposed to be inclined by 17.5° (=θα/2) with respect to the X′Y′ plane (XY plane). A principal ray Lc of the reflected light Sc from the micro mirrors Msc is coaxial with the optical axis AXa, a principal ray La of the reflected light Sa from the micro mirrors Msa is parallel to the optical axis AXa, and the reflected lights Sc and Sa enter the projection unit PLU according to a predetermined numerical aperture (NA).

A reduced image ic of the micro mirror Msc reduced by the projection magnification Mp of the projection unit PLU is formed on the substrate P at a position of the optical axis AXa in a telecentric state by the reflected light Sc. Similarly, a reduced image ia of the micro mirrors Msa reduced by the projection magnification Mp of the projection unit PLU is formed on the substrate P at a position away from the reduced image ic in the +X′ direction in a telecentric state by the reflected light Sa. As an example, the first lens system 116 of the projection units PLU is constituted by two lens groups G1 and G2, and the second lens system 118 is constituted by three lens groups G3, G4 and G5. An exit pupil (also simply referred to as a pupil) Ep is provided between the lens group G3 and the lens group G4 of the second lens system 118. Alight source image of the illumination light ILm (an aggregate of a plurality of point light sources formed on an emission surface side of the MFE lens 108A) is formed at a position of the pupil Ep, and configures Koehler illumination. The pupil Ep is also referred to as an opening of the projection unit PLU, and a size (diameter) of the opening is one of factors that define resolution of the projection unit PLU.

Regular reflected light from the micro mirrors Ms in an ON state of the DMD 10 is set to pass therethrough without being blocked by the maximum diameter (diameter) of the pupil Ep, and a numerical aperture NAi on an image side (the side of the substrate P) in an equation representing resolution R, R=k1·(λ/NAi), is determined by the maximum diameter of the pupil Ep and a distance of a rear (image side) focal point of the projection unit PLU (the lens groups G1 to G5 as the image forming projection lens system). In addition, a numerical aperture NAo on the side of the physical surface (the DMD 10) of the projection unit PLU (the lens groups G1 to G5) is expressed by a product of the projection magnification Mp and the numerical aperture NAi, and when the projection magnification Mp is ⅙, it becomes NAo=NAi/6.

In the configuration of the illumination unit ILU and the projection unit PLU shown in FIG. 6 and FIG. 4 above, an emission end of the optical fiber bundle FBn (n=1 to 27) connected to each module MUn (n=1 to 27) is set to an optical conjugation relation with an emission end side of the MFE lens 108A of the optical integrator 108 by the input lens system 104, and an incidence end side of the MFE lens 108A is set to an optical conjugation relation with a center of the mirror surface (neutral plane) of the DMD 10 by the condenser lens system 110. Accordingly, the illumination light ILm radiated to the entire mirror surface of the DMD 10 becomes a uniform illuminance distribution (for example, intensity irregularity within ±1%) due to an action of the optical integrator 108. In addition, an emission end side of the MFE lens 108A and a surface of the pupil Ep of the projection unit PLU are set to an optical conjugation relation by the condenser lens system 110 and the lens groups G1 to G3 of the projection unit PLU.

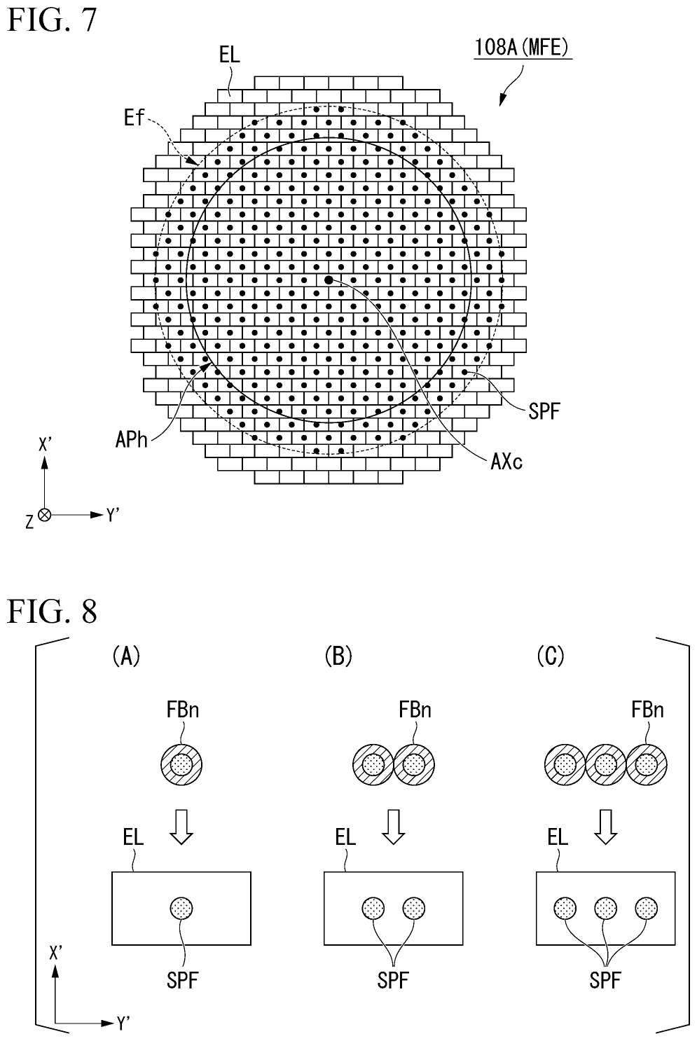

FIG. 7 is a schematic view showing the MFE lens 108A of the optical integrator 108 seen from an emission surface side. The MFE lens 108A has a cross-sectional shape similar to that of the entire mirror surface (image forming region) of the DMD 10, and is configured by densely arranging a plurality of lens elements EL having a rectangular cross-sectional shape extending in the Y′ direction in the X′Y′ plane in the X′ direction and the Y′ direction. The illumination light ILm from the input lens system 104 shown in FIG. 4 is radiated into a substantially circular irradiation region Ef on an incident surface side of the MFE lens 108A. The irradiation region Ef is a circular region using the optical axis AXc as a center by design with a shape similar to each emission end of a single or a plurality of optical fiber wires of the optical fiber bundle FB18 (FBn) in FIG. 4.

Point light sources SPF created by the illumination light ILm from the emission end of the optical fiber bundle FB18 (FBn) are densely distributed in a substantially circular region on the emission surface side of each of the lens elements EL located in the irradiation region Ef among the plurality of lens elements EL of the MFE lens 108A. In addition, a circular region APh in FIG. 7 represents an opening range when a variable opening diaphragm is provided on an emission surface side of the MFE lens 108A. The actual illumination light ILm is created by the plurality of point light sources SPF scattered in the circular region APh, and light from the point light sources SPF outside the circular region APh is blocked.

FIGS. 8(A), 8(B) and 8(C) are views schematically showing an example of an arrangement relation between the point light sources SPF formed on the emission surface side of the lens elements EL of the MFE lens 108A and the emission end of the optical fiber bundle FBn in FIG. 7. The coordinate system X′Y′ of each of FIGS. 8(A), 8(B) and 8(C) is the same as the coordinate system X′Y′ set in FIG. 7. FIG. 8(A) expresses a case in which the optical fiber bundle FBn is a single optical fiber wire, FIG. 8(B) expresses a case in which two optical fiber wires as the optical fiber bundle FBn are arranged in the X′ direction, and FIG. 8(C) expresses a case in which three optical fiber wires as the optical fiber bundle FBn are arranged in the X′ direction.

Since the emission end of the optical fiber bundle FBn and the emission surface of the MFE lens 108A (the lens elements EL) are set to an optical conjugation relation (image forming relation), when the optical fiber bundle FBn is the single optical fiber wire, as shown in FIG. 8(A), the single point light source SPF is formed at a center position of the emission surface side of the lens elements EL. When the two optical fiber wires are bundled in the X′ direction as the optical fiber bundle FBn, as shown in FIG. 8(B), a geometrical center of the two point light sources SPF is formed to become a center position of the emission surface side of the lens elements EL. Similarly, when the three optical fiber wires are bundled in the X′ direction as the optical fiber bundle FBn, as shown in FIG. 8(C), a geometrical center of the three point light sources SPF is formed to become a center position of the emission surface side of the lens elements EL.

Further, when power of the illumination light ILm from the optical fiber bundle FBn is large and the point light sources SPF are condensed to the emission surface of each of the lens elements EL of the MFE lens 108A as the surface light source member or the optical integrator, damage (cloudiness, burning, or the like) may be applied to each of the lens elements EL. In this case, the condensing position of the point light sources SPF may be set in a space slightly deviated outward from the emission surface of the MFE lens 108A (the emission surface of the lens elements EL). In this way, a configuration in which a position of a point light source (focusing point) is deviated outward from the lens element in an illumination system using a fly's eye lens is disclosed in, for example, U.S. Pat. No. 4,939,630.

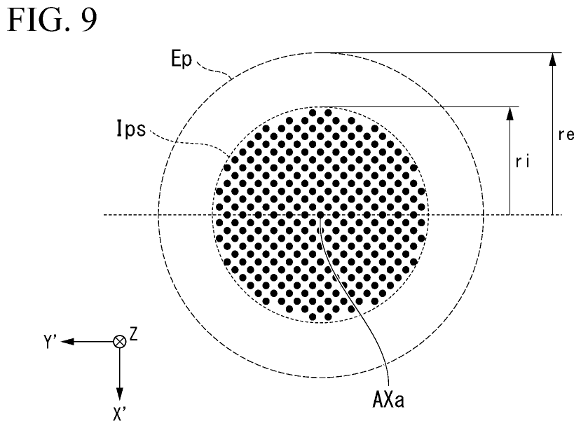

FIG. 9 is a view schematically showing an aspect of a light source image Ips formed on the pupil Ep in the second lens system 118 of the projection unit PL in FIG. 6 when it is assumed that the planar mirror is inclined by an angle θα/2 to be parallel to the inclined mirror 112 in FIG. 6 using the entire mirror surface of the DMD 10 as a single planar mirror. The light source image Ips shown in FIG. 9 is an image obtained by forming the plurality of point light sources SPF (becoming the surface light source aggregated in a substantially circular shape) formed on the emission surface side of the MFE lens 108A again. In this case, diffraction light or scattered light is not generated from the single planar mirror disposed instead of the DMD 10, and only the light source image Ips is generated at the center in the pupil Ep coaxially with the optical axis AXa using only the regular reflected light (zero order light).

In FIG. 9, when a radius corresponding to the maximum diameter of the pupil Ep is referred to as re and a radius corresponding to an effective diameter of the light source image Ips as the surface light source is referred to as ri, a σ value representing a size (area) of the light source image Ips with respect to the size (area) of the pupil Ep is σ=ri/re. The a value is appropriately changed in order to improve a line width, a concentration degree, or a depth of focus (DOF) of the projected and exposed pattern. The σ value can be changed by providing a variable opening diaphragm (the circular region APh in FIG. 7) at a position of the emission surface side of the MFE lens 108A or a position of the pupil Ep in the second lens system 118.

In this type of exposure apparatus EX, since the pupil Ep in the second lens system 118 is often used with its maximum diameter, change of the σ value is mainly performed by the variable opening diaphragm provided on the emission surface side of the MFE lens 108A. In this case, the radius ri of the light source image Ips is defined as a radius of the circular region APh in FIG. 7. Of course, the σ value or the depth of focus (DOF) may be adjusted by providing the variable opening diaphragm on the pupil Ep of the projection unit PLU.

### (Telecentric Error Upon Projection Exposure)

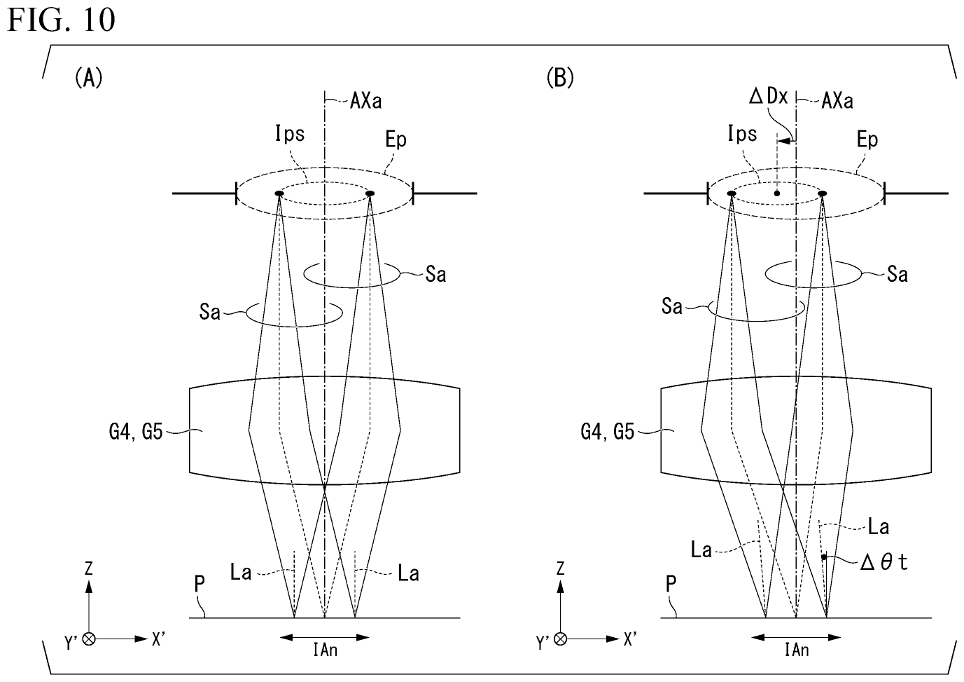

Next, while a telecentric error that may occur in the case of the exposure apparatus EX using the DMD 10 like the embodiment will be described, one of generation factors of the telecentric error will be simply described with reference to FIG. 10 in advance. FIGS. 10(A) and 10(B) are views schematically showing a behavior of the illumination light (image forming light flux) Sa of the optical path from the pupil Ep of the second lens group 118 to the substrate P shown in FIG. 6. The orthogonal coordinate system X′Y′Z in FIGS. 10(A) and 10(B) is the same as the coordinate system X′Y′Z of FIG. 6. For the purpose of simple description, here, a case in which the entire mirror surface of the DMD 10 is inclined by the angle θα/2 parallel to the inclined mirror 112 in FIG. 6 as a single planar mirror is assumed. In FIGS. 10(A) and 10(B), the lens groups G4 and G5 are disposed along the optical axis AXa between the pupil Ep and the substrate P, and a circular light source image (surface light source image) Ips is formed in the pupil Ep as shown in FIG. 9. Further, a principal ray of the reflected light (image forming light flux) Sa entering the lens groups G4 and G5 through one point of a peripheral portion of the light source image (surface light source image) Ips in the X′ direction is La.

FIG. 10(A) shows a behavior of the reflected light (image forming light flux) Sa when the light source image (surface light source image) Ips is accurately located at a center of the pupil Ep, the principal ray La of the reflected light (image forming light flux) Sa toward one point in the projection region IAn on the substrate P is parallel to the optical axis AXa, and the image forming light flux projected to the projection region IAn is in a state in a telecentric state, i.e., a state in which the telecentric error is zero. On the other hand, FIG. 10(B) shows a behavior of the reflected light (image forming light flux) Sa when the light source image (surface light source image) Ips is laterally shifted by ΔDx in the X′ direction from the center of the pupil Ep. In this case, the principal ray La of the reflected light (image forming light flux) Sa toward one point in the projection region IAn on the substrate P is inclined by Δθt with respect to the optical axis AXa. The inclination quantity Δθt is the telecentric error, the inclination quantity Δθt (i.e., a lateral shift quantity ΔDx) is greater than a predetermined allowance, and thus, the image forming state of the pattern image projected to the projection region IAn is decreased.

### (Configuration of DMD)

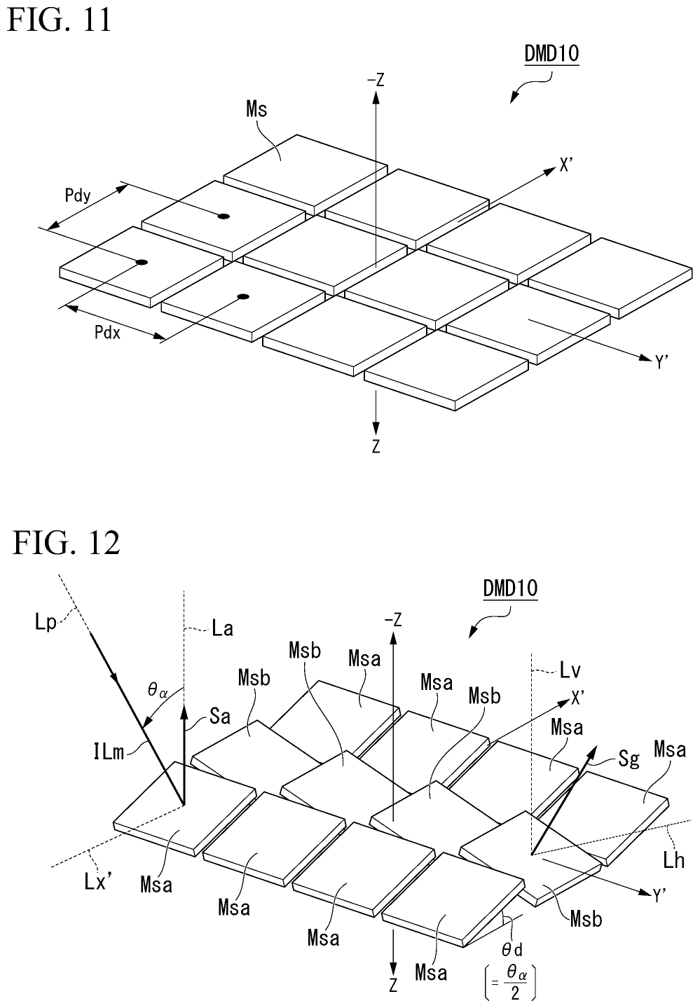

As described above, while the DMD 10 used in the embodiment is a roll and pitch driving type, a specific configuration thereof will be described with reference to FIG. 11 and FIG. 12. FIG. 11 and FIG. 12 are partially enlarged perspective view of the mirror surface of the DMD 10. Again, the orthogonal coordinate system X′Y′Z is the same as the coordinate system X′Y′Z in FIG. 6 above. FIG. 11 shows a state when a power supply to the driving circuit provided on a lower layer of each of the micro mirrors Ms of the DMD 10 is off. When the power supply is in an OFF state, the reflecting surface of each of the micro mirrors Ms is set to be parallel to the X′Y′ plane. Here, while an arrangement pitch of the micro mirrors Ms in the X′ direction is Pdx (μm) and an arrangement pitch in the Y′ direction is Pdy (μm), in practice, it is set to Pdx=Pdy.

FIG. 12 shows an aspect in which power supply to the driving circuit is on and the micro mirrors Msa in the ON state and the micro mirrors Msb in the OFF state are mixed. In the embodiment, the micro mirrors Msa in the ON state are driven to be inclined by the angle θd (=θα/2) from the X′Y′ plane around a line parallel to the Y′ axis, and the micro mirrors Msb in the OFF state are driven to be inclined by the angle θd (=θα/2) from the X′Y′ plane around a line parallel to the X′ axis. The illumination light ILm is radiated to each of the micro mirrors Msa and Msb along a principal ray Lp parallel to the X′Z plane (parallel to the optical axis AXb shown in FIG. 6). Further, the line Lx′ in FIG. 11 is obtained by projecting the principal ray Lp to the X′Y′ plane and is parallel to the X′ axis.

The incidence angle θα of the illumination light ILm to the DMD 10 is an inclination angle with respect to the Z axis in the X′Z plane, and the reflected light (image forming light flux) Sa that advances substantially parallel to the Z axis in the −Z direction is generated from the micro mirrors Msa in the ON state inclined by the angle θα/2 in the X′ direction from a geometrical optical point of view. Meanwhile, the reflected light Sg reflected by the micro mirrors Msb in the OFF state is generated in the −Z direction in a state non-parallel to the Z axis because the micro mirrors Msb are inclined in the Y′ direction. In FIG. 12, when a line Lv is a line parallel to the Z axis (the optical axis AXa) and a line Lh projects to the X′Y′ plane of the principal ray of the reflected light Sg, the reflected light Sg advances in a direction inclined in a surface containing the line Lv and the line Lh.

### (Image Forming State by DMD)

In the projection exposure using the DMD 10, the pattern exposure is performed by scanning the substrate P in the X direction at a speed corresponding to a switching speed while rapidly switching each of a plurality of micro mirrors Ms between an inclination in an ON state and an inclination in an OFF state on the basis of the pattern data (drawing data) using the operation shown in FIG. 12. However, the telecentric state (telecentricity) of the image forming light flux projected from the projection unit PLU (the first lens group 116 and the second lens group 118) to the substrate P may be changed according to fineness, concentration degree or periodicity of the projected pattern. This is because the mirror surface of the DMD 10 is used as a reflective diffraction grating (brazed diffraction grating) according to an inclined state corresponding to the pattern of the plurality of micro mirrors Ms of the DMD 10.

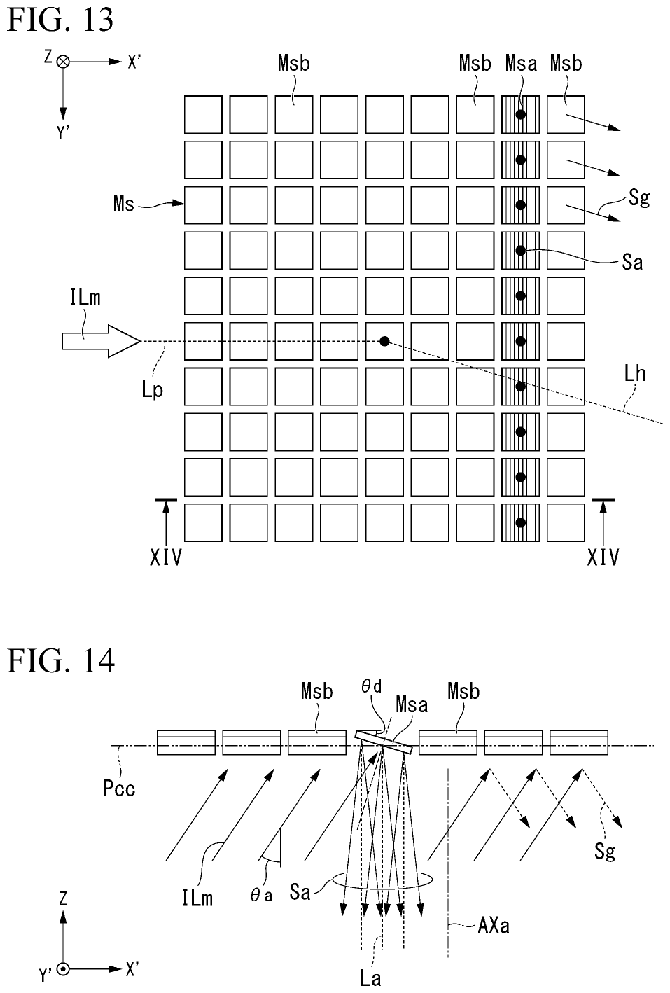

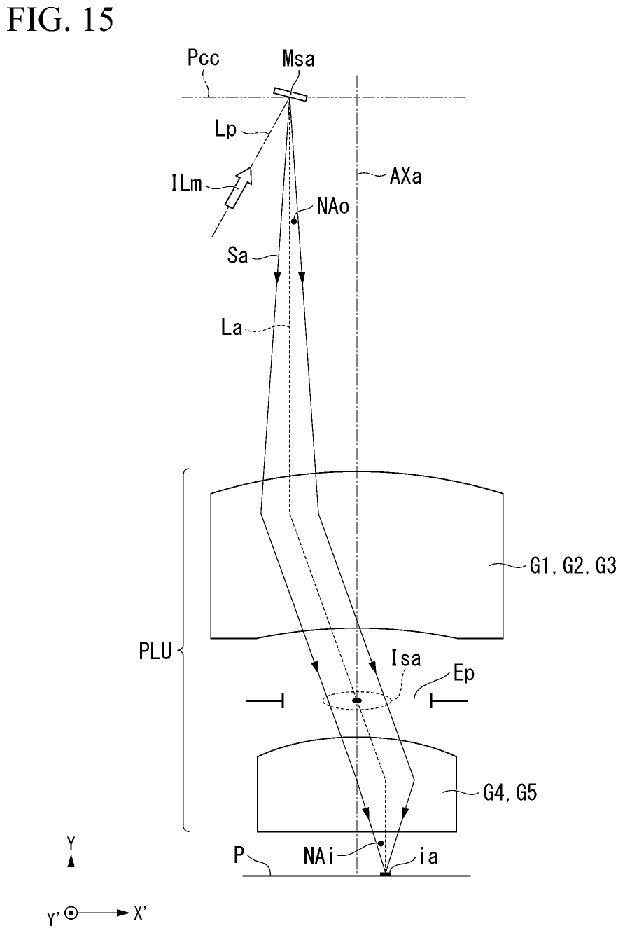

FIG. 13 is a view showing a part of the mirror surface of the DMD 10 in the X′Y′ plane, and FIG. 14 is a view showing a portion of the mirror surface of the DMD 10 of FIG. 13 along an arrow XIV-XIV in the X′Z plane. In FIG. 13, in the plurality of micro mirrors Ms, only the micro mirrors Ms in a row arranged in the Y′ direction are the micro mirrors Msa in the ON state, and the other micro mirrors Ms are the micro mirrors Msb in the OFF state. The inclined state of the micro mirrors Ms shown in FIG. 13 is appeared when an isolated line pattern of the line width (for example, about 1 μm) of the resolution limit is projected. In the X′Y′ plane, the reflected light (image forming light flux) Sa from the micro mirrors Msa in the ON state is generated parallel to the Z axis in the −Z direction, and the reflected light Sg from the micro mirrors Msb in the OFF state is generated in the −Z direction but inclined in a direction along the line Lh in FIG. 11.

In this case, as shown in FIG. 14, only one of the plurality of micro mirrors Ms arranged in the X′ direction is the micro mirror Msa in the ON state inclined by the angle θd (=θα/2) around a line parallel to the Y′ axis with respect to the neutral plane Pcc (a surface parallel to the X′Y′ plane containing the center point of all the micro mirrors Ms). Accordingly, in the X′Z plane, the reflected light (image forming light flux) Sa generated from the micro mirrors Msa in the ON state becomes a simple regular reflected light that does not contain diffraction light of one order or more, and the principal ray La enters the projection unit PLU parallel to the optical axis AXa. The other reflected light Sg from the micro mirrors Msb in the OFF state does not enter the projection unit PLU. Further, when the micro mirror Msa in the ON state is one isolated in the X′ direction (or a row arranged in the Y′ direction), the principal ray La of the reflected light (image forming light flux) Sa becomes parallel to the optical axis AXa, regardless of a wavelength λ of the illumination light ILm.

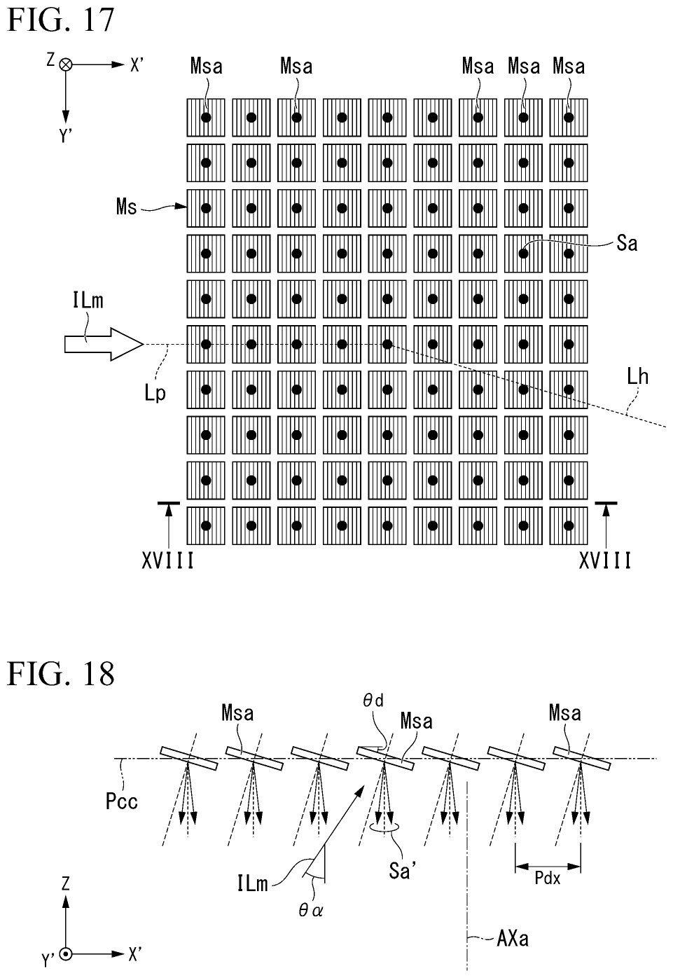

FIG. 15 is a view schematically showing an image forming state by the projection unit PLU of the reflected light (image forming light flux) Sa from the micro mirrors Msa isolated as shown in FIG. 14 in the X′Z plane. In FIG. 15, the member having the same function as the member described in FIG. 6 above is designated by the same reference sign. Since the projection unit PLU (the lens groups G1 to G5) is a bilateral telecentric reduction projection system, if the principal ray La of the reflected light (image forming light flux) Sa from the isolated micro mirrors Msa is parallel to the optical axis AXa, the principal ray La of the reflected light (image forming light flux) Sa formed as the reduced image ia is also parallel to a line (the optical axis AXa) perpendicular to the surface of the substrate P, and a telecentric error does not occur. Further, the numerical aperture NAo of the reflected light (image forming light flux) Sa on the object surface side (the DMD 10) of the projection unit PLU shown in FIG. 18 is equal to the numerical aperture of the illumination light ILm.

As described above in FIG. 9 and FIG. 10(A) above, when the DMD 10 is inclined by the angle θα/2 as a single large planar mirror, a center position of the circular light source image (surface light source image) Ips formed on the pupil Ep of the projection units PLU passes through the optical axis AXa. Similarly, when only the regular reflected light Sa from the isolated micro mirrors Msa in the mirror surface of the DMD 10 enters the projection unit PLU, since the point image intensity distribution of the light flux Isa at the position (Fourier conversion surface) of the pupil Ep of the regular reflected light Sa is a rectangular shape (square shape) in which the reflecting surface of the micro mirror Ms is fine, the optical axis AXa is expressed by a sin c2 function (a point image intensity distribution of a square opening) as a center.

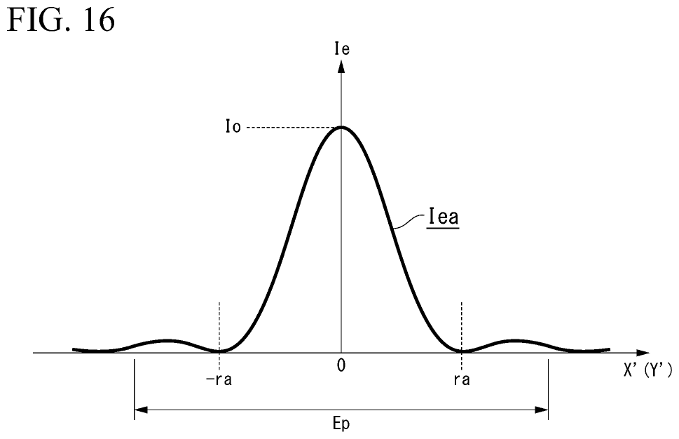

FIG. 16 is a graph schematically expressing a theoretical point image intensity distribution lea (distribution created by light flux from the one point light source SPF shown in FIG. 7 and FIG. 8) of the light flux (here, zero order diffraction light) Isa in the pupil Ep by the reflected light Sa from the row of (or single) micro mirrors Msa isolated in the X′ direction. In the graph of FIG. 16, a lateral axis represents a coordinate position in the X′ (or Y′) direction as the position of the optical axis AXa, and a vertical axis represents a light intensity Ie. The point image intensity distribution lea is expressed by the following Equation (1).

$$\begin{matrix}[ Math . 1 ] & \\ {Ie = Io \cdot sin {c}^{2} ( X ’ ) = Io \cdot {sin}^{2} ( X ’ ) / ( X ’ )}^{2} & ( 1 )\end{matrix}$$

In the above-mentioned Equation (1), Io expresses a peak value of the light intensity Je, and a position of the peak value Io by the reflected light Sa from the row of (or single) isolated micro mirrors Msa coincides with an origin 0 in the X′ (or Y′) direction, i.e., a position of the optical axis AXa. In addition, a position ±ra in the X′ (or Y′) direction of a first dark line on which the light intensity Ie of the point image intensity distribution lea initially becomes a minimum value (0) from the origin 0 corresponds to a position of the radius ri of the light source image Ips described in FIG. 9 above. Further, the actual intensity distribution on the pupil Ep is obtained by convolution-integrating (convolution-calculating) the point image intensity distribution lea throughout a wide range (σ value) of the light source image Ips shown in FIG. 9, and the intensity is approximately uniform.

Next, a case in which a width of the projected pattern in the X′ direction (X direction) is sufficiently large will be described with reference to FIG. 17 and FIG. 18. FIG. 17 is a view showing a part of the mirror surface of the DMD 10 in the X′Y′ plane, and FIG. 18 is a view showing a portion of the mirror surface of the DMD 10 of FIG. 17 along an arrow XVII-XVII in the X′Z plane. FIG. 17 shows a case in which all the plurality of micro mirrors Ms shown in FIG. 13 above become the micro mirrors Msa in the ON state. In FIG. 17, while only disposition of the micro mirrors Ms of nine in the X′ direction and ten in the Y′ direction is shown, the adjacent micro mirrors Ms of the above-mentioned number or more (or preferably all the micro mirrors Ms on the DMD 10) may be in an ON state.

As shown in FIG. 17 and FIG. 18, the reflected light Sa′ is generated from the plurality of micro mirrors Msa in the ON state arranged adjacent to each other in the X′ direction by a diffraction effect in a state slightly inclined from the optical axis AXa. When the mirror surface of the DMD 10 in the state of FIG. 18 is considered as diffraction gratings arranged at a pitch Pdx in the X′ direction along the neutral plane Pcc, a generation angle θj of the diffraction light is expressed by the following Equation (2) when j is an order (j=0, 1, 2, 3, . . . ), λ is a wavelength and an incidence angle of the illumination light ILm is θα.

$$\begin{matrix}[ Math . 2 ] & \\ sin θ j = j ( λ / Pdx ) - sin θα & ( 2 )\end{matrix}$$

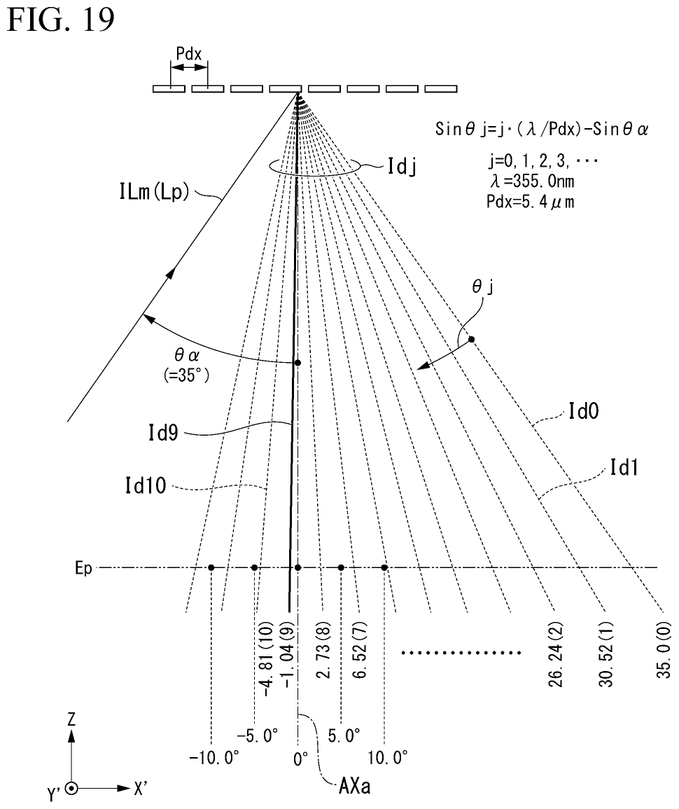

FIG. 19 is a graph expressing a distribution of an angle θj of diffraction light Idj calculated, for example, when the incidence angle θα of the illumination light ILm (an inclination angle of the principal ray Lp of the illumination light ILm with respect to the optical axis AXa) is 35.0°, the inclination angle θd of the micro mirrors Msa in the ON state is 17.5°, the pitch Pdx of the micro mirrors Msa is 5.4 μm, and a wavelength λ is 355.0 nm. As shown in FIG. 19, since the incidence angle θα of the illumination light ILm is 35°, zero order diffraction light Id0 (j=0) is inclined at +35° with respect to the optical axis AXa, and as the diffraction order increases, the angle θj with respect to the zero order diffraction light Id0 increases. A numerical value shown in a lower portion of FIG. 19 expresses the order j in a parenthesis and an inclination angle from the optical axis AXa of the diffraction light Idj of each order.

In the case of the numerical condition of FIG. 19, an inclination angle of 9-order diffraction light Id9 from the optical axis AXa is the smallest, approximately −1.04°. Accordingly, when the micro mirrors Ms of the DMD 10 are densely disposed and in the ON state as shown in FIG. 17 and FIG. 18, a center of the intensity distribution of the image forming light flux (Sa′) in the pupil EP of the projection unit PLU is eccentric from a position laterally shifted by an amount equivalent to an angle of −1.04° from the position of the optical axis AXa (equivalent to a lateral shift quantity ΔDx shown in FIG. 10(B) above). The distribution of the actual image forming light flux in the pupil Ep is obtained by convolution-integrating (convolution-calculating) the diffraction light distribution expressed by Equation (2) using the sin c2 function expressed by Equation (1).

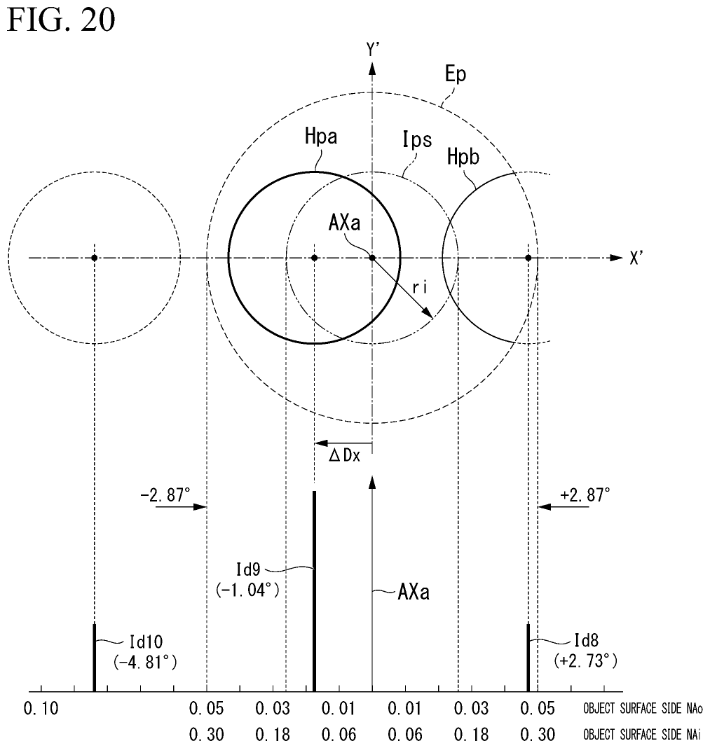

FIG. 20 is a view schematically showing the intensity distribution of the image forming light flux Sa′ in the pupil Ep in the generation state of the diffraction light as shown in FIG. 19. A lateral axis in FIG. 20 represents σ value obtained by converting the angle θj of the diffraction light Idj into the numerical aperture NAo on the side of the physical surface (the DMD 10) and the numerical aperture NAi on the side of the image surface (the substrate P) when the projection magnification Mp of the projection unit PLU is ⅙. In addition, the numerical aperture NAi on the image surface side of the projection unit PLU is assumed as 0.3 (the numerical aperture NAo on the object surface side=0.05). In this case, the resolution (minimum resolution line width) Rs is expressed by Rs=k1 (λ/NAi) using a process constant k1 (0<k1≤1).

Accordingly, the resolution Rs is about 0.83 μm when a wavelength λ=355.0 nm and k1=0.7. The pitch Pdx (Pdy) of the micro mirrors Ms is reduced by the projection magnification Mp=⅙ on the side of the image surface (the substrate P) and becomes 0.9 μm. Accordingly, if the projection unit PLU has the numerical aperture NAi on the image surface side of 0.3 (the numerical aperture NAo on the object surface side is 0.05) or more, one projection image of the micro mirrors Msa in the ON state can be formed with high contrast.

In FIG. 20, an angle θe from the optical axis AXa in the X′ direction of the numerical aperture NAo=0.05 on the object surface side, which is the maximum diameter of the pupil Ep of the projection unit PLU, becomes θe≈±2.87° from NAo=sin θe. As shown in FIG. 19 above, the inclination angle of −1.04° (accurately, −1.037°) of the 9-order diffraction light Id9 is about 0.018 when being converted into the numerical aperture NAo on the object surface side, and an intensity distribution Hpa of the image forming light flux Sa′ (regular reflected light ingredient) in the pupil Ep is displaced by a shift amount ΔDx in the X′ direction from the original position of the light source image Ips (radius ri). Further, while a part of an intensity distribution Hpb by an 8-order diffraction light Id8 is appeared in a periphery of the pupil Ep in the +X′ direction, the peak intensity is low. Further, since an inclination angle of a 10-order diffraction light Id10 on the object surface side from the optical axis AXa is large at 4.81°, the intensity distribution is disposed outside the pupil Ep and does not pass through the projection unit PLU.

As described also in FIG. 10(B) above, a telecentric error Δθt on the image surface side occurred by the shift amount ΔDx of the center of the intensity distribution Hpa becomes Δθt=−6.22° (=−1.037°/the projection magnification Mp) in the case of a condition shown in FIG. 19 and FIG. 20. In this way, when exposing a large pattern in which many of the plurality of micro mirrors Ms of the DMD 10 are densely in the ON state, the principal ray of the image forming light flux (Sa′) to the substrate P is directed as being inclined by 6° or more with respect to the optical axis AXa. Such a telecentric error Δθt may also play a role in reducing the image forming quality (contrast characteristics, distortion characteristics, symmetric properties, or the like) of the projection image.

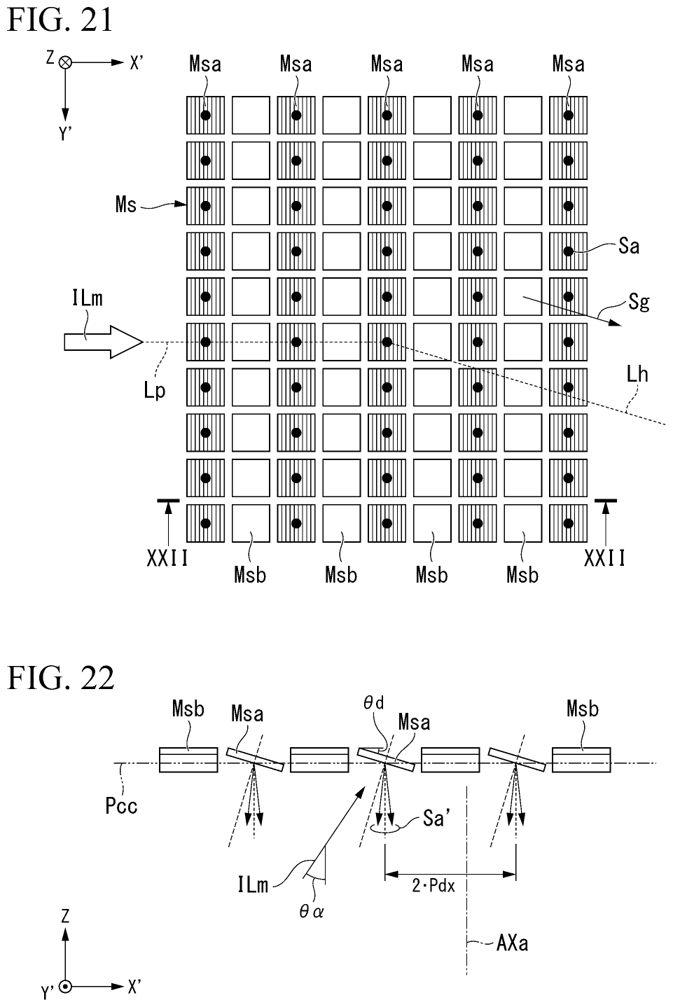

Next, a case of a line and space pattern in which a projected pattern has a constant pitch in the X′ direction (X direction) will be described with reference to FIG. 21 and FIG. 22. FIG. 21 is a view showing a part of the mirror surface of the DMD 10 in the X′Y′ plane, and FIG. 22 is a view showing a portion of the mirror surface of the DMD 10 of FIG. 21 along an arrow XXII-XXII in the X′Z plane. FIG. 21 shows a case in which, among the plurality of micro mirrors Ms shown in FIG. 13 above, the micro mirrors Ms of odd numbers arranged in the X′ direction are the micro mirrors Msa in the ON state, and the micro mirrors Ms of even numbers are the micro mirrors Msb in the OFF state. It is assumed that the micro mirrors Ms of the odd numbers in the X′ direction are all in the ON state for one row in the Y′ direction, and the micro mirrors Ms of the even numbers are all in the OFF state for one row in the Y′ direction.

As shown in FIG. 22, when the micro mirrors Msa in the ON state are arranged one by one in the X′ direction, the generation angle θj of the diffraction light generated from the DMD 10 is expressed by the following Equation (3) similar to Equation (2) above by considering the mirror surface of the DMD 10 as the diffraction gratings arranged at a pitch 2·Pdx along the neutral plane Pcc in the X′ direction.

$$\begin{matrix}[ Math . 3 ] & \\ sin θ j = j ( λ / 2 Pdx ) - sin θα & ( 3 )\end{matrix}$$

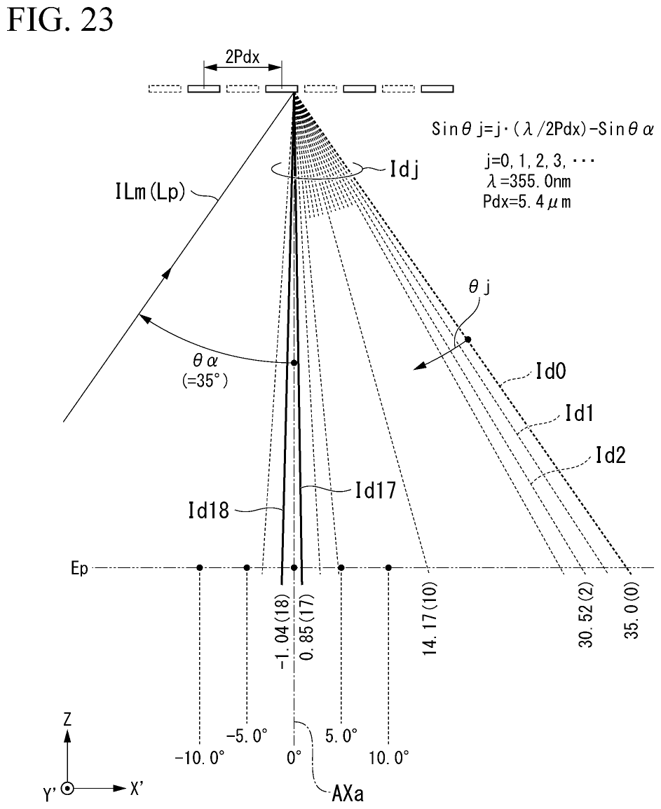

Like the case of FIG. 19, FIG. 23 is a graph expressing a distribution of the angle θj of the diffraction light Idj calculated when the incidence angle θα of the illumination light ILm (an inclination angle of the principal ray Lp of the illumination light ILm with respect to the optical axis AXa) is 35.0°, the inclination angle θd of the micro mirrors Msa in the ON state is 17.5°, a pitch 2Pdx of the micro mirrors Msa is 10.8 μm, and a wavelength λ is 355.0 nm. As shown in FIG. 23, since the incidence angle θα of the illumination light ILm is 35°, the zero order diffraction light Id0 (j=0) is inclined at +350 with respect to the optical axis AXa, and the angle θj with respect to the zero order diffraction light Id0 is increased as the diffraction order is increased. Numerical values shown in a lower portion of FIG. 23 express the order j in parentheses, and an inclination angle of the diffraction light Idj of each order from the optical axis AXa.

In the case of the numerical condition of FIG. 23, an inclination angle of 17-order diffraction light Id17 from the optical axis AXa is the smallest, approximately 0.85°. Further, 18-order diffraction light Id18 with an inclination angle of −1.04° from the optical axis AXa is also generated. Accordingly, as shown in FIG. 21 and FIG. 22, when the micro mirrors Ms of the DMD 10 are in the finest line and space shape in the ON state, a center of the intensity distribution of the image forming light flux (Sa′) in the pupil EP of the projection unit PLU is eccentric from a position laterally shifted by an amount equivalent to an angle of 0.850 or −1.04° from the position of the optical axis AXa. The distribution of the actual image forming light flux (Sa′) in the pupil Ep can be obtained by convolution-integrating (convolution-calculating) the diffraction light distribution expressed by Equation (3) using the sin c2 function expressed by Equation (1).

Like FIG. 20 above, also in the case of FIG. 23, the intensity distribution Hpa of the image forming light flux (regular reflected light ingredient) in the pupil Ep is displaced and appeared in the X′ direction from the original position of the light source image Ips (radius ri) to correspond to each of an inclination angle of 0.85° of the 17-order diffraction light Id17 and an inclination angle of −1.04° of the 18-order diffraction light Id18. In the case of the diffraction light distribution as shown in FIG. 23, since one of the intensity distribution Hpa formed in the direction of the 17-order diffraction light Id17 and the intensity distribution Hpa formed in the direction of the 18-order diffraction light Id18 is large and the other is small, the telecentric error Δθt on the image surface side occurred by the shift of the intensity distribution Hpa is substantially within a range between Δθt=5.10 and Δθt=−6.22°.

This range is slightly different from the telecentric error Δθt=−6.22° in the generation direction of the 9-order diffraction light Id9 (see FIG. 19) when the plurality of micro mirrors Ms are adjacent to each other to become the micro mirrors Msa in the ON state as shown in FIG. 17 and FIG. 18 above. Further, it is very different compared 5 to the telecentric error Δθt=0° when a row of (or a single) the plurality of micro mirrors Ms as shown in FIG. 13 and FIG. 14 above are isolated as the micro mirrors Msa in the ON state. Further, the actual pattern image projected onto the substrate P by the projection unit PLU is formed by the interference of the reflected light Sa′ containing the diffraction light from the DMD 10 captured in the projection unit PLU. Further, Equation (3) can specify a generation state of the diffraction light in the line and space pattern in which an arrangement pitch or a line width is n times the Pdx (5.4 μm) using the following Equation (4) in which n is a real number.

$$\begin{matrix}[ Math . 4 ] & \\ sin θ j = j ( λ / ( n \cdot Pdx ) ) - sin θα & ( 4 )\end{matrix}$$

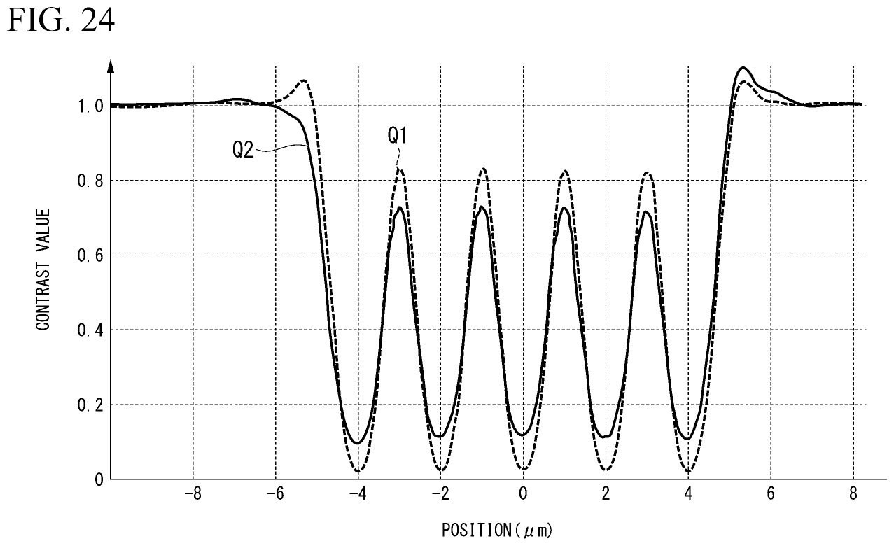

In this way, even when many of the plurality of micro mirrors Ms of the DMD 10 are disposed in the line and space shape in an ON state, the principal ray of the image forming light flux to the substrate P may be largely inclined with respect to the optical axis AXa, and image forming quality (contrast characteristics, distortion characteristics, or the like) of the projection image may be significantly deteriorated. Here, an example of a change in image forming quality due to generation of the telecentric error Δθt will be described with reference to FIG. 24. FIG. 24 is a graph expressing a result obtained by simulating a spatial image of a line and space pattern in which a line width on an image surface is 1 μm and a pitch in the X′ direction is 2 μm. A lateral axis of FIG. 24 represents a position (μm) on the image surface in the X′ direction, and a vertical axis represents a relative intensity value with the intensity of the illumination light (incidence light) normalized to 1.

In the graph of FIG. 24, the simulation is performed assuming that the numerical aperture NAi of the image side of the projection unit PLU is 0.25, a σ value of the illumination light ILm is 0.6, the image forming light flux (Sa′) in the pupil Ep of the projection unit PLU is eccentric from the optical axis AXa in the X′ direction, and the telecentric error Δθt on the image surface side becomes 50 mrad (≈2.865°). In the graph of FIG. 24, characteristics Q1 shown by a broken line are contrast characteristics in the best focus surface (best image forming surface) of the projection unit PLU, and characteristics Q2 shown by a solid line are contrast characteristics in a surface defocused by 3 μm from the best focus surface in a direction of the optical axis AXa. Further, in FIG. 24, dark lines with a line width of 1 μm are formed at five places of positions 0, ±2 μm, and ±4 μm.

It is typical that the contrast (intensity amplitude) of the characteristics Q2 is lower than the characteristics Q1 due to defocus, but it is determined that, due to the influence of the telecentric error Δθt, a symmetric property between the characteristics around +5 μm and the characteristics around −5 μm is deteriorated. From this, in the case of the pattern in which the telecentric error Δθt on the image surface side exceeds an allowable limit (for example, ±2°), i.e., when the micro mirrors Msa in the ON state among the plurality of micro mirrors Ms of the DMD 10 are densely disposed in a wide range or arranged with periodicity, the accuracy of the edge position of the resist image corresponding to the edge portion of the exposed pattern is lost, and as a result, errors occur in the line width or dimension of the pattern. That is, as the intensity distribution (distribution of the diffraction light) formed on the pupil Ep of the projection unit PLU by the reflected light (image forming light flux) Sa′ from the DMD 10 is deviated from an isotropic state centered on the optical axis AXa or a symmetrical state, an asymmetric property of the projected pattern image is increased.

### (Wavelength Dependency of Telecentric Error)

The telecentric error Δθt described above changes depending on the wavelength λ as is apparent from Equation (2) to Equation (3) above. For example, in the case of the state of FIG. 17 and FIG. 18 expressed by Equation (2), in order to make the telecentric error Δθt on the image surface side zero, the wavelength λ may be set such that the inclination angle of −1.04° (accurately, −1.037) from the optical axis AXa of the 9-order diffraction light Id9 shown in FIG. 19 and FIG. 20 becomes zero.

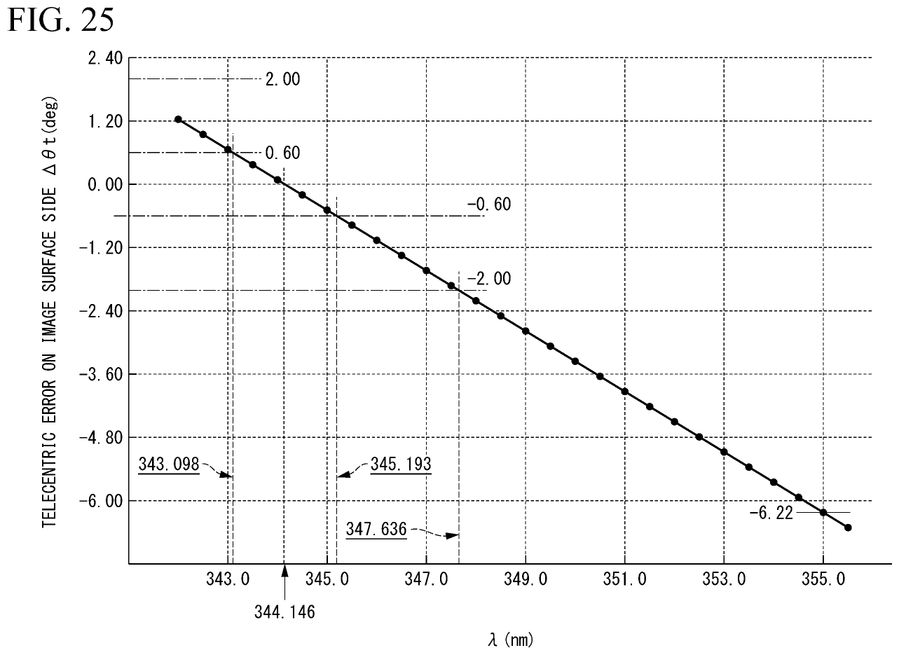

FIG. 25 is a graph in which a relation between a center wavelength λ and a telecentric error Δθt is obtained on the basis of the above-mentioned Equation (2), a lateral axis represents the center wavelength λ (nm), and a vertical axis represents the telecentric error Δθt (deg) on the image surface side. The pitch Pdx (Pdy) of the micro mirrors Ms of the DMD 10 is 5.4 μm, the inclination angle θd of the micro mirrors Ms is 17.5°, the incidence angle θα of the illumination light ILm is 35°, and in the case in which the micro mirrors Ms are dense in the ON state as shown in FIG. 17 and FIG. 18, the telecentric error Δθt theoretically becomes zero when the center wavelength λ is approximately 344.146 nm. The telecentric error Δθt on the image surface side is preferably set to zero as much as possible, but it can have an allowable limit depending on the minimum line width (or the resolution Rs) of the pattern to be projected.

For example, when the allowable limit of the telecentric error Δθt on the image surface side is set to within ±0.6° (approximately 10 mrad) as shown in FIG. 25, the center wavelength λ may be in the range of 343.098 nm to 345.193 nm (with a width of 2.095 nm). In addition, when the allowable limit of the telecentric error Δθt on the image surface side is set to within ±2.0°, the center wavelength λ may be in the range of 340.655 nm to 347.636 nm (with a width of 6.98 nm).

In this way, the telecentric error Δθt occurred due to arrangement (periodicity) or a concentration degree of the micro mirrors Msa in the ON state of the DMD 10, i.e., the size of the distribution density also has wavelength dependency. In general, since specifications of the pitch Pdx (Pdy), the inclination angle θd, or the like, of the micro mirrors Ms of the DMD 10 are uniquely set for a ready-made product (for example, a DMD compatible with ultraviolet ray manufactured by Texas Instrument), the wavelength λ of the illumination light ILm is set to match the specifications. In the DMD 10 of this embodiment, since the pitch Pdx (Pdy) of the micro mirrors Ms is 5.4 μm and the inclination angle θd is 17.5°, it is preferable to use a fiber amplifier laser light source that generates high brightness ultraviolet pulse light as a light source that supplies the illumination light ILm to each of the optical fiber bundles FBn (n=1 to 27).

The fiber amplifier laser light source is constituted by, for example, as disclosed in Japanese Patent No. 6428675, a semiconductor laser element configured to generate seed light in an infrared wavelength region, a high speed switching element (electric optical element or the like) of the seed light, an optical fiber configured to amplify the switched seed light using a pump beam, a wavelength conversion element configured to convert the light in the amplified infrared wavelength region into pulse light of a high frequency (ultraviolet wavelength region), and the like. In the case of such a fiber amplifier laser light source, a peak wavelength of the ultraviolet ray that can increase generation efficiency (conversion efficiency) by combining available semiconductor laser elements, optical fibers and wavelength conversion elements is 343.333 nm. In the case of the peak wavelength, the maximum telecentric error Δθt on the image surface side (the inclination angle on the image surface side of the 9-order diffraction light Id9 in FIG. 19 and FIG. 20) that can be generated in the state of FIG. 17 is about 0.466° (about 8.13 mrad).

From the above, as disclosed in Patent Document 1 in the related art, when two lights with significantly different peak wavelengths (for example, lights with wavelengths of 375 nm and 405 nm) are synthesized as the illumination light ILm, the telecentric error Δθt can vary greatly depending on the form of the pattern to be projected (an isolation pattern, a line and space pattern, or a large land-like pattern). In the embodiment, as the illumination light ILm supplied to each of the modules MUn (n=1 to 27), light synthesized from a plurality of fiber amplifier laser light sources whose peak wavelength is slightly shifted within the range where the wavelength-dependent telecentric error Δθt is allowed is used. In this way, by using the illumination light ILm obtained by synthesizing the plurality of lights with a slightly shifted peak wavelength, the coherence of the illumination light ILm can suppress the contrast of speckles (or interference fringes) generated on the micro mirrors Ms of the DMD 10 (as well as on the substrate P). Details thereof will be described below.

### (Telecentric Adjustment Mechanism)

As described above, when the micro mirrors Msa that become the ON state according to the pattern to be exposed to the substrate P among the plurality of micro mirrors Ms of the DMD 10 are densely arranged in the X′ direction and the Y′ direction, or when arranged with periodicity in the X′ direction (or the Y′ direction), the telecentric error (angular variation) At occurs, although there are varying degrees, in the image forming light flux (Sa, Sa′) projected from the projection unit PLU. Since each of the plurality of micro mirrors Ms of the DMD 10 can be switched between the ON state and the OFF state at a response speed of about 10 KHz, the pattern image generated by the DMD 10 also changes rapidly according to the drawing data. For this reason, during scanning exposure of a pattern of a display panel or the like, the pattern image projected from each of the modules MUn (n=1 to 27) instantaneously changes a shape into an isolated line pattern, a dotted pattern, a line and space pattern, a large land-like pattern, or the like.

A general display panel for a television (a liquid crystal type, an organic EL type) is constituted by an image display region arranged in a matrix such that a pixel part of about 200 to 300 μm square has a predetermined aspect ratio such as 2:1, 16:9, or the like, on the substrate P, and a peripheral circuit part (an extraction wiring, a connection pad, or the like) disposed at a periphery thereof. A thin film transistor (TFT) for switching or current driving is formed in each pixel part, but a size (line width) of a pattern for TFT (a pattern for a gate layer, a drain/source layer, a semiconductor layer, or the like), a gate wiring, or a driving wiring is sufficiently small compared to the arrangement pitch (200 to 300 μm) of the pixel part. For this reason, when the pattern in the image display region is exposed, since the pattern image projected from the DMD 10 is almost isolated, the telecentric error Δθt does not occur.

However, according to the configuration of the lighting driving circuit (TFT circuit) for each pixel part, line and space wirings arranged in the X direction or the Y direction may be formed at a pitch smaller than the arrangement pitch of the pixel part. In this case, when the pattern in the image display region is exposed, the pattern image projected from the DMD 10 has periodicity. For this reason, the telecentric error Δθt occurs depending on the degree of periodicity. In addition, upon exposure of the image display region, a rectangular pattern having substantially the same size as the pixel part or having a size more than half of the area of the pixel part may be uniformly exposed. In this case, the plurality of micro mirrors Ms of the DMD 10 during exposure of the image display region becomes the ON state with more than half of them being in a nearly dense state. For this reason, a relatively large telecentric error Δθt may occur.

The generation state of the telecentric error Δθt can be estimated before exposure on the basis of the drawing data of the pattern for a display panel exposed to each of the plurality of modules MUn (n=1 to 27). In the embodiment, the module MUn is configured such that a position or a posture of each of several optical members is finely adjustable, and among these optical members, it is possible to correct the telecentric error Δθt by selecting an adjustable optical member according to the estimated magnitude of the telecentric error Δθt.

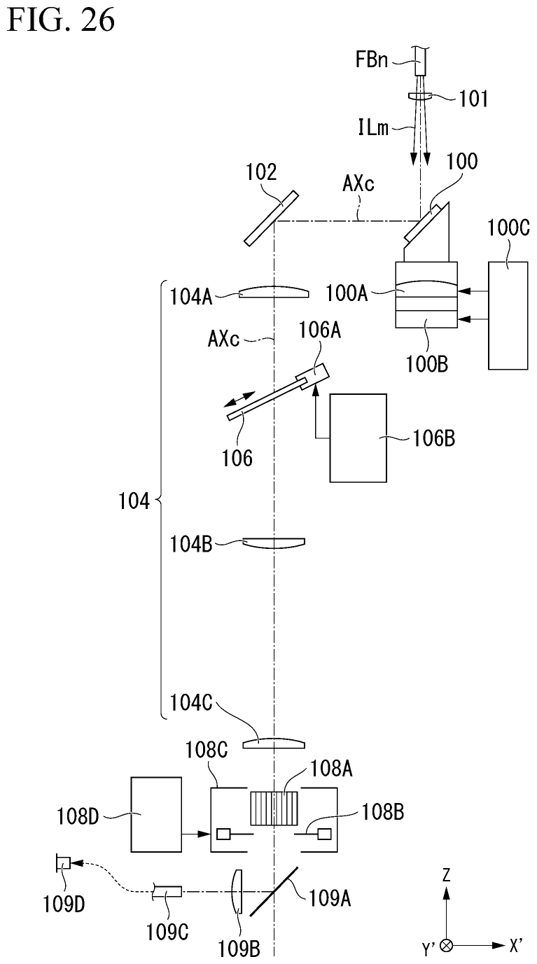

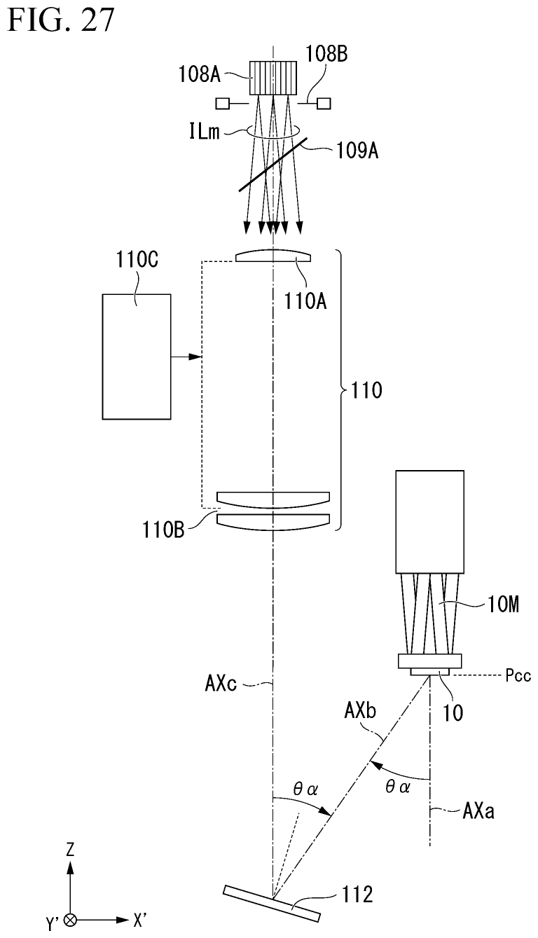

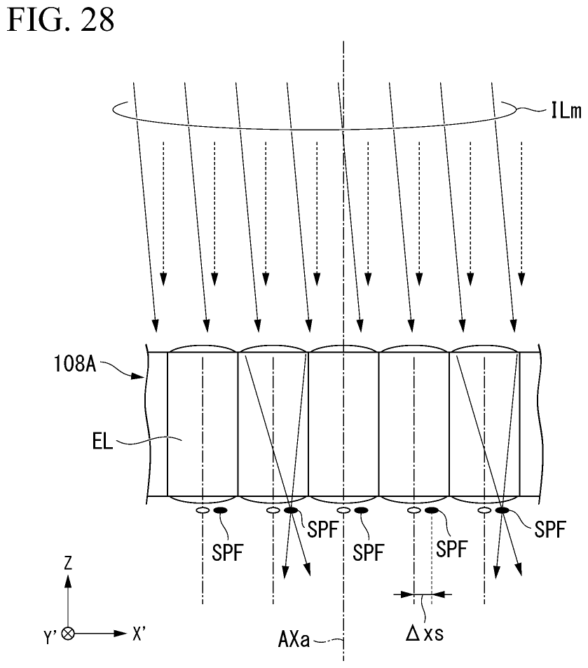

FIG. 26 shows a specific configuration of the optical path from the optical fiber bundle FBn to the MFE lens 108A in the illumination unit ILU of the module MUn shown in FIG. 4 or FIG. 6 above, and FIG. 27 shows a specific configuration of the optical path from the MFE lens 108A to the DMD 10 in the illumination unit ILU. In FIG. 26 and FIG. 27, the orthogonal coordinate system X′Y′Z is set to be the same as the coordinate system X′Y′Z of FIG. 4 (FIG. 6), and the members having the same functions as the members shown in FIG. 4 are designated by the same reference signs.

While not shown in FIG. 4, in FIG. 26, a contact lens 101 is disposed immediately behind the emission end of the optical fiber bundle FBn, and the spread of the illumination light ILm from the emission end is suppressed. The optical axis of the contact lens 101 is set to be parallel to the Z axis, and the illumination light ILm that advances from the optical fiber bundle FBn with a predetermined numerical aperture is reflected by the mirror 100 to advance parallel to the X′ axis and is reflected by the mirror 102 in the −Z direction. The condenser lens system 104 disposed in the middle of the optical path from the mirror 102 to the MFE lens 108A is constituted by three lens groups 104A, 104B and 104C along the optical axis AXc at an interval.

The illuminance adjustment filter 106 is supported by a holding member 106A translated by a driving mechanism 106B, and disposed between the lens group 104A and the lens group 104B. For example, as disclosed in Japanese Unexamined Patent Application, First Publication No. H11-195587, an example of the illuminance adjustment filter 106 is one in which a fine light shielding dot pattern is formed by gradually changing the density on a transmission plate such as a quartz or the like, or one in which a plurality of rows of elongated light shielding wedge-shaped patterns are formed, and transmissivity of the illumination light ILm can be changed continuously within a predetermined range by moving a quartz plate in parallel.

The first telecentric adjustment mechanism is constituted by a tilting mechanism 100A configured to finely adjust a two-dimensional inclination (a rotation angle around the X′ axis and the Y′ axis) of the mirror 100 configured to reflect the illumination light ILm from the optical fiber bundle FBn, a translation mechanism 100B configured to finely move the mirror 100 two-dimensionally in the X′Y′ plane perpendicular to the optical axis AXc, and a driving unit 100C constituted by a micro head, a piezo actuator, or the like, configured to individually drive each of the tilting mechanism 100A and the translation mechanism 100B.

By adjusting the inclination of the mirror 100, the center ray (principal ray) of the illumination light ILm entering the condenser lens system 104 can be adjusted to a state coaxial with the optical axis AXc. In addition, since the emission end of the fiber bundle FBn is disposed at a position of a front focal point of the condenser lens system 104, when the mirror 100 is finely moved in the X′ direction, the center ray (principal ray) of the illumination light ILm entering the condenser lens system 104 is shifted parallel to the optical axis AXc in the X′ direction. Accordingly, the center ray (principal ray) of the illumination light ILm emitting from the condenser lens system 104 advances slightly inclined with respect to the optical axis AXc. Accordingly, the illumination light ILm entering the MFE lens 108A is slightly inclined overall in the X′Z plane.

FIG. 28 is a view that exaggerates a state of the point light sources SPF formed on the emission surface side of the MFE lens 108A when the illumination light ILm entering the MFE lens 108A is inclined in the X′Z plane. When the center ray (principal ray) of the illumination light ILm is parallel to the optical axis AXc, the point light sources SPF condensed on the emission surface side of each of the lens elements EL of the MFE lens 108A are located at a center in the X′ direction as shown by a white circle in FIG. 28. When the illumination light ILm is inclined with respect to the optical axis AXc in the X′Z plane, the point light sources SPF condensed on the emission surface side each of the lens elements EL is eccentric by Δxs in the X′ direction from a center position as shown by a black circle in FIG. 28. In this case, as described in FIG. 7 to FIG. 9 above, the surface light source by the aggregate of the plurality of point light sources SPF formed on the emission surface side of the MFE lens 108A is laterally shifted by Δxs in the X′ direction as a whole. Since a cross-sectional dimension in the X′Y′ plane of each of the lens elements EL of the MFE lens 108A is small, eccentricity Δxs in the X′ direction as the surface light source is also small.

As shown in FIG. 26, a variable opening diaphragm (an adjusting diaphragm of a σ value) 108B is provided on the emission surface side of the MFE lens 108A, and the MFE lens 108A and the variable opening diaphragm 108B are integrally attached to a holding portion 108C. The holding portion 108C (the MFE 108A) is provided such that a position in the X′Y′ plane can be finely adjusted by the micro-motion mechanism 108D such as a micro head, a piezo motor, or the like. In the embodiment, the micro-motion mechanism 108D configured to finely move the MFE lens 108A in the X′Y′ plane two-dimensionally functions as a second telecentric adjustment mechanism.

A plate type beam splitter 109A inclined about 45° with respect to the optical axis AXc is provided immediately behind the MFE lens 108A. The beam splitter 109A transmits most of a quantity of light of the illumination light ILm from the MFE lens 108A, and reflects the remaining quantity of light (for example, about several %) toward a condensing lens 109B. Some of the illumination light ILm condensed by the condensing lens 109B is guided to a photoelectric element 109D by an optical fiber bundle 109C. The photoelectric element 109D is used as an integration sensor (integration monitor) configured to monitor the intensity of the illumination light ILm and measure an exposure value of the image forming light flux projected to the substrate P.

As shown in FIG. 27, the illumination light ILm from the surface light source on the emission surface side of the MFE lens 108A (the aggregate of the point light sources SPF) passes through the beam splitter 109A and enters the condenser lens system 110. The condenser lens system 110 is constituted by a front group lens system 110A and a rear group lens system 110B, which are disposed at an interval, and a two-dimensional position in the X′Y′ plane can be finely adjusted by a micro-motion mechanism 110C such as a micro head, a piezo motor, or the like. That is, eccentricity adjustment of the condenser lens system 110 can be performed by the micro-motion mechanism 110C. In the embodiment, the micro-motion mechanism 110C configured to finely move the condenser lens system 110 in the X′Y′ plane two-dimensionally functions as a third telecentric adjustment mechanism. Further, all the first telecentric adjustment mechanism, the second telecentric adjustment mechanism, and the third telecentric adjustment mechanism adjust a relative positional relation in an eccentric direction between the surface light source generated on the emission surface side of the MFE lens 108A (or the surface light source restricted in the circular opening of the variable opening diaphragm 108B) and the condenser lens system 110.

The front focal point of the condenser lens system 110 is set to a position of the surface light source on the emission surface side of the MFE lens 108A (the aggregate of the point light sources SPF), and the illumination light ILm that advances in a telecentric state from the condenser lens system 110 via the inclined mirror 112 Koehler-illuminates the DMD 10. As described in FIG. 28 above, when the surface light source by the aggregate of the plurality of point light sources SPF formed on the emission surface side of the MFE lens 108A is laterally shifted by Δxs in the X′ direction as a whole, the principal ray (center ray) of the illumination light ILm radiated to the DMD 10 is slightly inclined with respect to the optical axis AXb in FIG. 27. That is, the incidence angle θα of the illumination light ILm described in FIG. 6, FIG. 14, FIG. 18 and FIG. 22 above can be slightly changed from an initial set angle (35.0°) in the X′Z plane by intentionally applying the telecentric error to the illumination light ILm using the first telecentric adjustment mechanism.

In addition, when the MFE lens 108A and the variable opening diaphragm 108B are integrally displaced in the X′Y′ plane in the X′ direction by the micro-motion mechanism 108D as the second telecentric adjustment mechanism shown in FIG. 26, the circular opening of the variable opening diaphragm 108B (the circular region APh in FIG. 7) is eccentric from the optical axis AXc. Accordingly, the surface light source formed in the circular opening (the circular region APh) is also shifted in the X′ direction as a whole. Even in this case, the principal ray (center ray) of the illumination light ILm radiated to the DMD 10 can be inclined with respect to the optical axis AXb in the X′Z plane in FIG. 27. That is, incidence angle θα of the illumination light ILm to the DMD 10 can be changed from the initial set angle (35.0°) in the X′Z plane. Further, even when only the variable opening diaphragm 108B is configured to be solely finely moved in the X′Y′ plane by the micro-motion mechanism 108D, the incidence angle θα can be changed similarly.

In this way, since the MFE lens 108A and the variable opening diaphragm 108B are integrally relatively largely displaced, it is necessary to expand a light flux width (a diameter of an irradiation range) of the illumination light ILm radiated from the condenser lens system 104 to the MFE lens 108A. Further, it is also effective to provide a shift mechanism configured to laterally shift the illumination light ILm radiated to the MFE lens 108A in the X′Y′ plane in conjunction with an amount of the displacement. The shift mechanism can be constituted by a mechanism configured to incline a direction of the emission end of the optical fiber bundle FBn, a mechanism configured to incline a parallel planar plate (quartz plate) disposed in front of the MFE lens 108A, or the like.

While both the first telecentric adjustment mechanism (the driving unit 100C or the like) and the second telecentric adjustment mechanism (the micro-motion mechanism 108D or the like) can adjust the incidence angle θα of the illumination light ILm to the DMD 10, regarding the adjustment amount, the first telecentric adjustment mechanism can be used for fine adjustment, and the second telecentric adjustment mechanism can be used for rough adjustment. In actual adjustment, whether to use both the first telecentric adjustment mechanism and the second telecentric adjustment mechanism or to use either one can be selected as appropriate depending on the form of the pattern to be projected and exposed (the amount of the telecentric error Δθt and the correction amount).

Further, the micro-motion mechanism 110C as the third telecentric adjustment mechanism configured to make the condenser lens system 110 eccentric in the X′Y′ plane has the same effect as a case in which the position of the surface light source defined by the MFE lens 108A and the variable opening diaphragm 108B is made relatively eccentric by the second telecentric adjustment mechanism. However, when the condenser lens system 110 is eccentric in the X′ direction (or the Y′ direction), since the irradiation region of the illumination light ILm projected to the DMD 10 is laterally shifted, the irradiation region is set larger than the size of the entire mirror surface of the DMD 10 while taking into account the lateral shift. The third telecentric adjustment mechanism by the micro-motion mechanism 110C can also be used for rough adjustment in the same way as the second telecentric adjustment mechanism.

### (Other Telecentric Adjustment Mechanism)

In adjustment (correction) of the telecentric error, a position in the X′Y′ plane of the emission end of each of the optical fiber bundles FBn (n=1 to 27) shown in FIG. 4 and FIG. 26 can also be laterally shifted by the micro-motion mechanism. In this case, like the above-mentioned first telecentric adjustment mechanism (the driving mechanism 100C or the like), the position of the surface light source (the aggregate of the plurality of point light sources SPF) formed on the emission surface side of the MFE lens 108A can be finely adjusted.

In correction of the telecentric error, the original angle of the inclined mirror 112 shown in FIG. 4, FIG. 6 and FIG. 27 can be adjusted by the micro-motion mechanism such as a micro head, a piezo actuator, or the like, and the incidence angle θα (for example, 35.0° by design) of the illumination light ILm to the DMD 10 can also be finely adjusted. Alternatively, the inclination of the mirror surface (the neutral plane Pcc) of the DMD 10 can be finely adjusted by a micro-motion stage obtained by combining a parallel link mechanism of the mount portion 10M and a piezo element shown in FIG. 4 and FIG. 27, and the telecentric error may also be corrected. However, the angle adjustment of the inclined mirror 112 or the DMD 10 is used for rough adjustment because the reflected light is inclined at twice the adjustment angle. Further, in angle adjustment of the DMD 10, image surface inclination in which the conjugation surface (best focus surface) of the neutral plane Pcc projected onto the substrate P is inclined in the direction of the scanning exposure (the X′ direction or the X direction) with respect to the plane perpendicular to the optical axis AXa occurs.

When the direction of the image surface inclination is the direction of the scanning exposure, since the scanning exposure is performed at an average image surface position of the inclined image surface, a decrease in contrast of the exposed pattern image is minor. Accordingly, a function of inclining the DMD 10 in the scanning exposure direction (the X′ direction or the X direction) and correcting the telecentric error Δθt can also be utilized within a range in which contrast reduction of the exposed pattern image is negligible. When the DMD 10 is inclined to such an extent that contrast reduction cannot be ignored, some kind of image surface inclination correction systems (such as a two-wedge-shaped declination prism or the like) will be provided within the projection unit PLU. Alternatively, in order to correct the telecentric error Δθt, a mechanism configured to make a specified lens group or lens eccentric in the projection unit PLU with respect to the optical axis AXa may be provided. Further, the inclination correction system (the two-wedge-shaped declination prism or the like) may be provided in the illumination unit ILU.

### (Beam Supply Unit)

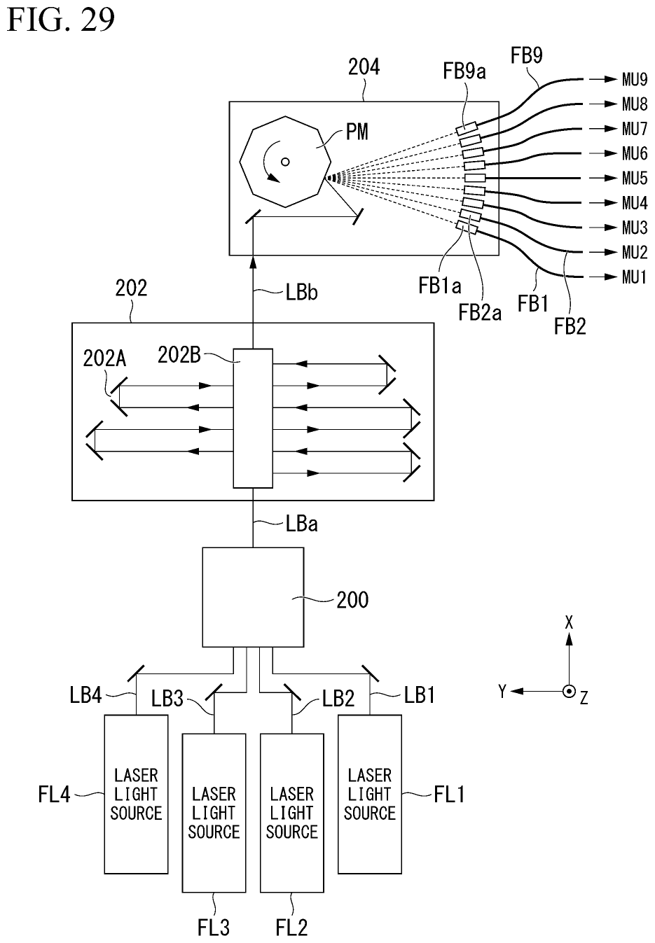

Next, an example of a beam supply unit attached to the exposure apparatus EX shown in FIG. 1 above and configured to supply the illumination light ILm to each of the modules MUn (n=1 to 27) will be described with reference to FIG. 29. The orthogonal coordinate system XYZ in FIG. 29 is set to the same as the coordinate system XYZ in FIG. 1 in convenience. In the beam supply unit of FIG. 29, beams LB1 to LB4 (a beam diameter of 1 mm or less) from four laser light sources (fiber amplifier laser light sources) FL1 to FL4 are synthesized to a bundle of beams LBa by a beam synthesizing unit 200. Each of the laser light sources FL1 to FL4 has a basic peak wavelength of 343.333 nm, and oscillates pulse light with a light emission duration (duration time) on the order of tens of picoseconds, each with a peak wavelength (a spectral width of about 0.05 nm) that differs by a predetermined wavelength.

Each of the four laser light sources FL1 to FL4 oscillates the pulse light at a predetermined timing in synchronization in response to a clock pulse of a common clock signal (for example, a frequency of 200 KHz). The timing of the pulsed oscillation of each of the four laser light sources FL1 to FL4 may be synchronized with the clock signal to be completely the same as the clock signal, or the laser light sources FL1 to FL4 may be sequentially oscillated with a time difference (delay) of about a light emission duration (duration time). In this way, by providing a time difference (delay) in the emission timing, it is also possible to reduce the coherence of the illumination light ILm radiated to the DMD 10.

The beam LBa synthesized by the beam synthesizing unit 200 enters a retarder part 202 configured to divide the beam into a plurality of optical paths with different beam optical path lengths, circulate them, and then, synthesize them. The retarder part 202 emits a beam LBb synthesized after generating a plurality of beams with a temporal delay of beam wave fronts in order to reduce occurrence of speckles due to high coherency (temporal and spatial coherency) of the original beams LB1 to LB4. For this reason, the retarder part 202 has a plurality of delay optical path portions 202A set to have different optical path lengths, and a split synthesizing unit 202B configured to perform division of the entering beam LBa into the delay optical path portions 202A and synthesis of return beams from the delay optical path portions 202A, respectively. A theoretical configuration of such a retarder part 202 is disclosed in, for example, Japanese Unexamined Patent Application, First Publication No. 2007-227973.

The beam LBb whose temporal coherency is reduced by the retarder part 202 enters a beam switching part 204. A rotary polygon mirror PM that rotates at a high speed is provided on the beam switching part 204, and the beam LBb is deflected in a fan shape by each of the reflecting surfaces of the rotary polygon mirror PM. Incidence ends FB1a to FB9a of the nine optical fiber bundles FB1 to FB9 are arranged at a constant angle in an arc shape in a direction in which the beam LBb enters at substantially equidistant positions from an incidence position of the beam LBb on a reflecting surface of the rotary polygon mirror PM.

As described in FIG. 8 above, each of the optical fiber bundles FB1 to FB9 is a single optical fiber wire or a bundle of a plurality of optical fiber wires. Further, while not shown in FIG. 29, a f-θ lens (non-telecentric) configured to cover a fan-shaped deflection area of the beam LBb is provided immediately behind the rotary polygon mirror PM, and further, a small lens configured to condense the beam LBb from the rotary polygon mirror PM to a small spot is provided in front of each of the incidence ends FB1a to FB9a of the optical fiber bundles FB1 to FB9. In addition, the beam LBb is pulse-oscillated in response to a common clock signal to each of the laser light sources FL1 to FL4, and synchronous control of the beam LBb between a period of a clock signal and a rotating speed (angle phase) of the rotary polygon mirror PM is performed such that the beam enters the incidence ends FB1a to FB9a of the optical fiber bundles FB1 to FB9 in sequence for each pulse light.

In the embodiment, two sets of beam supply units having the same configuration as in FIG. 29 are provided, one set thereof switches and supplies the beams LBb to the optical fiber bundle FB10 to FB18 of the module MU10 to MU18, respectively, and the other set switches and supplies the beams LBb of the optical fiber bundles FB19 to FB27 of the module MU19 to MU27, respectively. In addition, while the four laser light sources FL1 to FL4 are used in the beam supply unit of FIG. 29, three or less laser light sources may be provided, or a larger number of laser light sources may be provided to synthesize five or more beams using the beam synthesizing unit 200.

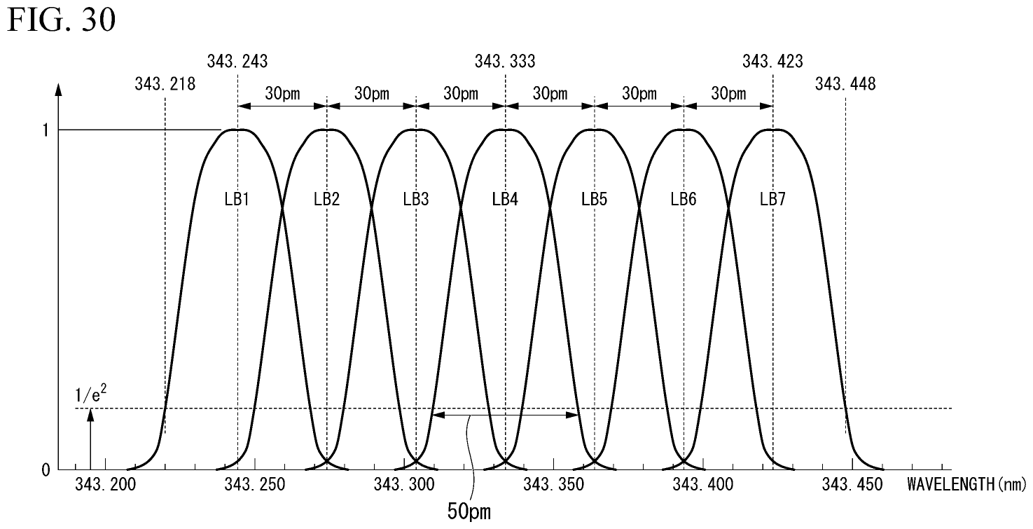

In addition, as described above, peak wavelengths of beams LBn (n=1, 2, 3 . . . ) of a plurality of laser light sources FLn (n=1, 2, 3 . . . ) may be different from each other by a constant wavelength for the purpose of speckle reduction. For example, FIG. 30 is a view schematically showing a wavelength distribution of the beam LBb after synthesis of the beams LB1 to LB7 from the seven laser light sources FL1 to FL7 using the beam synthesizing unit 200. In FIG. 30, a lateral axis represents a wavelength (nm), and a vertical axis represents σ value where peak intensities of the beams LB1 to LB7 are normalized to 1. While the seven laser light sources FL1 to FL7 have substantially the same configuration, by varying the wavelength of each seed light by a certain value, the peak wavelengths (center wavelengths) of the beams LB1 to LB7 that are finally output are set to differ by about 30 pm (0.03 nm).

Since such a fiber amplifier laser light source in an ultraviolet wavelength region uses a wavelength conversion element, a spectral width of an oscillation wavelength is also reduced, and for example, as shown in FIG. 30, it becomes about 50 μm (0.05 nm) in the intensity of 1/e2 of the peak intensity. In the case of FIG. 30, a center wavelength of the beam LB4 from the laser light source FL4 is set to 343.333 nm, a center wavelength of the beam LB3 from the laser light source FL3 is set to 343.303 nm, a center wavelength of the beam LB2 from the laser light source FL2 is set to 343.273 nm, and a center wavelength of the beam LB1 from the laser light source FL1 is set to 343.243 nm. Further, a center wavelength of the beam LB5 from the laser light source FL5 is set to 343.363 nm, a center wavelength of the beam LB6 from the laser light source FL6 is set to 343.393 nm, and a center wavelength of the beam LB7 from the laser light source FL7 is set to 343.423 nm.

Accordingly, a wavelength spectral width of the beam LBb obtained by synthesizing the beams LB1 to LB7 is about 180 μm (0.18 nm) when seen at an interval of a peak wavelength, and about 230 μm (0.23 nm) when seen at an interval (343.218 nm to 343.448 nm) at the intensity of 1/e2. In this way, when a spectral width of the beam LBb, i.e., the illumination light ILm of the DMD 10 is widened to reduce the speckles, the telecentric error Δθt also occurs according thereto, but the spectral width is set such that the influence is within an allowable limit. In the above-mentioned example of the spectral width, a peak wavelength of 343.243 nm and a peak wavelength of 343.423 nm are included in the illumination light ILm, and in the case of FIG. 17 and FIG. 18 above where the telecentric error Δθt largely occurs, a trial calculation using Equation (2) described in FIG. 19 will be performed.

Even in the trial calculation, when the incidence angle θα of the illumination light ILm is 35.0°, the inclination angle θd of the micro mirrors Msa in the ON state is 17.5°, and the projection magnification Mp is ⅙, the telecentric error on the object surface side (the side of the DMD 10) of the 9-order diffraction light Id9 generated when the peak wavelength of the illumination light ILm is 343.243 nm is about 0.0860 (the telecentric error Δθt≈0.517° on the image surface side). Similarly, the telecentric error on the object surface side (on the side of the DMD 10) of the 9-order diffraction light Id9 generated in the case in which the peak wavelength of the illumination light ILm is 343.423 nm is about 0.069° (the telecentric error Δθt≈0.414° on the image surface side).

Accordingly, when the peak wavelength is between 343.243 nm to 343.423 nm as the spectral width of the illumination light ILm, the telecentric error Δθt on the image surface side that may occur due to the widening of the wavelength spectral width can be suppressed, for example, within an allowable limit of 2° described in FIG. 25 (more desirably, within an allowable limit of 10).

When the illumination light ILm is provided with a spectral width (becoming broadband) in order to reduce the speckles, limits for short and long wavelength values may be set in consideration of the allowable limit (for example, within ±2°) of the telecentric error Δθt on the image surface side generated due to a difference in wavelength. Accordingly, the number of the laser light sources FLn is not limited to seven, and further, a shift degree of center wavelength of the beams LBn from each of the laser light source is not also limited to 30 μm.

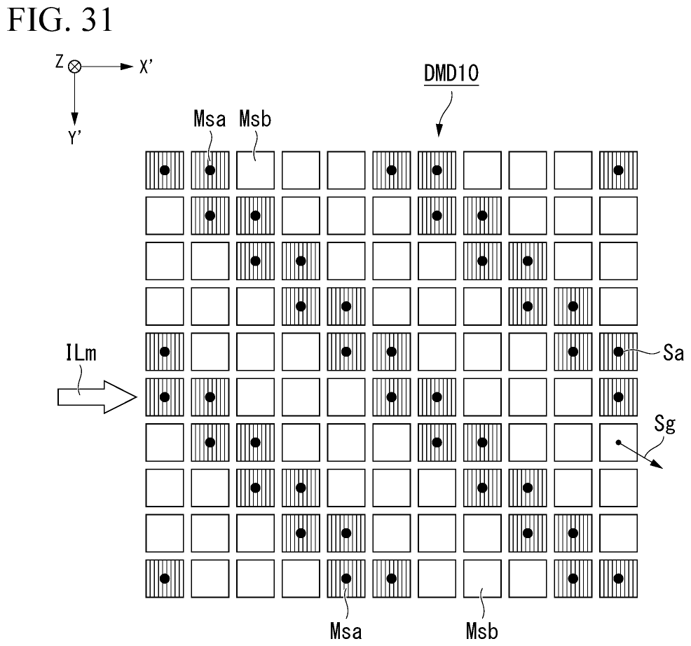

FIG. 31 is a view showing an aspect of a portion of the mirror surface of the DMD 10 upon exposure of the line and space pattern inclined by 45° obliquely on the substrate P. In FIG. 31, as in FIG. 13, FIG. 17 and FIG. 21 above, the reflected light Sa from each of the micro mirrors Msa in the ON state is reflected in the −Z direction, and the reflected light Sg from each of the micro mirrors Msb in the OFF state is inclined in an inclination direction in the X′Y′ plane. The micro mirrors Msa in the ON state are arranged in rows adjacent to each other in a diagonal 450 direction, and the rows are arranged to form a diffraction grating. For this reason, the telecentric error Δθt occurs in the reflected light (image forming light flux) Sa′ generated from all the micro mirrors Msa in the ON state due to an influence of a diffraction phenomenon.

In the case of the line and space pattern as shown in FIG. 21 above, the telecentric error Δθt occurs only in the X′ direction, but in the case of the line and space pattern as shown in FIG. 31, the telecentric error Δθt occurs in the X′ direction and the Y′ direction. Accordingly, even in the case of the line and space pattern inclined at an angle of 45°, or 30° to 60° in FIG. 31, if the telecentric error Δθt that may occur exceeds the allowable limit in either the X′ direction or the Y′ direction, it can be corrected by some adjustment mechanisms for the telecentric error described in FIG. 26 and FIG. 27 above.

### (Control System for Telecentric Error Correction)

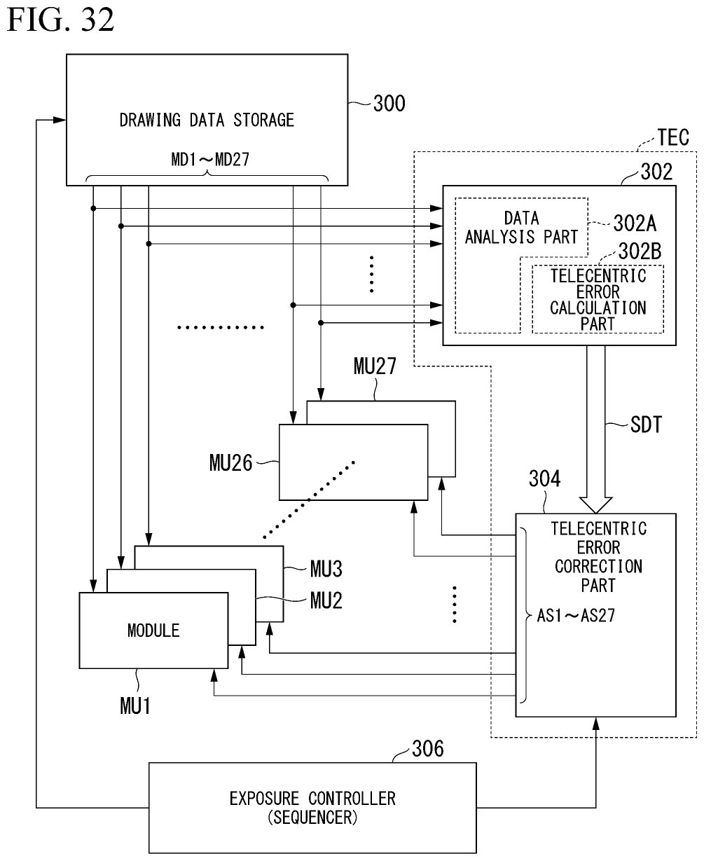

FIG. 32 is a block diagram showing a schematic example of a portion of an exposure control device attached to the exposure apparatus EX of the embodiment, in particularly, related to adjustment control of the telecentric error. An adjustment control system TEC for a telecentric error shown in FIG. 32 is applied when all or at least one of the first telecentric adjustment mechanism (the driving unit 100C or the like), the second telecentric adjustment mechanism (the micro-motion mechanism 108D or the like), and the third telecentric adjustment mechanism (the micro-motion mechanism 110C or the like) described in FIG. 26 and FIG. 27 can be electrically driven by an actuator such as a motor or the like.

In FIG. 32, a drawing data storage unit (hereinafter, also simply referred to as a storage unit) 300 configured to send drawing data MD1 to MD27 for pattern exposure is provided on the DMD 10 of each of the 27 modules MU1 to MU27 shown in FIG. 2 above. Each of the drawing data MID to MD27 is sent to an angular variation specifying part (hereinafter, also referred to as a telecentric error specifying part) 302 before the exposure operation. The telecentric error specifying part 302 has a data analysis part 302A configured to analyze a form (isolation, line and space, pad, or the like) of a pattern exposed in each of the projection regions IA1 to IA27 (see FIG. 2 and FIG. 3) on the substrate P and a position on the substrate P on the basis of each of the drawing data MD1 to MD27, and a telecentric error calculation unit 302B configured to calculate information SDT related to the telecentric error Δθt according to the form of the analyzed pattern.

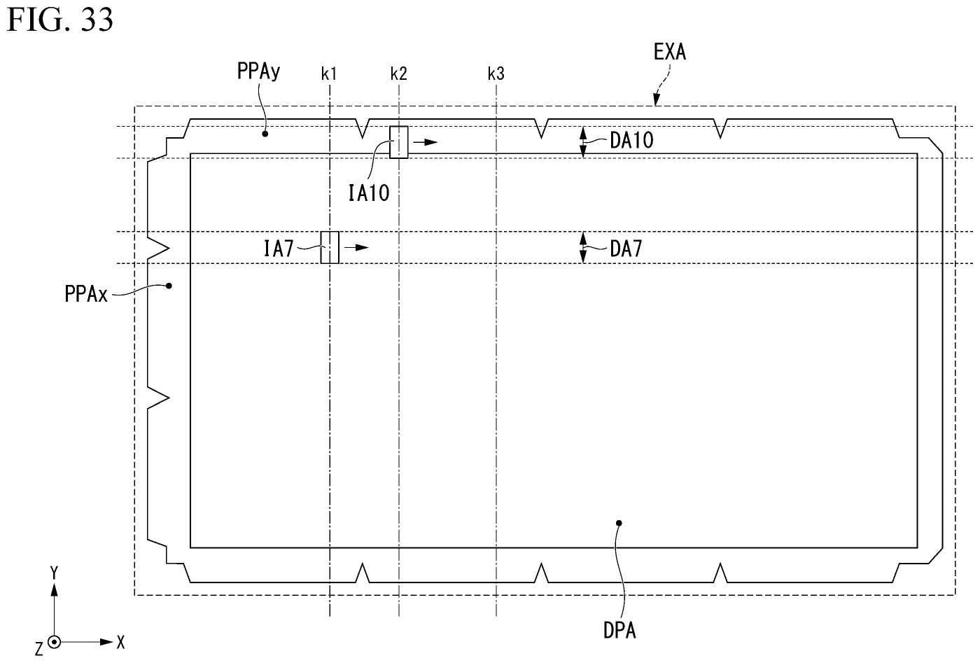

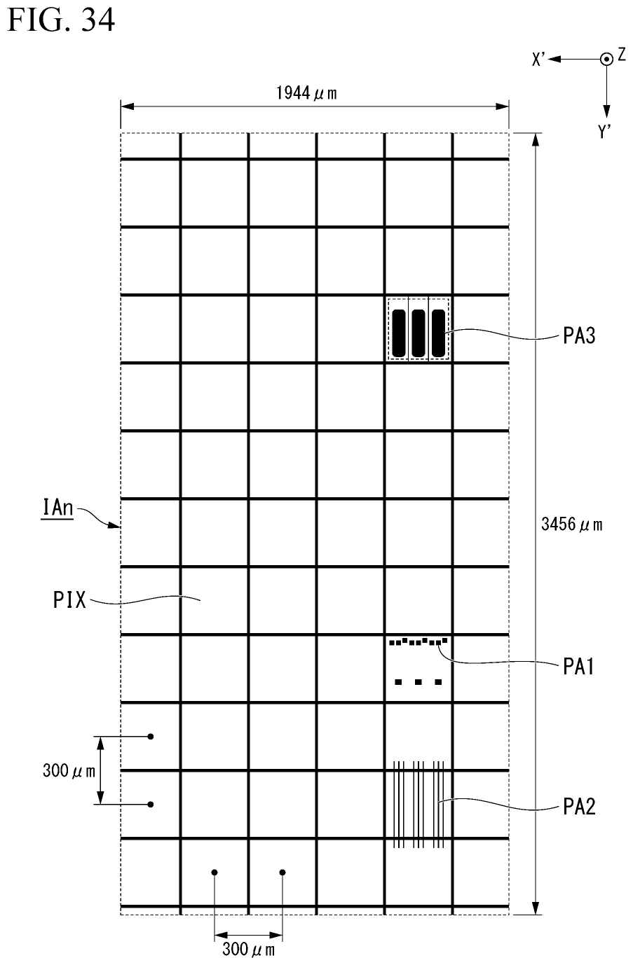

Here, an example of a main function of the angular variation specifying part (telecentric error specifying part) 302 will be described with reference to FIG. 33 and FIG. 34. FIG. 33 shows an example of disposition of a display region DPA for a display panel exposed on the substrate P by the exposure apparatus EX shown in FIG. 1 and FIG. 2 and peripheral regions PPAx and PPAy, and a maximum exposure region EXA on an outer edge represents a range that can be exposed by the modules MU1 to MU27 in one scanning exposure of the exposure apparatus EX. The display region DPA is constituted by a plurality of pixels arranged at a constant pitch in the X direction and the Y direction, and has an aspect ratio such as 16:9, 2:1, or the like, as a whole. Further, here, a longitudinal direction of the display region DPA is the X direction.

As an example, regions DA7 and DA10 scanning-exposed by the projection regions IA7 and IA10 of the modules MU7 and MU10 shown in FIG. 2 will be described. The actual projection regions IA7 and IA10 are inclined by the angle θk with respect to an XY coordinate system as shown in FIG. 3 above. Although the region DA7 contains the peripheral region PPAx having a narrow width in the X direction on the end portion in the −X direction (or the +X direction), the region DA7 is mostly occupied by the display region DPA extending in the X direction (scanning exposure direction). While pixels of about 200 μm to 300 μm square are arranged in the XY direction in the display region DPA, the pattern exposed in the pixel may be an isolation pattern, a line and space pattern, or a large land-like pattern for each process on a manufacturing process.

FIG. 33 is a view showing an example of a disposition state of pixels PIX in the display region DPA appeared in one projection region IAn (n=1 to 27). As mentioned earlier as a numerical example, it is assumed that the arrangement pitch Pd of the micro mirrors Ms of the DMD 10 is 5.4 μm, and the micro mirrors Ms are arranged in 2160 pieces in the X′ direction and 3840 pieces in the Y′ direction. In this case, an aspect ratio is 16:9 (=3840:2160), an actual size of the mirror surface of the DMD 10 in the X′ direction is 11.664 mm, and an actual size in the Y′ direction is 20.736 mm. When the projection magnification Mp by the projection units PLU is ⅙, a dimension of the projection region IAn on the substrate P in the X′ direction is 1944 μm, and a dimension in the Y′ direction is 3456 μm. In addition, a single projection image of the micro mirror Msa in the ON state has a dimension of approximately 0.9 μm square on the substrate P.

When a pitch of the pixels PIX on the substrate P in the X′ direction and the Y′ direction is 300 μm, approximately 6 pixels PIX in the X′ direction and approximately 11 pixels in the Y′ direction will appear in the projection region IAn. The patterns exposed in the pixels PIX may be an isolation pattern PA1, a line and space pattern PA2, or a land-like pattern PA3 for each layer. In FIG. 34, for convenience of description, while the three types of patterns PA1, PA2 and PA3 are shown together, the pattern PA1 is appeared in all the pixels PIX contained in the projection region IAn upon exposure of the pattern PA1, the pattern PA2 is appeared in all the pixels PIX contained in the projection region IAn upon exposure of the pattern PA2, and then, the pattern PA3 is appeared in all the pixels PIX contained in the projection region Ian upon exposure of the pattern PA3.

Further, in FIG. 34, for convenience of description, while the vertical and horizontal arrangement of the pixels PIX in the projection region Ian coincides with an X′Y′ coordinates, in fact, as described in FIG. 3 and FIG. 5, the vertical and horizontal arrangement of the pixels PIX is inclined by the angle θk with respect to the X′Y′ coordinates, and is set such that it appears consistent with the XY coordinate system, which is movement coordinates of the substrate P.

As shown in FIG. 34, the exposure of the isolation pattern PA1 to all the pixels PIX in the display region DPA is performed by, for example, a process of forming a semiconductor layer, an electrode layer, a via hole, or the like, of a TFT. In such a case, as described in FIG. 13 to FIG. 16 above, the telecentric error Δθt exceeding the allowable limit does not occur. That is, if the illumination unit ILU and the projection units PLU are telecentrically adjusted with respect to the projection image of the isolation pattern projected by the micro mirrors Msa alone in the ON state, the telecentric error Δθt exceeding the allowable limit does not occur. However, even in the isolation pattern, when the isolation pattern is exposed on the substrate P with a pixel size of several tens of m, such as a display panel for a smart phone, about several tens of micro mirrors Msa in the ON state are densely arranged on the DMD 10 in the X′ direction and the Y′ direction. For this reason, even with an isolation pattern, the telecentric error Δθt may occur depending on its size (pattern dimension).

In addition, the peripheral region PPAx in the region DA7 shown in FIG. 33 is formed in a lattice shape in which wirings extending in the X direction (X′ direction) are mainly disposed at a constant interval in the Y direction (Y′ direction). Accordingly, even if the influence of the diffraction phenomenon in the X′ direction is small and the telecentric error Δθt occurs, it will be within the allowable limit.

In addition, as shown in FIG. 34, the exposure of the line and space pattern PA2 to all the pixels PIX in the display region DPA is performed by, for example, a process of forming a wiring that connects an electrode layer of a TFT, a power supply line, an earth line, a signal line, a choice line, and the like. In this case, as described in FIG. 21 to FIG. 23 above, the telecentric error Δθt exceeding the allowable limit may occur according to the pitch or the line width of the line and space. Further, as shown in FIG. 34, the exposure of the land-like pattern PA3 to all the pixels PIX in the display region DPA is performed by, for example, a process of forming a bank of an emission section of the pixels PIX, an electrode layer, or the like. The land-like pattern PA3 is open more than half (in some cases, close to 90%) of the area (about 300 μm square) of the pixels PIX, and in such a case, as described in FIG. 18 to FIG. 20 above, there is a high possibility that the telecentric error Δθt exceeding the allowable limit will occur.

In addition, the peripheral region PPAx in the region DA7 shown in FIG. 33 is formed in a lattice shape in which wirings extending in the X direction (X′ direction) are mainly disposed at a constant interval in the Y direction (Y′ direction). Accordingly, even when the influence of the diffraction phenomenon in the X′ direction is small and the telecentric error Δθt occurs, it is within the allowable limit. However, when a line and space wiring that is inclined in both the X′ direction and the Y′ direction as described in FIG. 31 above is formed in the peripheral region PPAx, the telecentric error Δθt may occur.

From above, the data analysis part 302A of the angular variation specifying part (telecentric error specifying part) 302 of FIG. 32 analyzes the drawing data MD7 of the entire region DA7 sent to the module MU7, and generates position information of each partial regions obtained by dividing the region DA7 into a plurality of partial regions in the X direction and form information that determines whether the form of the pattern appeared in the partial region is the isolation pattern PA1, the line and space pattern PA2, or land-like pattern PA3 as shown in FIG. 34. The telecentric error calculation part 302B of the angular variation specifying part (telecentric error specifying part) 302 of FIG. 32 calculates the telecentric error Δθt that occurs according to the line width, the pitch, or the like, when the form information of the pattern appeared in the partial region is the line and space pattern PA2, and calculates the telecentric error Δθt that occurs according to the size or the like when the form information of the pattern appeared in the partial region is the land-like pattern PA3.

Further, in calculation of the telecentric error Δθt by the telecentric error calculation part 302B, as simple calculation, a proportion of each of the plurality of partial regions obtained by dividing the region DA7 in the X direction with respect to the entire area of the partial region of the area in which exposure light is radiated onto the substrate P in the partial region is obtained, and the telecentric error Δθt may also be estimated according to the proportion. The proportion may be an average density of the micro mirrors Msa in the ON state while exposing the partial region, among all the micro mirrors Ms of the DMD 10. Accordingly, when the density is a prescribed value, for example, 50% or more, the telecentric error Δθt may be estimated according to the density.

The above-mentioned operation is performed similarly even in the region DA10 shown in FIG. 33, and the angular variation specifying part (telecentric error specifying part) 302 of FIG. 32 calculates the telecentric error Δθt that can be generated in each partial region upon pattern exposure by the projection regions IA10 of the module MU10 on the basis of the drawing data MD10 from the storage unit 300. The region DA10 shown in FIG. 33 contains many patterns of the peripheral region PPAy. Since the peripheral region PPAy contains a line and space pattern in which wirings extending in the Y direction (Y′ direction) are mainly arranged at a constant pitch in the X direction (X′ direction), the telecentric error Δθt exceeding the allowable limit may occur.

Now, the angular variation specifying part (telecentric error specifying part) 302 of FIG. 32 generates the information SDT (also including position information in the scanning exposure direction) related to the telecentric error Δθt calculated (estimated) as above in relation with each of the modules MU1 to MU27, and sends the information to a telecentric error correction part 304. The telecentric error correction part 304 selects at least one of the mechanisms that meet with adjustment amount or adjustment accuracy, among the first telecentric adjustment mechanism (the driving unit 100C or the like), second telecentric adjustment mechanism (the micro-motion mechanism 108D or the like), and third telecentric adjustment mechanism (the micro-motion mechanism 110C or the like) described in FIG. 26 and FIG. 27 on the basis of the information SDT related to the telecentric error Δθt with respect to each of the modules MU1 to MU27, and outputs adjustment instruction information AS1 to AS27 to each of the modules MU1 to MU27.

The adjustment instruction information AS1 to AS27 from the telecentric error correction part 304 is sent to the corresponding telecentric adjustment mechanism and correction of the telecentric error Δθt is performed in real time when each of the modules MU1 to MU27 performs an exposure operation in actual. An exposure controller (sequencer) 306 controls sending of the drawing data MD1 to MD27 from the storage unit 300 to the modules MU1 to MU27 and sending of the adjustment instruction information AS1 to AS27 from the telecentric error correction part 304 in synchronization with the scanning exposure (moving position) of the substrate P.

According to the above-mentioned embodiment, in the pattern exposure apparatus including the DMD 10 as the spatial light modulating element having the plurality of micro mirrors Ms selectively driven on the basis of the drawing data MDn (n=1 to 27), the illumination unit ILU configured to irradiate the DMD 10 with the illumination light ILm at the predetermined incidence angle θα, and the projection units PLU configured to project the reflected light Sa (image forming light flux) entering from the selected micro mirrors Msa in the ON state of the DMD 10 to the substrate P, and configured to project and expose the pattern corresponding to the drawing data MDn to the substrate P, the telecentric error Δθt of the reflected light (image forming light flux) Sa′ occurred due to the diffraction effect when the plurality of micro mirrors Ms of the DMD 10 are in the ON state can be normally suppressed within the allowable limit by providing the angular variation specifying part (telecentric error specifying part) 302 configured to previously specify (estimate) the telecentric error (telecentric error) At occurred in the reflected light Sa projected to the substrate P from the projection units PLU upon projection exposure of the pattern according to a distribution state (a concentration degree or periodicity) of the micro mirrors Msa in the ON state of the DMD 10, and the adjustment mechanism (the driving unit 100C, the micro-motion mechanism 108D, the micro-motion mechanism 110C, and the like) configured to adjust a position of some optical members (the mirror 100, the opening diaphragm 108B, the condenser lens system 110, and the like) in the illumination unit ILU or the projection units PLU according to the telecentric error Δθt that is previously specified.

### (Variant 1)

As described above, since the telecentric error occurs in the reflected light (image forming light flux) Sa′ reflected by the DMD 10 according to the distribution state of the micro mirrors Msa in the ON state of the DMD 10 and the projection units PLU is a reduction projection system, the telecentric error Δθt on the image surface side is magnified by the reciprocal of the projection magnification Mp. Since the size of the telecentric error Δθt that occurs in actual is changed according to the form of the pattern generated by the DMD 10, how much the telecentric error Δθt occurs for each form of several patterns may be measured in advance.

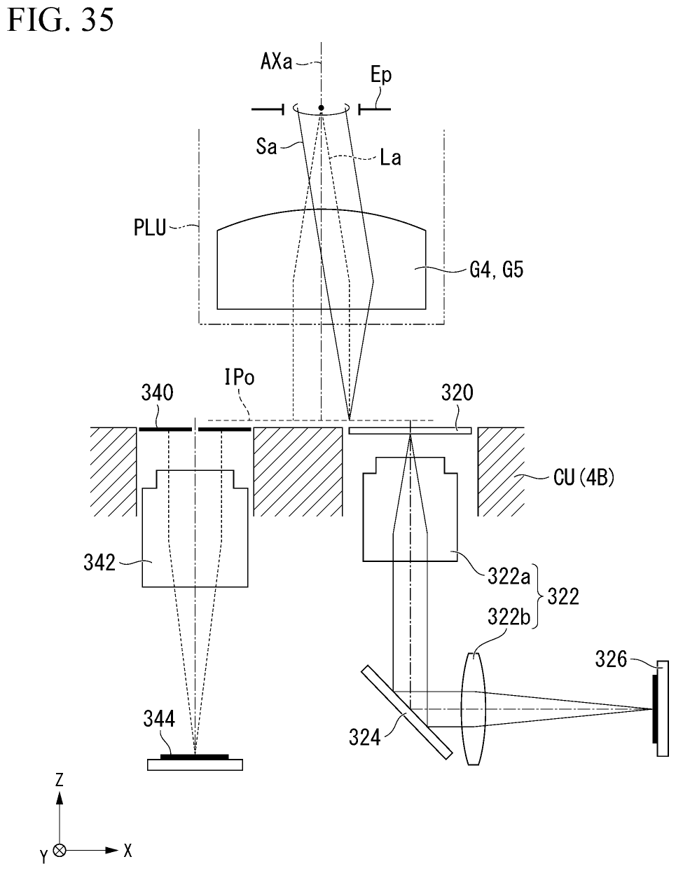

FIG. 35 is a view showing a schematic configuration of an optical measurement part provided in the reference portion CU for calibration attached to the end portion on the substrate holder 4B of the exposure apparatus EX shown in FIG. 1. In FIG. 35, an image of the reflected light (image forming light flux) Sa from the DMD 10 is formed on the best focus surface (best image forming surface) IPo through the lens groups G4 and G5 on the image surface side of the projection units PLU, and the principal ray La of the reflected light Sa is parallel to the optical axis AXa. The first optical measurement part is constituted by a quartz plate 320 attached to an upper surface of the reference portion CU for calibration, an image forming system 322 (an object lens 322a and a lens group 322b) configured to form a pattern image by the DMD 10 projected from the projection units PLU via the quartz plate 320 as an enlarged image, a reflecting mirror 324, and an image pick-up device 326 by a CCDD or a CMOS configured to capture the enlarged pattern image. Further, a surface of the quartz plate 320 and an image pick-up surface of the image pick-up device 326 have a conjugation relation.

The second optical measurement part is constituted by a pinhole plate 340 attached to the upper surface of the reference portion CU for calibration, an object lens 342 configured to allow incidence of the reflected light (image forming light flux) Sa from the DMD 10 projected from the projection units PLU via the pinhole plate 340 and form an image (an image forming light flux in the pupil Ep or an intensity distribution of the light source image) of the pupil Ep of the projection units PLU, and an image pick-up device 344 by a CCDD or a CMOS configured to capture an image of the pupil Ep. That is, the image pick-up surface of the image pick-up device 344 of the second optical measurement part and the position of the pupil Ep of the projection units PLU have a conjugation relation.

Since the substrate holder 4B (the reference portion CU for calibration) can be two-dimensionally moved in the XY plane by the XY stage 4A, the quartz plate 320 of the first optical measurement part or the pinhole plate 340 of the second optical measurement part is disposed immediately below the projection unit PLU of any one of the modules MU1 to MU27 to be measured, and the reflected light Sa corresponding to various types of test patterns for measurement is generated by the DMD 10. In measurement of the telecentric error by the first optical measurement part, the substrate holder 4B (the reference portion CU for calibration), all the projection units PLU, or the lens groups G4 and G5 are vertically moved such that a surface of the quartz plate 320 is defocused by a constant amount with respect to the best focus surface IPo in each of the +Z direction and the −Z direction.

Then, the telecentric error Δθt can be measured on the basis of the lateral deviation amount and the defocus amount (a micro-motion range of Z) of the image of the test pattern captured by the image pick-up device 326 upon defocusing in each of the +Z direction and the −Z direction. Since the image pick-up device 326 of the first optical measurement part captures the mirror surface of the DMD 10 via the projection units PLU, it can also be used to confirm the micro mirrors Ms that are malfunctioned, among the plurality of micro mirrors Ms of the DMD 10. In addition, typical some test patterns (patterns belonging to any one of an isolation shape, a line and space shape, and a land-like shape) in which the telecentric error Δθt can occur can be generated in the DMD 10, and asymmetry of the intensity distribution of the projection image of the test pattern (the distribution in FIG. 24 above) can be measured by the image pick-up device 326 of the first optical measurement part.

### (Variant 2)

In addition, in measurement of the telecentric error by the second optical measurement part, eccentricity or the like of the intensity distribution in the pupil Ep of the image forming light flux (Sa, Sa′) formed on the pupil Ep of the projection units PLU upon projection of the test pattern is measured by the image pick-up device 344. In this case, the telecentric error Δθt can be measured on the basis of the eccentricity of the intensity distribution in the pupil Ep, the focal distance of the image surface side of the projection units PLU, and the like. In addition, as described in FIG. 13 to FIG. 15 above, among the plurality of micro mirrors Ms of the DMD 10, only a specified single micro mirror Ms is made in the ON state, and a positional relation between a center of gravity of the intensity distribution formed on the pupil Ep and the optical axis AXa is measured by the image pick-up device 344 of the second optical measurement part. If there is a deviation in the positional relation, it is determined that the inclination angle θd of the specified micro mirror Msa in the ON state has an error from the standard value (for example, 17.5°).

While the measurement time is required, by turning all the micro mirrors Ms of the DMD 10 to the ON state one by one and performing measurement using the image pick-up device 344, the error (driving error) of the inclination angle θd of each of the micro mirrors Ms can be obtained. While the error of the inclination angle θd of each of the micro mirrors Ms cannot be adjusted or corrected due to the unique characteristics of the DMD 10, if the micro mirrors Ms with a large error in the inclination angle θd are distributed on the average, the telecentric error may also occur due to the error in the inclination angle θd.

For example, when a nominal value (standard value) of the inclination angle θd of the micro mirrors Ms of the DMD 10 is 17.5° and the driving error of the angle is ±0.5°, if the incidence angle θα of the illumination light ILm to the DMD 10 is 35.0°, the maximum telecentric error on the object surface side (the side of the DMD 10) of the projection units PLU is ±1°. Accordingly, when the projection magnification Mp of the projection units PLU is ⅙, the maximum telecentric error Δθt on the image surface side due to the driving error of the micro mirrors Ms is ±6°. According to the variant, since the telecentric error Δθt due to the unique driving error of the inclination angle θd of the micro mirrors Ms of the DMD 10 can be measured, the adjustment (calibration) can be performed before exposure of the actual pattern in order to correct the telecentric error Δθt.

### (Variant 3)

As described in the above-mentioned Variant 1, before the actual pattern is exposed on the substrate P, the telecentric error Δθt that can occur in some typical pattern forms (in particular, the line and space pattern, and the pad-shaped pattern) contained in the actual pattern is previously measured using the first optical measurement part (the image pick-up device 326) or the second optical system measurement unit (the image pick-up device 344). Then, for example, a relation between the measured telecentric error Δθt and the pattern form can be learnt (stored) in the exposure controller 306 shown in FIG. 32 as database.

Conventionally, such an exposure apparatus EX receives various types of pieces of information such as exposure conditions, setting conditions of the driving unit, operation parameters, operation sequences, or the like, related to the actual exposure pattern for each layer of the electronic device (display panel or the like) formed on the substrate P as recipe information and performs a series exposure operation. Like the exposure apparatus EX shown in FIG. 1 to FIG. 6, in a maskless type in which each of the modules MU1 to MU27 for the plurality of drawings forms a pattern image dynamically changed by the DMD 10, each of the drawing data MA1 to MD27 (see FIG. 32) that controls the operations of the plurality of micro mirrors Ms of the DMD 10 may be included as one of recipe information. Such recipe information is often stored and managed by a main control unit (computer) that generally controls the entire exposure apparatus EX.

Here, the data analysis part 302A and the telecentric error calculation part 302B of the adjustment control system TEC described in FIG. 32 compare each of the drawing data MD1 to MD27 with the pattern form in the previously learnt (stored) database, and generate information (corrected position information) related to the scanning exposure position of the portion in which the telecentric error Δθt is equal to or exceeds the allowable limit (for example, a partial region in the region DA7 or DA10 in the X direction of FIG. 33), and information related to the angular variation from the telecentric state of the telecentric error Δθt, i.e., the image forming light flux (the reflected light Sa′ containing the diffraction light) (information related to the inclination direction, the inclination quantity, or the correction amount of the inclination), as one of new recipe information (equivalent to the information STD in FIG. 32). Further, the information (corrected position information) related to the scanning exposure position is not necessarily required unless there is a change in pattern form in the entire range of each of the regions DAn (n=1 to 27) on the substrate P exposed by each of the projection regions IAn (n=1 to 27).

In addition, important pattern parts with high specification values for line width accuracy, positional accuracy, or overlapping accuracy are extracted from the drawing data related to the actual exposure pattern contained in the recipe information, and the recipe information is registered in advance as a test pattern for telecentric error measurement. Then, before switching to the recipe information and starting the actual exposure, the image of the test pattern registered by the DMD 10 may be projected, and the telecentric error Δθt may be measured using the first optical measurement part (the image pick-up device 326) or the second optical system measurement unit (the image pick-up device 344) to generate adjustment (correction) information.

From above, according to the variant, in the pattern exposure apparatus including the illumination unit ILU configured to irradiate the illumination light ILm to the DMD 10 as the spatial light modulating element having the plurality of micro mirrors Ms that switch between the ON state and the OFF state on the basis of the drawing data MDn, and the projection units PLU configured to allow incidence of the reflected light from the micro mirrors Msa in the ON state of the DMD 10 as the image forming light flux (Sa′) and project an image of the pattern corresponding to the drawing data MDn to the substrate P, an angular variation (telecentric error) of the image forming light flux (Sa′) generated by the diffraction effect when the plurality of micro mirrors Ms of the DMD 10 are made in the ON state can be suppressed within the allowable limit by providing the control unit configured to store information related to the angular variation (the telecentric error Δθt) of the image forming light flux (Sa′) generated according to the distribution density of the micro mirrors Msa in the ON state of the DMD 10 together with the drawing data MDn as the recipe information, and the adjustment mechanism (the driving unit 100C, the micro-motion mechanism 108D, the micro-motion mechanism 110C, or the like) configured to adjust a position or an angle of at least one optical member (the mirror 100, 112, the opening diaphragm 108B, the condenser lens system 110, the DMD 10, or the like) in the illumination unit ILU (or the projection units PLU) according to the information related to the angular variation (Δθt) when the DMD 10 is driven to expose the pattern on the substrate P on the basis of the recipe information.

### (Variant 4)

As described in the above-mentioned Variant 3, when the image of the test pattern corresponding to an important pattern portion included in the recipe information is projected by the DMD 10 and measured by the first optical measurement part (the image pick-up device 326), the first optical measurement part (the image pick-up device 326) measures the intensity distribution of the projected image of the test pattern. Here, as shown in FIG. 24 above, a degree of degradation (asymmetry) of symmetric properties of the image is image-analyzed by, for example, the exposure controller 306 or the like as shown in FIG. 32. Then, in order to reduce asymmetry of the image, the adjustment mechanism (the driving unit 100C the micro-motion mechanism 108D, the micro-motion mechanism 110C, or the like) for the telecentric error in the illumination unit ILU, or the eccentric micro-motion mechanism of the lens group or the lens element in the projection units PLU may be controlled.

In this case, for example, after performing a predetermined amount of adjustment using the telecentric error adjustment mechanism or the eccentric micro-motion mechanism, the asymmetry of the image can be reduced by learning of repeatedly measuring a degree of the asymmetry of the image of the test pattern using the first optical measurement part (the image pick-up device 326) a plurality of times. Accordingly, if the asymmetry degree of the pattern image to be projected and the adjustment amount of the telecentric error adjustment mechanism or the eccentric micro-motion mechanism to reduce them are associated and created in the database, there is no need to quantitatively obtain the telecentric error Δθt or use the information.

From above, according to the variant, in the pattern exposure apparatus including the illumination unit ILU configured to irradiate the illumination light ILm to the DMD 10 as the spatial light modulating element having the plurality of micro mirrors Ms that switch between the ON state and the OFF state on the basis of the drawing data MDn, and the projection units PLU configured to allow incidence of the reflected light from the micro mirrors Msa in the ON state of the DMD 10 as the image forming light flux (Sa′) and project the image of the pattern corresponding to the drawing data MDn to the substrate P, asymmetry of the pattern image caused by the telecentric error of the image forming light flux (Sa′) occurred due to the diffraction effect when the plurality of micro mirrors Ms of the DMD 10 are in the ON state can be reduced by providing the measurement unit (the image pick-up device 326) configured to measure a degree of asymmetry of the image of the pattern generated according to the telecentric error of the image forming light flux (Sa′) occurred according to the distribution density of the micro mirrors Msa in the ON state of the DMD 10, and the adjustment mechanism (the driving unit 100C, the micro-motion mechanism 108D, the micro-motion mechanism 110C, or the like) configured to adjust a position or an angle of at least one optical member (the mirror 100, 112, the opening diaphragm 108B, the condenser lens system 110, the DMD 10 or the like) in the illumination unit ILU (or the projection units PLU) to reduce the measured asymmetry when the DMD 10 is driven on the basis of the recipe information to expose the pattern on the substrate P.

In the description of the above-mentioned first embodiment and each variant, the isolation pattern as an aspect of the pattern is not particularly limited to the case in which one or a row of all the micro mirrors Ms of the DMD 10 becomes the micro mirrors Msa in the ON state. For example, it can also be regarded as the isolation pattern even when two, three (1×3), four (2×2), six (2×3), eight (2×4), or nine (3×3) micro mirrors Msa in the ON state are densely arranged, and, for example, 10 or more micro mirrors Ms therearound become the micro mirrors Msb in the OFF state in the X′ direction and the Y′ direction. On the contrary, it can also be regarded as the land-like pattern when two, three (1×3), four (2×2), six (2×3), eight (2×4), or nine (3×3) micro mirrors Msa in the OFF state are densely arranged, and, for example, the micro mirrors Msb therearound becomes the micro mirrors Msa in the ON state densely arranged to several or more (corresponding to a dimension several times or more than the isolation pattern) in the X′ direction and the Y′ direction.

In addition, the line and space pattern as an aspect of the pattern is also not particularly limited to the aspect as shown in FIG. 21 in which the micro mirrors Msa in the ON state of one row and the micro mirrors Msb in the OFF state of one row are alternately arranged repeatedly. For example, the pattern may be an aspect in which the micro mirrors Msa in the ON state of two rows and the micro mirrors Msb in the OFF state of two rows are alternately arranged repeatedly, an aspect in which the micro mirrors Msa in the ON state of three rows and the micro mirrors Msb in the OFF state of three rows are alternately arranged repeatedly, or an aspect in which the micro mirrors Msa in the ON state of two rows and the micro mirrors Msb in the OFF state of four rows are alternately arranged repeatedly. Even in the case of any pattern type, when the distribution state (a density or a concentration degree) of the micro mirrors Ms in the ON state per unit area (for example, an arrangement region of 100×100 micro mirrors Ms) in all the micro mirrors Ms of the DMD 10 is determined, the telecentric error Δθt or the degree of the asymmetry property can also be easily specified by simulation or the like.

### Second Embodiment

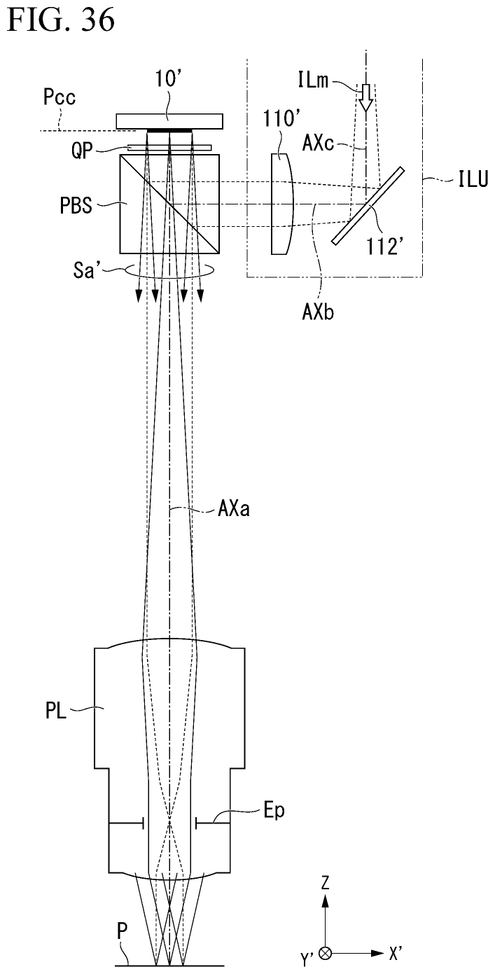

FIG. 36 is a view showing one schematic configuration of a drawing module provided in a pattern exposure apparatus according to a second embodiment. For example, an orthogonal coordinate system X′Y′Z in FIG. 36 is set to the same as the coordinate system X′Y′Z of FIG. 6 above. In the embodiment, illumination light ILm radiated to a digital mirror device (DMD) 10′ as a spatial light modulating element from the illumination unit ILU is epi-illuminated via a cap type polarization beam splitter PBS as a beam splitter. In FIG. 36, a neutral plane Pcc of the DMD 10′ is set to be perpendicular to an optical axis AXa of a bilateral telecentric projection unit PLU, and the polarization beam splitter PBS is disposed in the middle of the optical path between the DMD 10′ and the projection unit PLU. A polarization splitting surface of the polarization beam splitter PBS is disposed to rotate by 45° from the X′Y′ plane around a line parallel to the Y′ axis to cross the optical axis AXa at 45° by simulation.

The illumination light ILm entering a side surface of the polarization beam splitter PBS via a reflecting mirror 112′ and a condenser lens system 110′ of the illumination unit ILU is set to S polarization with linear polarization in the Y′ direction in FIG. 36, and 95% or more of the quantity of light is reflected by the polarization splitting surface of the polarization beam splitter PBS in the +Z direction. The illumination light ILm that advances from the polarization beam splitter PBS in the +Z direction passes through a ¼ wavelength plate QP and becomes circular polarization to irradiate the DMD 10′ with a uniform illuminance distribution.

The reflecting surface of the micro mirrors Ms of the DMD 10′ according to the embodiment is set to become a flat posture parallel to the neutral plane Pcc in the ON state in which the reflected light enters the projection units PLU, and set to be inclined by a constant angle θd with respect to the neutral plane Pcc in the OFF state in which the reflected light does not enter the projection units PLU. Accordingly, a non-exposure period in which the DMD 10′ does not expose any pattern becomes an initial state in which all the micro mirrors Ms are inclined at the angle θd. For this reason, unlike the aspect shown in FIG. 11 and FIG. 12 above, the micro mirrors Msa in the ON state are in a posture parallel to the neutral plane Pcc, and the micro mirrors Msb in the OFF state are in a posture inclined by the angle θd from the neutral plane Pcc.

In addition, even in the configuration of FIG. 36, the illumination light ILm from the surface light source image (the aggregate of the point light source SPF) formed on the emission surface side of the micro fly's eye (MFE) lens 108A in the illumination unit ILU Koehler-illuminates the DMD 10′, and the pupil Ep of the projection units PLU is set to have a conjugation relation with the surface light source image on the emission surface side of the MFE lens 108A. The reflected light (image forming light flux) Sa′ from the micro mirrors Msa in the ON state of the DMD 10′ travels rearward through the ¼ wavelength plate QP, is converted into linear polarization (P polarization) in the X′ direction to pass through the polarization splitting surface of the polarization beam splitter PBS, and enters the projection units PLU. In the embodiment, it is conceivable that, since the principal ray of the illumination light ILm is set to be perpendicular to the neutral plane Pcc of the DMD 10′, the principal ray of the reflected light (image forming light flux) Sa′ from the micro mirrors Msa in the ON state is geometrically and optically parallel to the optical axis AXa, and it is considered that a large telecentric error Δθt does not occur.

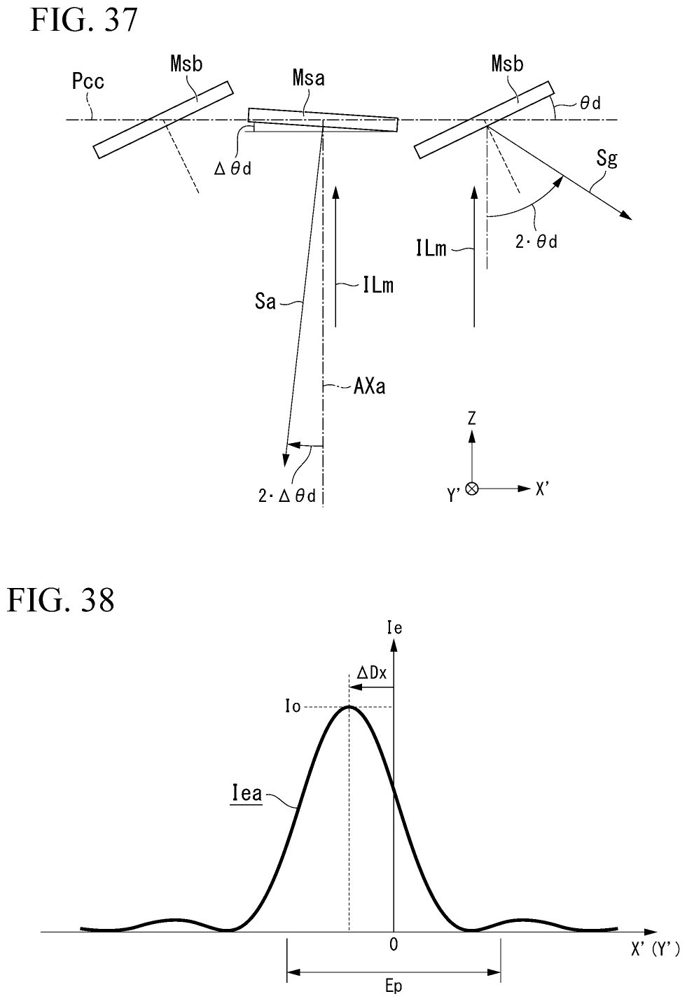

However, since a predetermined error occurs in a driving angle of the micro mirrors Ms of the DMD 10′, this may cause the telecentric error Δθt. FIG. 37 is a view that exaggerates a state of the micro mirrors Ms when the isolation patterns with a minimum line width are projected by the DMD 10′. In FIG. 37, the micro mirrors Msb in the OFF state in the X′Z plane is inclined at the angle θd of the initial state, and the reflected light Sg due to the irradiation of the illumination light ILm is reflected at a double angle 2θd with respect to the optical axis AXa. Meanwhile, the micro mirrors Msa in the ON state are inclined by the angle θd from the posture in the initial state, and the reflecting surface is driven to be parallel to the neutral plane Pcc. Here, when there is a driving error Δθd, the micro mirrors Msa in the ON state are inclined by θd+Δθd from the posture of the initial state.

For this reason, the principal ray of the reflected light (image forming light flux) Sa from the isolated micro mirrors Msa in the ON state is generated at a double angle 2·Δθd inclined with respect to the optical axis AXa. As exemplified in the above-mentioned embodiment, the pitches Pdx and Pdy of the micro mirrors Ms of the DMD 10′ is 5.4 μm, the angle θd of the initial state is 17.5°, the projection magnification Mp of the projection units PLU is ⅙, and the driving error Δθd is up to ±0.5°. In this case, the telecentric error on the object surface side of the reflected light (image forming light flux) Sa is up to ±1, and the telecentric error Δθt on the image surface side is up to ±6°. In general, the driving error Δθd rarely varies among the plurality of micro mirrors Ms of the DMD 10′, and it is often the specified value (average value) within the maximum error range on average. Since the maximum value (±0.5°) of the driving error Δθd is within the allowable limit according to the product specifications of the DMD 10′, among several production lots, it is also possible to select those in which the average driving error Δθd of the micro mirrors Msa in the on-state is, for example, ±0.25° or less. In any case, with the influence of the driving error Δθd, the point image intensity distribution of the reflected light (image forming light flux) Sa in the pupil Ep of the projection units PLU becomes the distribution of the sin c2 function as shown in FIG. 16 above.

FIG. 38 is a graph schematically expressing the point image intensity distribution lea of the diffraction image in the pupil Ep of the reflected light Sa from the isolated micro mirrors Msa in the ON state shown in FIG. 37. As shown in FIG. 38, a center position of the point image intensity distribution lea is laterally shifted from the position of the optical axis AXa in the pupil Ep by ΔDx in the X′ direction. The lateral shift ΔDx corresponds to the size of the driving error Δθd of the micro mirrors Msa in the ON state. For this reason, the telecentric error Δθt by the driving error Δθd can be suppressed by measuring the telecentric error Δθt occurred at the driving error Δθd of the micro mirrors Msa in the ON state of the DMD 10′ in actual using the first optical measurement part (the image pick-up device 326) or the second optical measurement part (the image pick-up device 344) described in FIG. 35 above and correcting it using the adjustment mechanism of the telecentric error.

The above-mentioned telecentric error Δθt caused by the driving error Δθd of the micro mirrors Ms occurs similarly even in the case of the DMD 10 according to the above-mentioned first embodiment. For example, while the telecentric error Δθd by the diffraction effect does not occur upon projection of the isolation pattern described in FIG. 13 and FIG. 14 above, the telecentric error Δθt caused by the driving error Δθd can occur. Accordingly, even upon projection of the isolation pattern by the DMD 10 of the first embodiment, it is desirable to control the telecentric error adjustment mechanism such that the telecentric error Δθt on the image surface side caused by the driving error Δθd is reduced within the allowable limit (for example, within ±2°, desirably, within 1).

Next, the case in which many of the micro mirrors Ms of the DMD 10′ are densely packed and become the micro mirrors Msa in the ON state will be described with reference to FIG. 39. FIG. 39 is a view that exaggerates a state of the micro mirrors Ms when a large land-like pattern is projected by the DMD 10′. In FIG. 39, the micro mirrors Msa in the ON state in the X′Z plane act as a planar diffraction grating arranged by the pitch Pdx in the X′ direction ideally. Even in this case, it is assumed that each of the micro mirrors Msa in the ON state has the driving error Δθd.

Even in the case of FIG. 39, it is possible to obtain a diffraction angle θj of a j-order diffraction light Idj on the basis of Equation (2) described in FIG. 19 above.

$$\begin{matrix}[ Math . 5 ] & \\ sin θ j = j ( λ / Pdx ) - sin θα & ( 2 )\end{matrix}$$

When the pitch Pdx of the micro mirrors Msa in the ON state is 5.4 μm, the wavelength λ is 343.333 nm, and the incidence angle θα of the illumination light ILm is 0°, a diffraction angle θ0 (an angle from the optical axis AXa) of the zero order diffraction light Id0 contained in the reflected light (image forming light flux) Sa′ from the DMD 10′ is of course 0°. Further, a diffraction angle θ1 of the ±1-order diffraction lights (−Id1, +Id1) contained in the reflected light (image forming light flux) Sa′ is about ±3.645° with the optical axis AXa being interposed therebetween on the object surface side of the projection unit PLU.

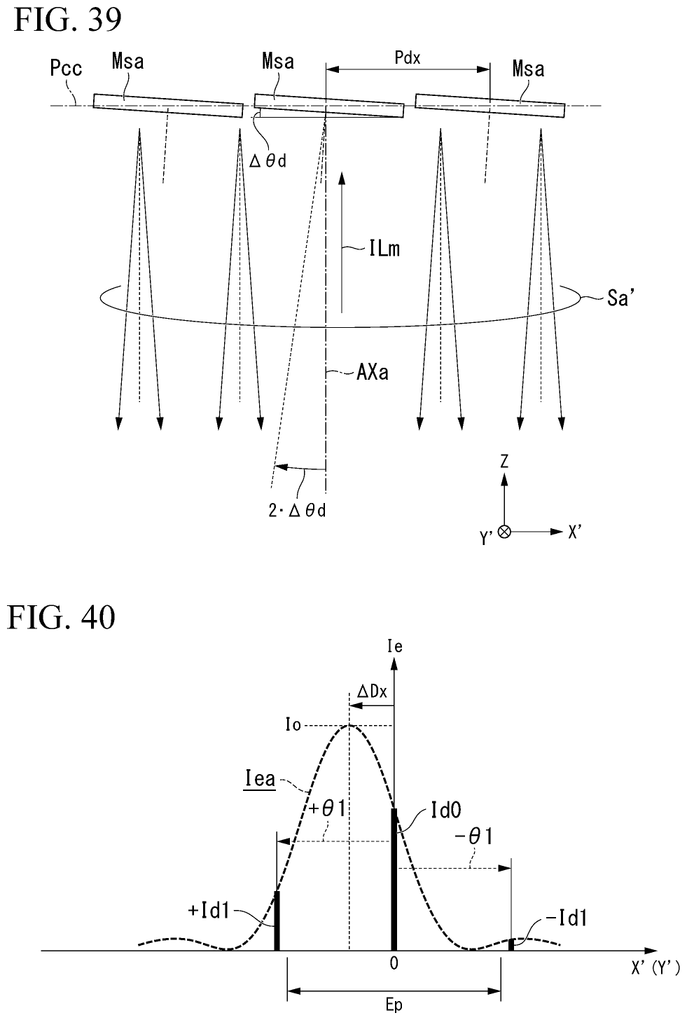

FIG. 40 is a view schematically showing an example of a center ray of the zero order diffraction light Id0 and the +1-order diffraction lights (−Id1, +Id1) contained in the reflected light (image forming light flux) Sa′ in the generating direction on the surface of the pupil Ep of the projection unit PLU in the state of FIG. 39. Like FIG. 38 above, the point image intensity distribution lea is laterally shifted by ΔDx from the optical axis AXa by the driving error Δθd of the micro mirrors Msa in the ON state. The actual intensity distribution of the zero order diffraction light Id0 and the +1-order diffraction lights (−Id1, +Id1) formed on the pupil Ep is obtained by convolution-integration (convolution-calculation) of the point image intensity distribution lea (sin c2 function) laterally shifted by ΔDx and Equation (2) in consideration of the size (σ value) of the surface light source that can be formed on the pupil Ep (the light source image Ips shown in FIG. 9 above).

As shown in FIG. 40, while the point image intensity distribution lea is laterally shifted by ΔDx from the optical axis AXa, the zero order diffraction light Id0 is parallel to the optical axis AXa, and the +1-order diffraction lights (−Id1, +Id1) is generated symmetrically with respect to the zero order diffraction light Id0. As a result, since the actual intensity distribution of the zero order diffraction light Id0 obtained by convolution integration is located at the center of the pupil Ep, the telecentric error Δθt does not occur. However, a peak value of the actual intensity distribution (substantially circular shape) of the zero order diffraction light Id0 is decreased from a peak value Io of the point image intensity distribution lea. In addition, the peak value of the actual intensity distribution (substantially circular shape) of each of the ±1-order diffraction lights (−Id1, +Id1) is largely reduced. A change in quantity of light of the zero order diffraction light Id0 or the +1-order diffraction lights (−Id1, +Id1) can be specified by simulation, and can be specified by measuring the projection image such as a test pattern or the like using the first optical measurement part (the image pick-up device 326) shown in FIG. 35.

A diffraction angle ±θ1′ on the image surface side of the diffraction angle θ1 (≈3.645°) of the ±1-order diffraction lights (−Id1, +Id1) on the object surface side is the reciprocal multiple of the projection magnification Mp (⅙), and ranges from θ1′=θ1/Mp≈±21.87°. The angle θ1′ corresponds to approximately 0.37 when converted to the numerical aperture NAi on the image surface side of the projection units PLU. When the numerical aperture NAi on the image surface side is, for example, about NAi=0.30, about half of the actual intensity distribution (circular shape) of each of the ±1-order diffraction lights (−Id1, +Id1) does not pass through the pupil Ep. Further, when the numerical aperture NAi on the image surface side of the projection units PLU is about 0.25, most of the actual intensity distribution of the +1-order diffraction lights (−Id1, +Id1) is located outside the opening of the pupil Ep, and the reflected light (image forming light flux) Sa′ projected to the substrate P is exclusively a component of the zero order diffraction light Id0.

Hereinabove, in the epi-illumination type like the embodiment, among the plurality of micro mirrors Ms of the DMD 10′, when a large number of the micro mirrors Msa in the ON state are crowded together to correspond to the large land-like pattern, a remarkable telecentric error Δθt on the image surface side due to the diffraction effect does not occur. However, the quantity of light of the reflected light (image forming light flux) Sa′ that becomes the land-like pattern is reduced according to the size of the driving error Δθd (the lateral shift ΔDx) of the micro mirrors Msa in the ON state. When reduction in quantity of light increases, defects such as an increase in the dimension error of the resist image of the land-like pattern and worsening of omissions appeared after development of the substrate P occur.

Accordingly, as shown in FIG. 39, upon exposure of the land-like pattern in which a large number of the micro mirrors Msa in the ON state are densely provided, the purpose is not to correct the telecentric error Δθt but to correct the decrease in quantity of light of the reflected light (image forming light flux) Sa′ due to the driving error Δθd, and the adjustment mechanism (the driving unit 100C, the micro-motion mechanism 108D, the micro-motion mechanism 110C, or the like) for the telecentric error in the illumination unit ILU may be adjusted to finely adjust the incidence angle θα (0° by design) of the illumination light ILm to the DMD 10′.

Since the light quantity variation error of the reflected light (image forming light flux) Sa′ caused by the driving error Δθd of the micro mirrors Msa in the ON state can also occur even when the DMD 10 is irradiated with the illumination light ILm using the oblique illumination type like the above-mentioned first embodiment, the telecentric error Δθt may be corrected in consideration of the driving error Δθd. In addition, when the light quantity variation error of the reflected light (image forming light flux) Sa′ is within the allowable limit (for example, 10%) or more due to correction of the telecentric error Δθt, the illuminance adjustment filter 106 shown in FIG. 26 above may be adjusted and the illumination light ILm may be adjusted to increase the transmittance thereof. Accordingly, in order to perform the adjustment, the information related to the light quantity variation error of the reflected light (image forming light flux) Sa′ caused by the driving error Δθd of the micro mirrors Msa in the ON state can also be generated as one type of the recipe information and stored in a main control unit (computer).

In addition, since the light quantity variation error of the reflected light (image forming light flux) Sa′ occurs in a decreasing direction, this can also be addressed by powering up the beams LB1 to LB4 from the laser light sources FL1 to FL4 described in FIG. 29. However, in order to maximize productivity (takt), in many cases, each of the laser light sources FL1 to FL4 oscillates the beams LB1 to LB4 at almost full power, and no further power up can be expected. This is also similar to the illuminance adjustment filter 106, and it may not be possible to increase the transmittance further. In such a case, it is possible to compensate for a decrease in exposure amount (dose) given to a resist layer of the substrate P by decreasing a scanning speed of the substrate P in the X direction upon scanning exposure (a moving speed of the XY stage 4A in FIG. 1). Here, a switching period (frequency) of the micro mirrors of the DMD 10′ (or the DMD 10) in the OFF state/ON state is also adjusted according to a scanning speed of the substrate P.

Further, among the telecentric error Δθt of the reflected light (image forming light flux) Sa′ projected to the substrate P, the asymmetry error (see FIG. 24) of the pattern image caused by the telecentric error Δθt, and the light quantity variation error of the reflected light (image forming light flux) Sa′ caused by the driving error Δθd of the micro mirrors Msa in the ON state, at least one error that exhibits a particularly notable error may be specified, and at least one of the optical member in the illumination unit ILU or the projection units PLU, or a two-dimensional inclination of the DMD 10′ (or the DMD 10) may be adjusted to reduce the error.

As is apparent from the state of FIG. 40, not only the influence by the driving error Δθd, but also the lateral shift quantity of the diffraction light Id0 equivalent to the zero order light on the distribution of the Sin c2 function is also changed depending on the telecentric error Δθt occurred due to the diffraction phenomenon by the pattern form (isolation form, L&S form, land-like form, or the like), and the intensity of the diffraction light Id0 is decreased. In this case, even if the adjustment member in the illumination optical system or a posture (inclination) or the like of the DMD 10′ or the DMD 10 is adjusted such that the telecentric error Δθt including the driving error Δθd becomes zero, the intensity of the diffraction light Id0 continues to be decreased. For this reason, it is desirable to calculate a total light quantity variation (mainly, a decrease in illuminance) that may occur due to the telecentric error Δθt according to the form of the exposed pattern in advance by prediction calculation (simulation), actually measure the projection state of the test pattern using the first optical measurement part (the image pick-up device 326), or perform illuminance correction upon actual exposure.

Hereinabove, according to the embodiment, in the device manufacturing method of forming the device pattern on the substrate P by irradiating the DMD 10′ (or the DMD 10) as the spatial light modulating element having the plurality of micro mirrors Ms that switch between the ON state and the OFF state on the basis of the drawing data MDn with the illumination light ILm from the illumination unit ILU, and projecting an image of the device pattern corresponding to the drawing data MDn to the substrate P using the projection units PLU configured to allow incidence of the reflected light from the micro mirrors Msa in the ON state of the DMD 10′ (or the DMD 10) as the image forming light flux (Sa′), the device manufacturing method of reducing a telecentric error or a change in quantity of light caused by the diffraction effect or the driving error Δθd when the micro mirrors Ms of the DMD 10′ (or the DMD 10) are in the ON state and forming a faithful pattern based on the drawing data is obtained by performing a step of specifying a change in quantity of light of the image forming light flux (Sa′) caused by the telecentric error of image forming light flux (Sa′) occurred according to the distribution state of the micro mirrors Msa in the ON state of the DMD 10′ (or the DMD 10) or the driving error Δθd of the micro mirrors Msa in the ON state, and a step of adjusting an installation state (position or angle) of at least one optical member (may be the mirror 100, 112, the opening diaphragm 108B, the condenser lens system 110, the illuminance adjustment filter 106, or the DMD 10 or the DMD 10′) in the illumination unit ILU (or the projection units PLU) to reduce the specified telecentric error or the change in quantity of light when the DMD 10′ (or the DMD 10) is driven on the basis of the recipe information (the drawing data MDn) to expose a device pattern on the substrate P.

Further, according to the embodiment, in the device manufacturing method of forming an electronic device on the substrate P by irradiating the DMD 10′ (the DMD 10) as the spatial light modulating element having the plurality of micro mirrors Ms that switch between the ON state and the OFF state on the basis of the drawing data MDn with the illumination light ILm from the illumination unit ILU and projecting a pattern image of the electronic device corresponding to the drawing data MDn to the substrate P using the projection units PLU configured to allow incidence of the reflected light Sa′ from the micro mirrors Msa in the ON state of the DMD 10′ (the DMD 10) as the image forming light flux, the device manufacturing method capable of forming a faithful pattern on the basis of the drawing data by reducing a telecentric error caused by the diffraction effect or the driving error Δθd, an error of asymmetry, or an error of a light quantity variation when the micro mirrors Ms of the DMD 10′ (or the DMD 10) are in the ON state is obtained by performing a step of specifying at least one error that exhibits a particularly notable error or two errors occurred in combination (for example, a telecentric error and a light quantity variation error, or a telecentric error and an asymmetry error) among the telecentric error Δθt of the reflected light (image forming light flux) Sa′ generated by the diffraction effect according to the distribution state of the micro mirrors Msa in the ON state of the DMD 10′ (the DMD 10), an asymmetry error of the pattern image occurred due to the telecentric error Δθt, and a telecentric error or a light quantity variation error of the reflected light (image forming light flux) Sa′ caused by the driving error Δθd of the micro mirrors Msa in the ON state, and a step of adjusting an installation state (position or angle) of at least one optical member in the illumination unit ILU or the projection units PLU to reduce at least one specified error when the DMD 10′ (the DMD 10) is driven to expose a pattern image on the substrate P.

What is claimed is:

1. A pattern exposure apparatus comprising: an illumination unit configured to irradiate illumination light to a spatial light modulating element including a plurality of micro mirrors that are driven to switch between an ON state and an OFF state based on drawing data, and a projection unit configured to allow incidence of reflected light from the micro mirrors of the spatial light modulating element which are in the ON state as an image forming light flux and configured to project an image of a pattern corresponding to the drawing data to a substrate,
wherein the pattern exposure apparatus comprises:
a control unit configured to store information, which is related to an angular variation of the image forming light flux generated according to a distribution density of the micro mirrors of the spatial light modulating element which are in the ON state, together with the drawing data as recipe information; and
an adjustment mechanism configured to adjust (i) a position or an angle of at least one optical member in the illumination unit or the projection unit or (ii) an angle of the spatial light modulating element, according to the information related to the angular variation when a pattern is exposed on the substrate by driving the spatial light modulating element based on the recipe information.

2. The pattern exposure apparatus according to claim 1, wherein the projection unit includes an exit pupil which allows the image forming light flux to pass through a predetermined opening diameter, and
wherein the adjustment mechanism is configured to perform adjustment such that an eccentric state of a distribution of the image forming light flux in the exit pupil defined from the information related to the angular variation is decreased.

3. The pattern exposure apparatus according to claim 2, further comprising a stage apparatus configured to move while supporting the substrate at an image surface side of the projection unit,
wherein the stage apparatus includes an optical measurement part configured to measure a distribution of the image forming light flux formed in the exit pupil of the projection unit.

4. The pattern exposure apparatus according to claim 3, wherein the control unit generates the information related to the angular variation based on the drawing data as a telecentric error amount and previously determines whether the telecentric error amount becomes a predetermined allowable limit or more defined according to the distribution density of the micro mirrors which are in the ON state, and
wherein the adjustment mechanism performs an adjustment operation upon pattern exposure when the telecentric error amount becomes the predetermined allowable limit or more.

5. The pattern exposure apparatus according to claim 4, wherein the control unit stores drawing data for a test pattern corresponding to a pattern form in which the telecentric error amount can become or exceed the predetermined allowable limit, and
wherein the optical measurement part confirms the telecentric error amount by measuring a distribution in the exit pupil of the image forming light flux from the spatial light modulating element which is driven by the drawing data for the test pattern.

6. The pattern exposure apparatus according to claim 1, wherein the illumination unit includes an optical integrator configured to allow incidence of a beam from a light source device, and a condenser lens system configured to perform Koehler illumination by directing illumination light from a surface light source generated by the optical integrator toward a mirror surface of the spatial light modulating element, and
wherein the projection unit includes an exit pupil having an optical conjugation relation with a position of the surface light source generated by the optical integrator, and reduces and projects an image of a pattern generated by the micro mirrors of the spatial light modulating element which are in the ON state.

7. The pattern exposure apparatus according to claim 6, wherein the adjustment mechanism is constituted by an adjustment mechanism configured to adjust an incidence position or an incidence angle of the beam entering the optical integrator or an adjustment mechanism configured to adjust a relative positional relation related to an eccentric direction of the optical integrator and the condenser lens system such that an incidence angle of the illumination light radiated to the spatial light modulating element is changed.

8. The pattern exposure apparatus according to claim 6, wherein the control unit further stores information related to an illuminance variation of the image forming light flux generated according to a density distribution of the micro mirrors of the spatial light modulating element which are in the ON state as one of pieces of the recipe information.

9. The pattern exposure apparatus according to claim 8, wherein the illumination unit includes an illuminance adjustment filter configured to change an illuminance of the illumination light radiated to the spatial light modulating element, and
wherein the adjustment mechanism further includes a mechanism configured to control the illuminance adjustment filter based on the information related to the illuminance variation.

10. The pattern exposure apparatus according to claim 3, wherein the control unit stores further information related to an illuminance variation of the image forming light flux generated according to the density distribution of the micro mirrors of the spatial light modulating element which are in the ON state as one of pieces of the recipe information, and
wherein the stage apparatus adjusts a moving speed when a projection image by the projection unit, which is a pattern generated by the micro mirrors in the ON state, is scanned and exposed on the substrate based on the information related to the illuminance variation.

11. The pattern exposure apparatus according to claim 2, wherein the projection unit includes a plurality of lenses disposed in front of and behind the exit pupil, and an optical member configured to correct an image surface inclination generated when an angle of the spatial light modulating element is adjusted by the adjustment mechanism.

12. The pattern exposure apparatus according to claim 2, wherein the projection unit includes a plurality of lenses disposed in front of and behind the exit pupil, and
wherein positions of some of the plurality of lenses are adjusted in an eccentric direction such that an image surface inclination, which is generated when an angle of the spatial light modulating element is adjusted by the adjustment mechanism, is corrected.

13. A pattern exposure apparatus comprising: a spatial light modulating element including a plurality of micro mirrors selectively driven based on drawing data, an illumination unit configured to irradiate illumination light to the spatial light modulating element at a predetermined incidence angle, and a projection unit configured to allow incidence of reflected light from the selected micro mirrors of the spatial light modulating element which are in the ON state as an image forming light flux and configured to project the reflected light to a substrate, and the pattern exposure apparatus is configured to project and expose a pattern corresponding to the drawing data to the substrate,
wherein the pattern exposure apparatus comprises:
a telecentric error specifying part configured to previously specify a telecentric error, which occurs in the image forming light flux projected to the substrate from the projection unit upon projection exposure of the pattern, according to a distribution state of the micro mirrors of the spatial light modulating element which are in the ON state; and
an adjustment mechanism configured to adjust a position or an angle of an optical member of a part of the illumination unit or the projection unit such that the telecentric error is corrected.

14. The pattern exposure apparatus according to claim 13, wherein the telecentric error specifying part determines a magnitude of the telecentric error by analyzing a density of the micro mirrors in the ON state according to the pattern based on the drawing data.

15. The pattern exposure apparatus according to claim 13, wherein the telecentric error specifying part determines a magnitude of the telecentric error based on the drawing data when more than half of all the micro mirrors of the spatial light modulating element are in the ON state.

16. The pattern exposure apparatus according to claim 13, wherein the plurality of micro mirrors of the spatial light modulating element are two-dimensionally disposed in each of a first direction and a second direction, which are perpendicular to each other, in a neutral plane when the reflecting surface which becomes flat when not being driven is set as the neutral plane, and
wherein the telecentric error specifying part determines the magnitude of the telecentric error based on the drawing data when several or more micro mirrors adjacent to each other in both the first direction and the second direction becomes the micro mirrors in the ON state.

17. The pattern exposure apparatus according to claim 13, wherein the telecentric error specifying part determines the magnitude of the telecentric error based on an arrangement periodicity and a period direction of the micro mirrors in the ON state among the micro mirrors of the spatial light modulating element when the pattern to be exposed is a line and space pattern based on the drawing data.

18. The pattern exposure apparatus according to claim 14, wherein the adjustment mechanism adjusts a position or an angle of the optical member when the magnitude of the telecentric error determined by the telecentric error specifying part exceeds a predetermined allowable limit.

19. The pattern exposure apparatus according to claim 18, wherein the predetermined allowable limit is set within ±2° as an inclination angle with respect to an optical axis of a principal ray of the image forming light flux advancing from the projection unit toward the substrate.

20. The pattern exposure apparatus according to claim 13, wherein the illumination unit includes a surface light source member configured to allow incidence of a beam from a laser light source device and to generate a surface light source of the illumination light, and a condenser lens system configured to allow incidence of the illumination light from the surface light source and to perform Koehler-illumination to a reflecting surface of the spatial light modulating element, and
wherein the adjustment mechanism adjusts a relative positional relation related to an eccentric direction of the surface light source and the condenser lens system.

21. The pattern exposure apparatus according to claim 20, wherein the adjustment mechanism includes a first telecentric adjustment mechanism configured to shift a position of a beam, which is from the laser light source device and which enters the surface light source member, in an eccentric direction.

22. The pattern exposure apparatus according to claim 20, wherein the adjustment mechanism includes a second telecentric adjustment mechanism configured to shift a position of the surface light source member with respect to the beam from the laser light source device in an eccentric direction.

23. The pattern exposure apparatus according to claim 20, wherein the adjustment mechanism includes a third telecentric adjustment mechanism configured to shift a position of the condenser lens system with respect to a position of the surface light source generated by the surface light source member in an eccentric direction.

24. The pattern exposure apparatus according to claim 18, wherein the illumination unit includes a mirror configured to reflect the illumination light at a predetermined angle as the optical member, and
wherein the adjustment mechanism changes an angle of the mirror and adjusts an incidence angle of the illumination light radiated to the spatial light modulating element.

25. The pattern exposure apparatus according to claim 20, wherein, when the reflecting surfaces of the micro mirrors of the spatial light modulating element which are in the ON state are inclined by angle θd (θd>0°) by design with respect to a plane perpendicular to the optical axis of the projection unit, the illumination unit is set as an oblique illumination type such that incidence angle θα of the illumination light from the condenser lens system to the spatial light modulating element is θα=2·θd by design, and the incidence angle θα is adjusted by the adjustment mechanism.

26. The pattern exposure apparatus according to claim 20, comprising a beam splitter disposed in an optical path between the spatial light modulating element and the projection unit,
wherein, when the reflecting surfaces of the micro mirrors of the spatial light modulating element which are in the ON state are set to angle θd=0° by design with respect to a plane perpendicular to the optical axis of the projection unit, the illumination unit is set as an epi-illumination type such that the illumination light from the condenser lens system is radiated to the spatial light modulating element at incidence angle θα=0° via the beam splitter, and incidence angle θα is adjusted by the adjustment mechanism.

27. A pattern exposure apparatus comprising: an illumination unit configured to irradiate illumination light to a spatial light modulating element including a plurality of micro mirrors that are switched between an ON state and an OFF state based on drawing data for pattern exposure, and a projection unit configured to allow incidence of the reflected light from the micro mirrors of the spatial light modulating element which are in the ON state as an image forming light flux and configured to project a pattern image corresponding to the drawing data to a substrate,
wherein the pattern exposure apparatus comprises:
a measurement unit configured to measure a degree of asymmetry of the pattern image caused by a telecentric error of the image forming light flux occurring according to a distribution density of the micro mirrors of the spatial light modulating element which are in the ON state; and
an adjustment mechanism configured to adjust (i) a position or an angle of at least one optical member in the illumination unit or the projection unit or (ii) an angle of the spatial light modulating element such that the measured asymmetry is reduced when the spatial light modulating element is driven based on the drawing data and the pattern image is exposed on the substrate.

28. The pattern exposure apparatus according to claim 27, further comprising a stage apparatus that is configured to support the substrate on an image surface side of the projection unit and that is movable along the image surface,
wherein the measurement unit is provided on a part of the stage apparatus and is configured to measure a degree of the asymmetry by measuring an intensity distribution of the pattern image.

29. The pattern exposure apparatus according to claim 28, wherein the adjustment mechanism adjusts a position or an angle of at least one optical member in the illumination unit such that an incidence angle of the illumination light radiated to the spatial light modulating element is changed.

30. The pattern exposure apparatus according to claim 29, wherein the illumination unit includes a surface light source member configured to allow incidence of a beam from a light source device and to generate a surface light source of the illumination light, and a condenser lens system configured to allow incidence of the illumination light from the surface light source and to perform Koehler-illumination to the reflecting surface of the spatial light modulating element, and
wherein the adjustment mechanism adjusts a relative positional relation related to an eccentric direction of the surface light source and the condenser lens system.

31. The pattern exposure apparatus according to claim 30, wherein the surface light source member includes a fly's eye lens configured to form the surface light source on an emission surface side of a plurality of lens elements arranged two-dimensionally, and an opening diaphragm disposed on an emission surface side of the fly's eye lens, and
wherein the adjustment mechanism adjusts a relative positional relation related to an eccentric direction of an opening of the opening diaphragm and the condenser lens system.

32. The pattern exposure apparatus according to claim 30, wherein the surface light source member includes a fly's eye lens configured to form the surface light source on an emission surface side of the plurality of lens elements arranged two-dimensionally, and
wherein the adjustment mechanism adjusts an incidence angle of the beam from the light source device to the fly's eye lens.

33. The pattern exposure apparatus according to claim 28, wherein the projection unit is a reduction projection optical system constituted by a plurality of lenses and configured to project a reduced image of a pattern generated by the micro mirrors of the spatial light modulating element which are in the ON state to the substrate, and
wherein a position of a lens which is a part of the reduction projection optical system is adjusted in the eccentric direction so that an inclination of an image surface of the reduction projection optical system is corrected when the angle of the spatial light modulating element is adjusted by the adjustment mechanism.

34. The pattern exposure apparatus according to claim 28, wherein the drawing data includes data for a test pattern in which the micro mirrors which are in the ON state are arranged at a distribution density to cause a telecentric error in the image forming light flux, and
wherein the measurement unit measures the asymmetry of the projection image of the test pattern generated by the spatial light modulating element from the projection unit.

35. The pattern exposure apparatus according to claim 27, wherein the reflecting surfaces of the micro mirrors of the spatial light modulating element which are in the ON state are set to be inclined by angle θd (θd>0°) by design with respect to a plane perpendicular to the optical axis of the projection unit,
wherein incidence angle θα of the illumination light from the illumination unit to the spatial light modulating element is set to an oblique illumination type so as to satisfy θα=2·θd by design, and
wherein the adjustment mechanism adjusts the incidence angle θα.

36. The pattern exposure apparatus according to claim 27, further comprising a beam splitter disposed between the spatial light modulating element and the projection unit,
wherein the reflecting surface of the micro mirrors of the spatial light modulating element which are in the ON state are set to angle θd=0° by design with respect to a plane perpendicular to the optical axis of the projection unit,
wherein incidence angle θα of the illumination light radiated to the spatial light modulating element via the beam splitter is set to an epi-illumination type so as to satisfy θα=0° by design, and
wherein the adjustment mechanism adjusts the incidence angle θα.

37. A device manufacturing method of forming a device pattern on a substrate by irradiating illumination light from an illumination unit to a spatial light modulating element including a plurality of micro mirrors that are switched between an ON state and an OFF state based on drawing data and by projecting an image of the device pattern corresponding to the drawing data to the substrate using a projection unit configured to allow incidence of reflected light from the micro mirrors of the spatial light modulating element which are in the ON state as an image forming light flux,
wherein the device manufacturing method comprises:
a step of specifying a telecentric error of the image forming light flux generated according to a distribution state of the micro mirrors of the spatial light modulating element which are in the ON state or a light quantity variation error of the image forming light flux caused by a driving error of the micro mirrors which are in the ON state; and
a step of adjusting an installation state of at least one optical member in the illumination unit or the projection unit or the spatial light modulating element such that the specified telecentric error or the specified light quantity variation error is reduced when an image of the device pattern is exposed on the substrate by driving the spatial light modulating element based on the drawing data.

38. The device manufacturing method according to claim 37, wherein the specifying step specifies the telecentric error of the image forming light flux or the light quantity variation error based on a generation state of diffraction light defined according to the distribution state in each of an isolation pattern, a line and space pattern and a land-like pattern, the isolation pattern being a pattern in which one or several of the micro mirrors in the ON state is arranged independently or are arranged in a row, the line and space pattern being a pattern in which the micro mirrors in the ON state are arranged such that the isolation patterns are disposed at a constant period, the land-like pattern being a pattern in which the micro mirrors in the ON state are densely arranged such that a dimension of the land-like pattern is several times larger than the isolation pattern.

39. The device manufacturing method according to claim 38, wherein the reflecting surfaces of the micro mirrors of the spatial light modulating element which are in the ON state are set to be inclined by angle θd (θd≥0°) by design with respect to a plane perpendicular to an optical axis of the projection unit, and
wherein the incidence angle θα of the illumination light from the illumination unit to the spatial light modulating element is set so as to satisfy θα=2·θd by design.

40. The device manufacturing method according to claim 39, wherein, provided that an arrangement pitch of the micro mirrors is Pdx, n is a real number, a wavelength of the illumination light is λ, and an angle for each order j (j=0, 1, 2, . . . ) of the diffraction light is θj,
wherein the telecentric error of the image forming light flux is defined at an angle of a j-order diffraction light with a small inclination from the optical axis of the projection unit among a plurality of orders of diffraction lights defined by
$$sin θ j = j \cdot ( λ / ( n \cdot Pdx ) ) - sin θα .$$

41. The device manufacturing method according to claim 40, wherein the adjusting step adjusts a position or an angle of the optical member in the illumination unit or the incidence angle θα of the illumination light by adjusting an angle of the spatial light modulating element such that an inclination angle of the j-order diffraction light from an optical axis of the projection unit is within a predetermined allowable limit.

42. The device manufacturing method according to claim 40, wherein the specifying step specifies the light quantity variation error of the image forming light flux based on a degree in which a point image intensity distribution of the reflected light from a single micro mirror which is in the ON state at an exit pupil of the projection unit is eccentric corresponding to the angle error ±Δθd, when an angle error of Δθd with respect to the inclination angle θd is included as the driving error of the micro mirrors which are in the ON state.

43. The device manufacturing method according to claim 42, wherein, in the adjusting step, adjustment of beam intensity from a light source device that is a source of the illumination light or adjustment of transmittance of the illumination light by an illuminance adjustment filter provided in the illumination unit is performed according to the specified light quantity variation error.

44. A device manufacturing method of forming an electronic device on a substrate by irradiating illumination light from an illumination unit to a spatial light modulating element including a plurality of micro mirrors that are switched between an ON state and an OFF state based on drawing data and projecting a pattern image of an electronic device corresponding to the drawing data to the substrate using a projection unit configured to allow incidence of reflected light from the micro mirrors of the spatial light modulating element which are in the ON state as an image forming light flux,
wherein the device manufacturing method comprises:
a step of specifying at least one error of (i) a telecentric error of the image forming light flux generated by a diffraction effect caused by a distribution state of the micro mirrors of the spatial light modulating element which are in the ON state, (ii) an asymmetry error of the pattern image occurring due to the telecentric error, (iii) a light quantity variation error of the image forming light flux caused due to a driving error of the micro mirrors which are in the ON state, and (iv) a telecentric error of the image forming light flux caused due to the driving error, and
a step of adjusting an installation state of at least one optical member in the illumination unit or the projection unit or an installation state of the spatial light modulating element such that the at least one specified error is reduced when the spatial light modulating element is driven and the pattern image is exposed on the substrate.

45. The device manufacturing method according to claim 44, wherein the specifying step specifies the telecentric error, the asymmetry error, or the light quantity variation error based on a generation state of diffraction light defined according to the distribution state in each of an isolation pattern, a line and space pattern and a land-like pattern, the isolation pattern being a pattern in which one or several of the micro mirrors in the ON state is arranged independently or are arranged in a row, the line and space pattern being a pattern in which the micro mirrors in the ON state are arranged such that the isolation patterns are disposed at a constant period, the land-like pattern being a pattern in which the micro mirrors in the ON state are densely arranged such that a dimension of the land-like pattern is several times larger than the isolation pattern.

46. The device manufacturing method according to claim 45, wherein the reflecting surfaces of the micro mirrors of the spatial light modulating element which are in the ON state are set to be inclined by angle θd (θd≥0°) by design with respect to a plane perpendicular to the optical axis of the projection unit and includes an angle error of ±Δθd as the driving error, and
wherein the incidence angle θα of the illumination light from the illumination unit to the spatial light modulating element is set so as to satisfy θα=2·θd by design.

47. The device manufacturing method according to claim 46, wherein, in the specifying step, the telecentric error of the image forming light flux when the micro mirrors in the ON state generate the isolation pattern is specified as the angle error ±Δθd.

48. The device manufacturing method according to claim 46, wherein, provided that an arrangement pitch of the micro mirrors is Pdx, n is a real number, a wavelength of the illumination light is λ, and an angle for each order j (j=0, 1, 2, . . . ) of the diffraction light is θj,
in the specifying step,
the telecentric error of the image forming light flux when the micro mirrors in the ON state generate the land-like pattern is defined at an angle of a j-order diffraction light with a small inclination from the optical axis of the projection unit among a plurality of orders of diffraction lights defined by
$$sin θ j = j \cdot ( λ / ( n \cdot Pdx ) ) - sin θα .$$

49. The device manufacturing method according to claim 46, wherein, in the specifying step,
the light quantity variation error of the image forming light flux is specified based on a degree in which a point image intensity distribution of the reflected light from a single micro mirror which is in the ON state at an exit pupil of the projection unit is eccentric corresponding to the angle error ±Δθd.

50. The device manufacturing method according to claim 45, wherein, in the specifying step,
the test pattern belonging to any one of the isolation pattern, the line and space pattern, and the land-like pattern is generated by the spatial light modulating element, and the asymmetry error is specified based on an intensity distribution of a projection image of the test pattern projected via the projection unit.

51. The device manufacturing method according to claim 45, wherein, in the specifying step,
in a state in which the image forming light flux corresponding to any one of the isolation pattern, the line and space pattern, and the land-like pattern generated by the spatial light modulating element is projected by the projection unit, the telecentric error is specified by measuring a deviation in the intensity distribution of the image forming light flux formed at the exit pupil of the projection unit.

52. An exposure method comprising: an illumination unit configured to irradiate illumination light to a spatial light modulating element including a plurality of micro mirrors that are driven to switch between an ON state and an OFF state based on drawing data, and a projection unit configured to allow incidence of reflected light from the micro mirrors of the spatial light modulating element which are in the ON state as an image forming light flux and configured to project the light to a substrate,
wherein an angular variation of the image forming light flux, which is generated based on a distribution of the micro mirrors of the spatial light modulating element which are in the ON state, is adjusted, and
wherein a light quantity variation of the image forming light flux caused by the adjustment is adjusted.

53. The exposure method according to claim 52, wherein the adjustment of the angular variation is performed by adjustment of a position or an angle of an optical member in the illumination unit or the projection unit, or an angle of the spatial light modulating element.
